(19) United States
(12) Patent Application Publication
(10) Pub. No.: US 2026/0190535 A1
(43) Pub. Date: Jul. 2, 2026

(54) CONDUCTIVE, MULTILAYER STACKS FOR USE IN SILICON SOLAR CELLS AND PROCESSES FOR MAKING AND USING THE SAME INCLUDING LASER-BASED PROCESSES

(71) Applicant: PHOTARA INC., San Carlos, CA (US)

(72) Inventors: Brian HARDIN, San Carlos, CA (US); Maxwell Albert L'ETOILE, San Carlos, CA (US); Carolina GUTIERREZ, San Carlos, CA (US); Jason Jeffrey POWELL, San Carlos, CA (US); James Kelvin SETO, San Carlos, CA (US); Johnny Danger DOLLARD, San Carlos, CA (US)

(21) Appl. No.: 19/539,091

(22) Filed: Feb. 13, 2026

Related U.S. Application Data
(63) Continuation of application No. PCT/US2024/053359, filed on Oct. 29, 2024.
(60) Provisional application No. 63/594,199, filed on Oct. 30, 2023.
(60) Provisional application No. 63/711,821, filed on Oct. 25, 2024.

(51) Int. Cl. H10F 77/20; H10F 19/90

(52) U.S. Cl. CPC H10F 77/211; H10F 19/902

(57) ABSTRACT

A conductive multilayer stack or a conductive multilayer line useful as a metallization layer in photovoltaics as well as other devices; solar cells having a conductive multilayer stack or line; solar modules having such cells; and methods of forming a conductive multilayer stack or line. The conductive multilayer stack or line having a metal layer including copper (Cu) or coated aluminum; a silver contact layer; and a solderable layer between, and contacting, the metal layer and the silver contact layer.

### RELATED APPLICATION

This application is a Continuation of PCT Application PCT/US2024/053359 filed on Oct. 29, 2024, which claims the priority to, and the benefit of, U.S. Provisional Application No. 63/594,199, filed Oct. 30, 2023, and U.S. Provisional Application No. 63/711,821, filed Oct. 25, 2024, the contents of which are incorporated by reference in their entirety.

### FIELD

The present disclosure concerns solar cells and modules and methods of making and using the same.

### BACKGROUND

Solar cells have at least three different metallization layers: fine grid lines, busbars, and solder pads, each of which transport electric charge from the silicon in the solar cell to other components of a module. Broadly speaking there are two types of solar cells: symmetric and asymmetric solar cells. Symmetric solar cells have metallization layers on the front and rear side of the solar cells and are connected from the top of one cell to the bottom of another (e.g., by soldering tabbing wires). Asymmetric solar cells have metallization layers on one side of the solar cell (e.g., on the rear side) and are connected from the metallized side of one cell to the metallized side of another (e.g., by soldering tabbing wires).

In 2021, approximately 95% of all solar cells manufactured were symmetric and used the “passivated emitter and rear cells” (PERC) architecture. PERC cells have achieved good cell efficiencies by passivating the front and rear surfaces of the solar cell with silicon nitride, alumina and silicon oxide (SiOₓ) to reduce the area where silicon-aluminum eutectic is formed (better known as the back-surface field) to reduce surface recombination on the rear side.

“Tunnel oxide passivated contact” (TOPCon) architecture improves surface passivation in solar cells by eliminating the back surface field formation and uses additional passivation layers on the rear side of the solar cell. The TOPCon architecture is typically used with n-type wafers because not only do n-type wafers have higher bulk minority carrier lifetimes, but it is also challenging to passivate p-type silicon (Si) surfaces with transparent materials. Using n-type wafers may allow cell makers to use alumina and silicon nitride/oxynitride passivation stacks of PERC cells on the illuminated (e.g., front) side and a combination of silicon oxide (tunnel oxide) and n⁺-polysilicon to minimize recombination at the n-Si surface. TOPCon and other next generation cell designs generally use between 70-150% more silver per cell than current PERC designs.

“Heterojunction” (HJT) architecture use a combination of intrinsic and doped hydrogenated, amorphous silicon passivation layers to minimize surface recombination on n-type silicon wafers to maximize solar cell efficiency. Amorphous silicon crystallizes at relatively low temperatures and specialized silver pastes that are cured at temperatures between 150-200° C. are often used. These metallization layers are less conductive than high temperature silver pastes used for TOPCon cells. Thus, silver consumption can be considerably higher for HJT cells than TOPCon/PERC cells. There are efforts to use silver coated copper particles to reduce silver but required silver coatings are relatively thick resulting in a small silver savings.

Asymmetric solar cells have higher photocurrent densities due to increased light absorption. The most common type of asymmetric silicon solar cell is called “Interdigitated Back Contact” (IBC) cells, and they can be fabricated using both p- and n-type wafers. One of the biggest challenges to commercializing IBC cells is reducing Ag usage, which is significantly greater than PERC cells, and cell interconnection. When tabbing ribbons are only used on the rear side, the stress may cause the wafers to bow and crack during module assembly. A variety of passivation structures can be used on asymmetric cells that are similar to those used for symmetric TOPCon and HJT cells.

Silver (Ag) is important in the solar supply chain and can limit future solar cell production and limit more efficient cell designs from mass commercialization. In 2023, silver used on silicon cells currently consumed 16% of the world's annual silver and accounted for 15% of module costs. Silver is expensive, the price is volatile, and silver is mainly a byproduct of base metal mining, which limits production increases. Solar cell production has increased 10-fold since 2010 but would not be able to grow at a similar rate without a drastic decrease in silver consumption. The high cost of silver makes it less economical to transition to higher efficiency cell architectures (e.g., TOPCon, HJT and p-type IBC), which consume significantly more silver per cell.

A long-felt need has existed for silicon solar cells to use base metals to form metallization layers. Base metal foils (e.g., aluminum and copper foil) have high bulk conductivities and are relatively cheap. One metallization method is to join metal foils to metal layers that are attached to the silicon wafer (e.g., silver or aluminum pads). The most common strategy is to use uncoated aluminum foils that are laser welded to metal layers (e.g., silver solder pads) on the solar cell. There are at least two challenges with laser welding uncoated aluminum foil that have prevented the commercialization of this process: 1) poor adhesion between the metal foil and the underlying silver pad and 2) increased contact resistance between aluminum and silver under damp heat conditions caused by galvanic corrosion.

Thus, there is a need to develop processes that allow cheap, base metals to replace a significant fraction of the silver in the metallization layers of solar cells, but also in integrated circuits and light emitting diodes. These coatings and processes can enable lower temperature joining methods such as soldering. It is also desirable that the coatings reduce corrosion between silver and metal foil to operate under damp heat conditions.

### SUMMARY

The disclosure herein relates to conductive, multilayer stacks (CMS) that are, in some embodiments, formed using metal foils that are soldered to silver pads and laser cut into desirable shapes. Conductive multilayer stacks have many uses, including in integrated circuits, light emitting diodes, and solar cell applications, among others. These conductive, multilayer stacks are particularly useful as metallization layers on solar cells. Conductive multilayer stacks can reduce silver consumption on solar cells while maintaining excellent electrical properties and strong damp heat reliability.

In an embodiment, set forth herein is a conductive multilayer stack comprising a metal layer; a silver contact layer comprising a silver sublayer and a glass frit sublayer, wherein the silver sublayer is on the glass frit sublayer; and a solderable layer between, and contacting, the metal layer and the silver contact layer; and wherein the glass frit sublayer of the conductive multilayer stack contacts at least a portion of a silicon substrate, contacts at least a portion of an at least one passivation layer on the silicon substrate, or contacts a combination thereof. The metal layer comprises copper (Cu) or coated aluminum. The metal layer may be laser cut.

In an embodiment, set forth herein is a conductive multilayer line, comprising at least two conductive multilayer stacks on a silicon substrate having at least one passivation layer. A conductive multilayer stack of the at least two conductive multilayer stacks comprising a metal layer; a silver contact pad comprising a silver sublayer and a glass frit sublayer, wherein the silver sublayer is on the glass frit sublayer; and a solderable layer between, and contacting, the metal layer and the silver contact pad; wherein the glass frit sublayer of the conductive multilayer stack contacts at least a portion of the silicon substrate, contacts at least a portion of the at least one passivation layer, or contacts a combination thereof. The metal layer of the conductive multilayer stack is a continuous layer that connects the at least two conductive multilayer stacks. The metal layer comprises copper (Cu) or coated aluminum. The metal layer may be laser cut.

In an embodiment, set forth herein is a conductive multilayer stack on a solar cell, the conductive multilayer stack comprising a metal layer; a silver contact layer comprising a silver sublayer and a glass frit sublayer, wherein the silver sublayer is on the glass frit sublayer; and a solderable layer between, and contacting, the metal layer and the silver contact layer; and wherein the solar cell has a doped silicon substrate with a front surface and a rear surface, wherein the front surface of the doped silicon substrate is a light-facing surface, and wherein the rear surface of the doped silicon substrate is opposite of the light-facing surface of the doped silicon substrate; wherein the front surface, the rear surface, or both the front and rear surface of the doped silicon substrate has at least one passivation layer thereon; and wherein the glass frit sublayer of the conductive multilayer stack contacts at least a portion of the front and/or rear surface of the doped silicon substrate, contacts at least a portion of the at least one passivation layer, or contacts a combination of both. The metal layer comprises copper (Cu) or coated aluminum. The metal layer may be laser cut. The at least one passivation layer may comprise a tunnel oxide layer, a doped layer on at least a portion of the tunnel oxide layer, and at least one SiOxNy passivation layer on at least a portion of the doped layer. The at least one passivation layer may comprise SiOx, AlOx, or SiOxNy. The rear surface of the doped silicon substrate may further comprise at least one doped layer, wherein the at least one doped layer comprises at least one doped region and at least one oppositely-doped region.

In an embodiment, set forth herein is a conductive multilayer stack on a solar cell, the conductive multilayer stack comprising a metal layer; a silver contact layer, wherein the silver contact layer does not comprise glass frit; and a solderable layer between, and contacting, the metal layer and the silver contact layer; and wherein the solar cell has a doped silicon substrate with a front surface and a rear surface, wherein the front surface of the doped silicon substrate is a light-facing surface, and wherein the rear surface of the doped silicon substrate is opposite of the light-facing surface of the doped silicon substrate; wherein the front surface, the rear surface, or both the front and rear surface the doped silicon substrate has at least one passivation layer thereon, wherein the at least one passivation layer comprises an intrinsic amorphous layer on at least a portion of the doped silicon substrate, and a doped layer on at least a portion of the intrinsic amorphous layer; wherein the solar cell has a transparent conductive oxide layer on at least a portion of the doped layer; and wherein the silver contact layer of the conductive multilayer stack contacts at least a portion of the transparent conductive oxide layer. The metal layer comprises copper (Cu) or coated aluminum. The metal layer may be laser cut. The at least one passivation layer may be on the rear surface of the doped silicon substrate, wherein the doped layer of the at least one passivation layer comprises at least one doped region and at least one oppositely-doped region.

In an embodiment, set forth herein is a symmetric solar cell comprising a doped silicon substrate having a front surface and a rear surface; at least one passivation layer on at least a portion of the front and/or rear surface of the doped silicon substrate, wherein the front surface of the doped silicon substrate is a light-facing surface and the rear surface is opposite of the light-facing surface; and at least one fine grid line on a portion of the front surface, the rear surface, or both the front and rear surface of the doped silicon substrate. The at least one fine grid line is a conductive multilayer line comprising at least two conductive multilayer stacks, a conductive multilayer stack of the at least two conductive multilayer stacks comprising a metal layer; a silver contact pad comprising a silver sublayer and a glass frit sublayer, wherein the silver sublayer is on the glass frit sublayer; and a solderable layer between, and contacting, the metal layer and the silver contact pad; wherein the glass frit sublayer of the conductive multilayer stack contacts at least a portion of the silicon substrate, contacts at least a portion of the at least one passivation layer, or contacts a combination thereof. The metal layer of the conductive multilayer stack is a continuous layer that connects the at least two conductive multilayer stacks in the conductive multilayer line. The metal layer comprises copper (Cu) or coated aluminum. The metal layer may be laser cut. The at least one passivation layer may comprise a tunnel oxide layer, a doped layer on at least a portion of the tunnel oxide layer, and at least one SiOxNy passivation layer on at least a portion of the doped layer. The at least one passivation layer may comprise SiOx, AlOx, or SiOxNy. The symmetric solar cell may further comprise at least one solder pad on a portion of the front, rear, or both front and rear surface of the doped silicon substrate, wherein the at least one fine grid line contacts the at least one solder pad. The symmetric solar cell may further comprise at least one busbar on a portion of the front, rear or both front and rear surface of the doped silicon substrate, wherein the at least one fine grid line contacts the at least one busbar. The symmetric solar cell may further comprise a tabbing wire contacting the metal layer of the at least one fine grid line, wherein the tabbing wire comprises a metal core and a solder coating.

In an embodiment, set forth herein is a symmetric solar cell comprising a doped silicon substrate having a front surface and a rear surface, wherein the front surface of the doped silicon substrate is a light-facing surface and the rear surface is opposite of the light-facing surface; at least one passivation layer on at least a portion of the front surface, the rear surface, or both the front and rear surface of the silicon substrate, wherein the at least one passivation layer comprises an intrinsic amorphous layer on at least a portion of the doped silicon substrate, and a doped layer on at least a portion of the intrinsic amorphous layer; a transparent conductive oxide layer on at least a portion of the at least one passivation layer; and at least one fine grid line on at least a portion of the front surface, the rear surface, or both the front and rear surface of the doped silicon substrate. The at least one fine grid line is a conductive multilayer line comprising at least two conductive multilayer stacks, a conductive multilayer stack of the at least two conductive multilayer stacks comprising a metal layer; a silver contact pad, wherein the silver contact pad does not comprise glass frit; and a solderable layer between, and contacting, the metal layer and the silver contact pad; wherein the silver contact pad of the conductive multilayer stack contacts at least a portion of the transparent conductive oxide layer. The metal layer of the conductive multilayer stack is a continuous layer that connects the at least two conductive multilayer stacks in the conductive multilayer line. The metal layer comprises copper (Cu) or coated aluminum. The metal layer may be laser cut. The symmetric solar cell may further comprise at least one busbar on at least a portion of the front, rear, or both front and rear surface of the doped silicon substrate, wherein the at least one fine grid line contacts the at least one busbar. The symmetric solar cell may further comprise a tabbing wire contacting the metal layer of the at least one fine grid line, wherein the tabbing wire comprises a metal core and a solder coating and wherein the metal layer of the at least one fine grid line comprises, consists of, or consists essentially of Cu.

In an embodiment, set forth herein is an asymmetric solar cell comprising a silicon substrate having a front, light-facing surface and a rear surface, wherein the rear surface is opposite of the light-facing surface; at least one passivation layer directly on at least a portion of the rear surface of the silicon substrate; at least one first fine grid line on at least a portion of the rear surface of the silicon substrate; and at least one second fine grid line on at least a portion of the rear surface of the silicon substrate. The at least one first fine grid line or the at least one second fine grid line is a first conductive multilayer line comprising at least two conductive multilayer stacks; wherein a conductive multilayer stack of the at least two conductive multilayer stacks comprises: a metal layer; a silver contact pad comprising a silver sublayer and a glass frit sublayer, wherein the silver sublayer is on the glass frit sublayer; and a solderable layer between, and contacting, the metal layer and the silver contact pad; wherein the glass frit sublayer of the conductive multilayer stack contacts the rear surface of the silicon substrate, contacts the at least one passivation layer, or contacts a combination thereof. The metal layer of the conductive multilayer stack is a continuous layer that connects the at least two conductive multilayer stacks of the first conductive multilayer line. The metal layer comprises copper (Cu) or coated aluminum. The metal layer may be laser cut. The asymmetric solar cell may further comprise at least one first interconnection pad contacting the at least one first fine grid line; and at least one second interconnection pad contacting the at least one second fine grid line; wherein the at least one first interconnection pad is a third conductive multilayer line comprising at least two conductive multilayer stacks; and wherein the at least one second interconnection pad is a fourth conductive multilayer line comprising at least two conductive multilayer stacks. The rear surface of the doped silicon substrate may further comprise at least one doped layer, wherein the at least one doped layer comprises at least one doped region and at least one oppositely-doped region. The at least one passivation layer may comprise a tunnel oxide layer, a doped layer on at least a portion of the tunnel oxide layer, and at least one SiOxNy passivation layer on at least a portion of the doped layer. The at least one passivation layer may comprises SiOx, AlOx, or SiOxNy.

In an embodiment, set forth herein is an asymmetric solar cell comprising a silicon substrate having a front, light-facing surface and a rear surface, wherein the rear surface is opposite of the light-facing surface; at least one passivation layer on at least a portion of the rear surface of the silicon substrate, wherein the at least one passivation layer comprises an intrinsic amorphous layer on at least a portion of the substrate and a doped layer on at least a portion of the intrinsic amorphous layer, wherein the doped layer comprises at least one doped region and at least one oppositely-doped region; a transparent conductive oxide layer on at least a portion of the at least one passivation layer; at least one first fine grid line on at least a portion of the transparent conductive oxide layer; at least one second fine grid line on at least a portion of the transparent conductive oxide layer. At least one of the at least one first fine grid line or the at least one second fine grid line is a first conductive multilayer line comprising at least two conductive multilayer stacks; wherein a conductive multilayer stack of the at least two conductive multilayer stacks comprises a metal layer; a silver contact pad comprising a silver sublayer and no glass frit; and a solderable layer between, and contacting, the metal layer and the silver contact pad; wherein the silver contact pad of the conductive multilayer stack contacts at least a portion of the transparent conductive oxide layer. The metal layer of the conductive multilayer stack is a continuous layer that connects the at least two conductive multilayer stacks of the first conductive multilayer line. The metal layer comprises copper (Cu) or coated aluminum. The metal layer may be laser cut. The asymmetric solar cell may further comprise at least one first interconnection pad contacting the at least one first fine grid line; and at least one second interconnection pad contacting the at least one second fine grid line; wherein the at least one first interconnection pad is a third conductive multilayer line comprising at least two conductive multilayer stacks; and wherein the at least one second interconnection pad is a fourth conductive multilayer line comprising at least two conductive multilayer stacks. The asymmetric solar cell may further comprise at least one first solder pad on at least a first portion of the front, rear, or front and rear surface of the silicon substrate and at least one second solder pad on at least a second portion of the front, rear, or front and rear surface of the silicon substrate, wherein the at least one first fine grid line contacts the at least one first solder pad, and wherein the at least one second fine grid line contacts the at least one second solder pad.

In an embodiment, set forth herein is a solar cell module comprising a first solar cell and a second solar cell; an interconnect that connects the first solar cell and the second solar cell. The first solar cell and the second solar cell comprise a doped silicon substrate having a front surface and a rear surface, wherein the front surface is a light-facing surface, and the rear surface is opposite of the light-facing surface; at least one passivation layer directly on at least a portion of the front surface, the rear surface, or both the front and rear surface of the doped silicon substrate; and at least one fine grid line on a portion of the front surface, the rear surface, or both the front and rear surface of the doped silicon substrate. The at least one fine grid line is a conductive multilayer line comprising at least two conductive multilayer stacks, the conductive multilayer stack of the at least two conductive multilayer stacks comprising a metal layer; a silver contact pad comprising a silver sublayer and a glass frit sublayer, wherein the silver sublayer is on the glass frit sublayer; and a solderable layer between, and contacting, the metal layer and the silver contact pad; and wherein the glass frit sublayer of the conductive multilayer stack contacts at least a portion of silicon substrate, contacts at least one passivation layer, or contacts a combination thereof. The metal layer of the conductive multilayer stack is a continuous layer that connects the at least two conductive multilayer stacks of the conductive multilayer line. The metal layer comprises copper (Cu) or coated aluminum. The metal layer may be laser cut. The first solar cell and the second solar cell may further comprise at least one solder pad on a portion of the front, the rear, or both the front and rear surface of the doped silicon substrate; and at least one busbar on a portion of the front, rear, or both front and rear surface of the doped silicon substrate, wherein the at least one busbar contacts the at least one solder pad, wherein the interconnect comprises a first tabbing wire that contacts the at least one solder pad on the first solar cell and the at least one solder pad on the second solar cell, and a bus ribbon that contacts the first tabbing wire. The interconnect may comprise a first interconnection pad on the first solar cell and a second interconnection pad on the second solar cell, wherein the first interconnection pad contacts the second interconnection pad to form a contact. The interconnect may comprise at least one first tabbing wire that contacts the at least one fine grid line on the first solar cell or the at least one fine grid line on the second solar cell, wherein the at least one first tabbing wire comprises a metal core and a solder coating, and wherein the interconnect further comprises a bus ribbon contacting the at least one first tabbing wire. The at least one passivation layer may comprise a tunnel oxide layer, a doped layer on at least a portion of the tunnel oxide layer, and at least one SiOxNy passivation layer on at least a portion of the doped layer. The at least one passivation layer may comprises SiOx, AlOx, or SiOxNy.

In an embodiment, set forth herein is a solar cell module comprising a first solar cell and a second solar cell; an interconnect that connects the first solar cell and the second solar cell. The first solar cell and the second solar cell comprise a doped silicon substrate having a front surface and a rear surface, wherein the front surface is a light-facing surface, and the rear surface is opposite of the light-facing surface; at least one passivation layer directly on at least a portion of the front surface, the rear surface, or both the front and rear surface of the silicon substrate, wherein the at least one passivation layer comprises an intrinsic amorphous layer on at least a portion of the doped silicon substrate and a doped layer on at least a portion of the intrinsic amorphous layer; a transparent conductive oxide layer on at least a portion of the at least one passivation layer; and at least one fine grid line on at least a portion of the front surface, the rear surface, or both the front and rear surface of the doped silicon substrate. The at least one fine grid line is a conductive multilayer line comprising at least two conductive multilayer stacks, a conductive multilayer stack of the at least two conductive multilayer stacks comprising a metal layer; a silver contact pad comprising a silver sublayer and no glass frit; and a solderable layer between, and contacting, the metal layer and the silver contact pad; and wherein the silver contact pad of the conductive multilayer stack contacts at least a portion of the transparent conductive oxide layer. The metal layer of the conductive multilayer stack is a continuous layer that connects the at least two conductive multilayer stacks of the conductive multilayer line. The metal layer comprises copper (Cu) or coated aluminum. The metal layer may be laser cut. The first solar cell and the second solar cell may further comprise at least one solder pad on at least a portion of the front, rear, or front and rear surface of the doped silicon substrate; and at least one busbar on at least a portion of the front, rear, or front and rear surface of the doped silicon substrate, wherein the at least one busbar contacts the at least one solder pad, wherein the interconnect comprises a first tabbing wire contacting the at least one solder pad on the first solar cell and the at least one solder pad on the second solar cell, and a bus ribbon that contacts the first tabbing wire. The interconnect may comprise a first interconnection pad on the first solar cell and a second interconnection pad on the second solar cell, wherein the first interconnection pad contacts the second interconnection pad to form a contact. The interconnect may comprise at least one first tabbing wire that contacts the at least one fine grid line on the first solar cell or the second solar cell, wherein the at least one first tabbing wire comprises a metal core and a solder coating, and wherein the interconnect further comprises a bus ribbon contacting the at least one first tabbing wire.

In an embodiment, set forth herein is a solar cell module comprising a first solar cell and a second solar cell; an interconnect that connects the first solar cell and the second solar cell. The first solar and the second solar cell comprise a silicon substrate having a front, light-facing surface and a rear surface, wherein the rear surface is opposite of the light-facing surface; at least one passivation layer directly on at least a portion of the rear surface of the silicon substrate; at least one first fine grid line on at least a portion of the rear surface of the silicon substrate; and at least one second fine grid line on at least a portion of the rear surface of the silicon substrate. The at least one first fine grid line, the at least one second fine grid line, or both is (are) a first conductive multilayer line comprising at least two conductive multilayer stacks; and wherein a conductive multilayer stack of the at least two conductive multilayer stacks comprises a metal layer; a silver contact pad comprising a silver sublayer and a glass frit sublayer, wherein the silver sublayer is on the glass frit sublayer; and a solderable layer between, and contacting, the metal layer and the silver contact pad; wherein the glass frit sublayer of the conductive multilayer stack is on the silicon substrate, is on the at least one passivation layer, or is on a combination thereof. The metal layer of the conductive multilayer stack is a continuous layer that connects the at least two conductive multilayer stacks. The metal layer comprises copper (Cu) or coated aluminum. The metal layer may be laser cut. The interconnect may comprise at least one first interconnection pad on the first solar cell contacting the at least one first fine grid line; at least one second interconnection pad on the second solar cell contacting the at least one second fine grid line; wherein the at least one first interconnection pad is connected to the at least one second interconnection pad. The solar cell module may further comprise at least one first solder pad on a portion of the front, rear, or both front and rear surface of the silicon substrate on the first solar cell and at least one second solder pad on a portion of the front, rear, or front and rear surface of the silicon substrate on the second solar cell, wherein the at least one first fine grid line on the first solar cell contacts the at least one first solder pad; and wherein at least one second fine grid line on the second solar cell contacts the at least one second solder pad; wherein the interconnect comprises a tabbing wire that contacts the at least one first solder pad on the first solar cell and the at least one second solder pad on the second solar cell, and wherein a bus ribbon contacts the tabbing wire. The rear surface of the doped silicon substrate may further comprise at least one doped layer, wherein the at least one doped layer comprises at least one doped region and at least one oppositely-doped region. The at least one passivation layer may comprise a tunnel oxide layer, a doped layer on at least a portion of the tunnel oxide layer, and at least one SiOxNy passivation layer on at least a portion of the doped layer. The at least one passivation layer may comprises SiOx, AlOx, or SiOxNy.

In an embodiment, set forth herein is a solar cell module comprising a first solar cell and a second solar cell; an interconnect that connects the first solar cell and the second solar cell. The first solar cell and the second solar cell comprise a silicon substrate having a front, light-facing surface and a rear surface, wherein the rear surface is opposite of the light-facing surface; at least one passivation layer directly on at least a portion of the rear surface of the silicon substrate, wherein the at least one passivation layer comprises an intrinsic amorphous layer on at least a portion of the substrate and a doped layer on at least a portion of the intrinsic amorphous layer, wherein the doped layer comprises at least one doped region and at least one oppositely doped region; a transparent conductive oxide layer on at least a portion of the at least one passivation layer; at least one first fine grid line on at least a portion of the transparent conductive oxide layer; and at least one second fine grid line on at least a portion of the transparent conductive oxide layer. At least one of the at least one first fine grid line or the at least one second fine grid line is a first conductive multilayer line comprising at least two conductive multilayer stacks, wherein a conductive multilayer stack of the at least two conductive multilayer stacks comprises a metal layer; a silver contact pad comprising a silver sublayer and no glass frit; and a solderable layer between, and contacting, the metal layer and the silver contact pad; wherein the silver contact pad of the conductive multilayer stack contacts at least a portion of the transparent conductive oxide layer. The metal layer of the conductive multilayer stack is a continuous layer that connects the at least two conductive multilayer stacks. The metal layer comprises copper (Cu) or coated aluminum. The metal layer may be laser cut. The interconnect may comprise at least one first interconnection pad on the first solar cell contacting the at least one first fine grid line; at least one second interconnection pad on the second solar cell contacting the at least one second fine grid line; wherein the at least one first interconnection pad is connected to the at least one second interconnection pad. The solar cell module may further comprise at least one first solder pad on at least a portion of the front, rear, or front and rear surface of the silicon substrate on the first solar cell and at least one second solder pad on at least a portion of the front, rear, or front and rear surface of the silicon substrate on the second solar cell, wherein the at least one first fine grid line on the first solar cell contacts the at least one first solder pad, wherein the at least one second fine grid line on the second solar cell contacts the at least one second solder pad, and wherein the interconnect comprises a tabbing wire that contacts the at least one first solder pad on the first solar cell and the at least one second solder pad on the second solar cell, and wherein a bus ribbon contacts the tabbing wire.

In an embodiment, set forth herein is a method for forming a conductive multilayer stack comprising providing a silicon substrate having at least one passivation layer on a front and/or a rear surface of the silicon substrate; forming a silver contact pad comprising a silver sublayer and a glass frit sublayer, wherein the silver sublayer is on the glass frit sublayer; forming a solderable layer by applying a solderable paste on the silver contact pad; applying a metal layer comprising copper (Cu) or coated aluminum on the solderable layer; and heating the metal layer to mechanically join the metal layer to the solderable layer and the solderable layer to the silver contact pad; wherein the glass frit sublayer of the conductive multilayer stack contacts at least one portion of the silicon substrate, contacts at least one portion of the at least one passivation layer, or contacts a combination thereof.

In an embodiment, set forth herein is a method for forming a conductive multilayer line comprising providing a silicon substrate having at least one passivation layer; forming a discontinuous line of silver contact pads, wherein a silver contact pad of the discontinuous line of silver contact pads comprises a silver sublayer and a glass frit sublayer, wherein the silver sublayer is on the glass frit sublayer; forming a discontinuous line of solderable pads by applying a discontinuous line of solderable paste on and aligned with the discontinuous line of silver contact pads; applying a metal layer comprising copper (Cu) or coated aluminum on the discontinuous line of solderable pads; and heating the metal layer to mechanically join the metal layer to the discontinuous line of solderable pads and the discontinuous line of solderable pads to the discontinuous line of silver contact pads; wherein the glass frit sublayers of the discontinuous line of silver contact pads contacts at least one portion of the silicon substrate, contact at least one portion of the at least one passivation layer, or contact a combination thereof. The method may further comprise mechanically joining a tabbing wire to the metal layer of the conductive multilayer stack or the conductive multilayer line, wherein the tabbing wire comprises a metal core and a solder coating, wherein the metal layer of the conductive multilayer stack or the conductive multilayer line comprises, consists of, or consists essentially of Cu.

In an embodiment, set forth herein is a method for forming a conductive multilayer stack comprising providing a silicon substrate having at least one passivation layer, and a transparent conductive oxide layer thereon, on a front and/or a rear surface of the silicon substrate; forming a silver contact pad, wherein the silver contact pad does not comprise a glass frit; forming a solderable layer by applying a solderable paste on the silver contact pad; applying a metal layer comprising copper (Cu) or coated aluminum on the solderable layer; and heating the metal layer to mechanically join the metal layer to the solderable layer and the solderable layer to the silver contact pad; wherein the silver contact pad is on at least one portion of the transparent conductive oxide layer.

In an embodiment, set forth herein is a method for forming a conductive multilayer line comprising providing a silicon substrate having at least one passivation layer and a transparent conductive oxide layer on the at least one passivation layer; forming a discontinuous line of silver contact pads, wherein a silver contact pad of the discontinuous line of silver contact pad does not comprise a glass frit; forming a discontinuous line of solderable pads by applying a discontinuous line of solderable paste on and aligned with the discontinuous line of silver contact pads; applying a metal layer comprising copper (Cu) or coated aluminum on the discontinuous line of solderable pads; and heating the metal layer to mechanically join the metal layer to the discontinuous line of solderable pads and the discontinuous line of solderable pads to the discontinuous line of silver contact pads; wherein the silver contact pad is on least one portion of the transparent conductive oxide layer. The method may further comprise laser cutting the metal layer into a pattern prior to applying the metal layer. The method may further comprise mechanically joining a tabbing wire to the metal layer of the conductive multilayer stack or the conductive multilayer liner, wherein the tabbing wire comprises a metal core and a solder coating, wherein the metal layer comprises Cu, and wherein the tabbing wire comprises a metal core and a solder coating.

These and other features, aspects, and advantages of the present disclosure will be apparent from a reading of the following detailed description together with the accompanying drawings, which are briefly described below. This disclosure is intended to be read holistically such that any separable features or elements of the disclosed disclosure, in any of its various aspects and embodiments, should be viewed as intended to be combinable unless the context clearly dictates otherwise.

### BRIEF DESCRIPTIONS OF THE DRAWINGS

The foregoing aspects and others will be readily appreciated by the skilled artisan from the following description of illustrative embodiments when read in conjunction with the accompanying drawings. The drawings are illustrative only and are not intended to be exhaustive or to limit the disclosure herein.

FIG. 1 is a schematic of an example silicon solar cell.

FIG. 2 is a cross-section schematic of an example conductive multilayer stack (CMS) disposed on a silicon substrate, consistent with some embodiments of the present disclosure.

FIG. 3 is a schematic of an example silicon solar cell comprising silver contact pads, busbars, and solder pads, consistent with some embodiments of the present disclosure.

FIG. 4 is a schematic of an example silicon solar cell comprising silver contact pads and solder pads, consistent with some embodiments of the present disclosure.

FIG. 5 is a schematic of an example asymmetric solar cell using continuous silver fine grid lines and solder pads.

FIG. 6 is a schematic of an example asymmetric solar cell comprising silver contact pads, consistent with some embodiments of the present disclosure.

FIGS. 7A-7C are top-view images of different stages of fabricating an example CMS on a silicon substrate, consistent with some embodiments of the present disclosure.

FIG. 7D is a height map of an example CMS on a silicon substrate, consistent with some embodiments of the present disclosure.

FIG. 8 is a cross-section schematic of an example conductive multilayer line disposed on a silicon substrate, consistent with some embodiments of the present disclosure.

FIG. 9A-9C are top-view images of a metal layer of an example CMS with horizontal laser cuts, consistent with some embodiments of the present disclosure.

FIG. 9D is a top-view image of a metal layer of an example CMS cut with a laser, consistent with some embodiments of the present disclosure.

FIG. 9E is a height map of a metal layer of an example CMS cut with a laser, consistent with some embodiments of the present disclosure.

FIG. 10A is a cross-section schematic of a metal layer of an example CMS cut with a laser, consistent with some embodiments of the present disclosure.

FIG. 10B is a top-view schematic of a metal layer of FIG. 10A, consistent with some embodiments of the present disclosure.

FIG. 11 is a schematic of an example silicon solar cell comprising conductive multilayer lines, busbars, and solder pads on a silicon wafer, consistent with some embodiments of the present disclosure.

FIG. 12 is a schematic of an example silicon solar cell comprising conductive multilayer lines and solder pads on a silicon wafer, consistent with some embodiments of the present disclosure.

FIG. 13 is a schematic of an example solar cell module comprising silicon solar cells and tabbing wires electrically connected to solder pads of the solar cells, consistent with some embodiments of the present disclosure.

FIG. 14 is a schematic of an example silicon solar cell comprising silver contact pads, consistent with some embodiments of the present disclosure.

FIG. 15 is a schematic of an example silicon solar cell comprising conductive multilayer lines, consistent with some embodiments of the present disclosure.

FIG. 16A is a schematic of an example silicon solar cell comprising conductive multilayer lines, consistent with some embodiments of the present disclosure.

FIG. 16B is a schematic of two example solar cells of FIG. 16A connected in series, consistent with some embodiments of the present disclosure.

FIG. 17 is a schematic of an example solar cell module comprising silicon solar cells with conductive multilayer lines, connected in series via interconnection pads, and electrically connected by bus ribbons, consistent with some embodiments of the present disclosure.

FIG. 18A is a schematic of an example asymmetric solar cell comprising conductive multilayer lines, consistent with some embodiments of the present disclosure.

FIG. 18B is a schematic of two example asymmetric solar cells of FIG. 18A connected in series, consistent with some embodiments of the present disclosure.

FIG. 19 is a schematic of an example asymmetric solar cell interconnection scheme, consistent with some embodiments of the present disclosure.

FIG. 20 is a cross-section schematic of an example conductive multilayer line disposed on a silicon substrate with a tabbing wire, consistent with some embodiments of the present disclosure.

FIG. 21A is a top-view image of a solar cell comprising a plurality of silver contact pads, consistent with some embodiments of the present disclosure.

FIG. 21B is a top-view image of a solar cell as illustrated in FIG. 21A that contains conductive multilayer lines, consistent with some embodiments of the present disclosure.

FIG. 21C is a top-view image of a solar cell as illustrated in FIG. 21A that contains tabbing wire and conductive multilayer lines, consistent with some embodiments of the present disclosure.

### DETAILED DESCRIPTION

Reference will now be made in detail to exemplary embodiments, examples of which are illustrated in the accompanying drawings. The following disclosure refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments. The present disclosure includes any combination of two, three, four, or more of the exemplary embodiments as well as combinations of any two, three, four, or more features or elements set forth in this disclosure, regardless of whether such features or elements are expressly combined in a specific embodiment description herein. Other aspects and advantages of the present disclosure will become apparent from the following.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the terms “or” and “and/or” encompass all possible combinations, except where infeasible. For example, if it is stated that a component may include A or B, then, unless specifically stated otherwise or infeasible, the component may include A, or B, or A and B. As a second example, if it is stated that a component may include A, B, and/or C, then, unless specifically stated otherwise or infeasible, the component may include A, or B, or C, or A and B, or A and C, or B and C, or A and B and C.

As used herein, the term “about” means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 5%. All numeric values are modified by the term “about” whether or not explicitly indicated. Numeric values modified by the term “about” include the specific identified value. For example, “about 100” means a number ranging from 95 to 105, including 95, 100, and 105. Recitation of ranges of values herein are merely intended to serve as a shorthand method of referring individually to each separate value falling within the range, unless otherwise indicated herein, and each separate value is incorporated into the specification as if it were individually recited herein.

In describing a relationship between components, the preposition “on” is used herein to mean that the components may or may not be in direct contact with one another (e.g., in physical contact). For example, if it is stated that a particular component (e.g., a layer) is on a substrate, then, unless specifically stated otherwise or infeasible, there may be one or more additional components (e.g., one or more additional layers) between the particular component and the substrate. As used herein, the expression “directly on” is understood to mean that components are, at least in part, in direct contact with one another. For example, if it is stated that a particular component (e.g., a layer) is directly on a substrate, then, unless specifically stated otherwise or infeasible, at least a portion of the particular component is positioned directly on and contacting the substrate.

In describing a “doped” component of a solar cell, the term “doped” may be understood to mean any concentration of a dopant. For example, a doped layer of a solar cell may be understood to contain any concentration of an n-type dopant or a p-type dopant. In describing a dopant concentration for a component of a solar cell, the term “highly doped” may be understood to mean a dopant concentration greater than or equal to 10¹⁸ cm⁻³. For example, a highly doped layer may have a dopant concentration from 10¹⁸ cm⁻³ to 10²⁰ cm⁻³. If it is stated that a component is “moderately doped,” then, unless specifically stated otherwise or infeasible, the dopant concentration of the component is from 10¹⁶ cm⁻³ to less than 10¹⁸ cm⁻³. If it is stated that a component is “lightly doped,” then, unless specifically stated otherwise or infeasible, the dopant concentration of the component is less than 10¹⁶ cm⁻³. For example, a lightly doped layer may have a dopant concentration from 10¹⁴ cm⁻³ to less than 10¹⁶ cm⁻³.

As used herein, the term “portion” may be understood to mean an entire component or any sub-range or fraction thereof. For example, a portion of a substrate front surface may be understood to mean the entire substrate front surface, ½ of the substrate front surface, ⅓ of the substrate front surface, ¼ of the substrate front surface, or any other area fraction of the substrate front surface. As another example, if it stated that a component is “on at least a portion” of a substrate rear surface, then, unless specifically stated otherwise or infeasible, the component may be on the entire substrate rear surface or may be on an a fraction of the total area of the substrate rear surface.

A substrate may be a solid, planar, rigid, inorganic material. In some embodiments, a substrate includes at least one material selected from silicon, silicon carbide, aluminum oxide, sapphire, germanium, gallium arsenide, gallium nitride, diamond, and indium phosphide, and combinations thereof. Such substrates are commonly used for deposition of films to manufacture transistors, light emitting diodes, integrated circuits, and photovoltaic cells. Substrates may be single crystal (monocrystalline) or multicrystalline (polycrystalline). Substrates can be doped either p-type or n-type by adding small quantities of dopants (e.g., boron, aluminum, or gallium for p-type silicon, and phosphorous, arsenic, or antimony for n-type silicon). In some embodiments, the substrate is doped with at least one material selected from boron, aluminum, gallium, indium, thallium, phosphorous, arsenic, antimony, bismuth, alloys thereof, composites thereof, and combinations thereof. Doping semiconducting substrates is a commonly known technique in the art. Silicon is the most used light absorbing substrate for photovoltaic cells and these substrates are generally referred to as silicon wafers. It is appreciated that the terms “silicon substrate” and “silicon wafer” are used interchangeably in this disclosure.

Solar cells (also known as photovoltaic cells) convert light energy into electricity through the photovoltaic effect. Solar cells use PN junctions (e.g., p-type silicon base with a heavily doped n-type layer at a surface) to separate electron and hole carriers in the solar cell, creating a voltage to do useful work. Solar cell power conversion efficiencies can be optimized by maximizing light absorption into the silicon and by minimizing minority carrier recombination and resistive losses. Silicon substrates for solar cells are generally from 120 μm to 180 μm thick and lightly doped (10¹⁵-10¹⁷ cm⁻³) either p- or n-type. In some embodiments, the substrate of a solar cell may have a region doped p-type and another region doped n-type, forming a PN junction within the substrate. In some embodiments, the substrate of a solar cell may be an n-type doped substrate and a p-type region may be formed at a surface of the n-type doped substrate (e.g., a p-type emitter layer for a TOPCon solar cell). It is desirable to reduce silicon substrate thickness below 90 μm to reduce manufacturing costs, improve efficiency, and improve solar cell flexibility, but such thin silicon substrates currently increase instances of wafer cracking during fabrication.

### Passivation Layers on Silicon Solar Cells

Silicon has a high index of refraction resulting in a strong reflection of light in the visible spectrum, and bare silicon surfaces have high surface recombination velocity. Passivation layers are used to reduce the surface recombination velocity and to improve light absorption by varying the index of refraction. In some embodiments, the passivation layer comprises at least one material selected from silicon (Si), nitrogen (N), aluminum (Al), oxygen (O), germanium (Ge), hafnium (Hf), gallium (Ga), composites thereof, and combinations thereof on the substrate surface. Silicon dioxide and suboxides (SiOₓ) are passivation layers that can be controllably grown from 1 nm to 5 nm on silicon wafers at high temperature in the presence of oxygen. Aluminum oxides and suboxides (AlOₓ) may be used in a passivation layer for p-type silicon and may be grown via, for example, atomic layer deposition (ALD) or plasma enhanced chemical vapor deposition (PECVD). It may be desirable to minimize AlOₓ thickness to approximately 4 nm-5 nm, which can be more controllably deposited via ALD. In some embodiments, at least one passivation layer comprises alumina with a thickness from 1 nm to 5 nm. In some examples, SiOₓ can be grown in ALD systems prior to deposition of AlOₓ for p-type silicon surfaces. Polycrystalline silicon (poly-Si) in conjunction with SiOₓ may also be used in passivation layers for solar cells. Poly-Si can be deposited in a variety of methods including, but not limited to, low pressure chemical vapor deposition (LPCVD) that allows for in-situ, n-type doping using phosphorous (n⁺ poly-Si). This passivation strategy may be useful when applied to the n-type side of certain cell architectures such as TOPCon. The poly-Si thickness may be from 50 to 200 nm and doping density may be optimized to minimize recombination and contact resistance. Silicon nitride (SiNₓ) and silicon oxynitride (SiON) with varying compositions of silicon, nitrogen, and oxygen can also be used to adjust the index of refraction to reduce light reflection at the silicon surface. Multiple graded SiNₓ layers and a SiON capping layer with a total film thickness from 50 to 100 nm or from 70 to 80 nm may be used to minimize reflections. SiNₓ can also be used in conjunction with SiOₓ to further reduce the surface recombination velocity on n-type silicon. Hydrogenated versions of the passivation layers may also be incorporated to improve chemical surface passivation or reliability under irradiation, heat, and/or humidity. In some embodiments, the at least one passivation layer may comprise an intrinsic amorphous layer and a doped layer, such as an amorphous doped layer. This passivation strategy may be useful when applied to either the front or rear side of certain cell architectures such as HJT. For an HJT solar cell, the at least one passivation layers on the front and/or rear surface of a silicon substrate may include, but are not limited to, a 2-5 nm layer of hydrogenated, intrinsic amorphous silicon (a-Si: H(i)) and a 10-50 nm layer of doped, hydrogenated amorphous silicon layer (a-Si: H). The HJT solar cell may further include a transparent conductive oxide (TCO) layer on the at least one passivation layers. It is appreciated that the above-mentioned passivation layers should not be construed as limiting. The index of refraction for the above-mentioned passivation layers is well known and the thickness of individual passivation layers and passivation layer stacks can be measured using, for example, ellipsometry techniques. See Shah, Arvind, ed. Solar Cells and Modules. Springer International Publishing, 2020, which is incorporated by reference herein in its entirety. SiOxNy, SiOₓ and AlOₓ materials may be found in Shah, Arvind, ed. Solar Cells and Modules.

### Solar Cell Architectures

In some embodiments, PERC solar cells may be made with a doped substrate with a thin (30 nm-200 nm), oppositely doped layer in the front surface. In some embodiments, the thin, oppositely doped layer may be a doped region in the front surface of the substrate. In some embodiments, the substrate may be p-type and the thin, oppositely doped layer is n⁺-type. In some embodiments, the thin, oppositely doped layer comprises phosphorus. SiOₓ (1 nm-5 nm) and SiNₓ/SiON (50 nm-100 nm) may be used to passivate the front (n⁺ type) surface and SiOₓ (1 nm-5 nm), AlOₓ (2 nm-7 nm), and/or SiNₓ/SiON (50 nm-100 nm) may be used to passivate the rear (p-type) surface. In some embodiments, the PERC solar cell further comprises an AlOₓ (1 nm-5 nm) layer between the SiOₓ and the SiNₓ/SiON passivation layers on the front surface. In some embodiments, AlOₓ (1 nm-5 nm) and SiNₓ/SiON (50 nm-100 nm) layers may be used to passivate the rear (p-type) surface.

In some embodiments, TOPCon solar cells may be made with a doped substrate with a thin (30 nm-200 nm), oppositely doped layer in the front surface. In some embodiments, the thin, oppositely doped layer may be a doped region in the front surface of the substrate. In some embodiments, the substrate may be n-type and the thin, oppositely doped layer is p⁺-type. In some embodiments, the thin, oppositely doped layer comprises phosphorus. In some embodiments, at least one passivation layer may be used to passivate a front and/or rear surface of a TOPCon solar cell. In some embodiments, layers of SiOₓ (1 nm-5 nm), AlOₓ (2 nm-7 nm), and SiN/SiON (50 nm-100 nm) may be used to passivate the front (p⁺-type) surface and layers of SiOₓ (1 nm-5 nm), n⁺ poly-Si (50 nm-200 nm), AlOₓ (2 nm-7 nm), and SiN/SiON (50 nm-100 nm) may be used to passivate the rear (n-type) surface. In some embodiments, layers of SiOₓ (1 nm-5 nm), n⁺ poly-Si (50-200 nm), and/or SiNₓ/SiON (50-100 nm) are used to passivate the rear side.

It is appreciated that the above-mentioned embodiments should not be construed as limiting. Those skilled in the art are aware of other cell architectures and deposition techniques to reduce recombination of silicon cells. Herein, “+” in “p⁺” or “n⁺” is used to denote a highly doped layer (e.g., >10¹⁸ cm⁻³). It should be noted that solar cells described in this present disclosure can be used in bifacial modules, which absorb light on both sides of the solar cell. Bifacial cells may be designed to minimize metallization area on the rear side of a solar cell, increase available surface area to improve light absorption, and reduce the thickness of passivation layers to improve light absorption.

In some embodiments, HJT solar cells may be made with a doped substrate with a 2-5 nm hydrogenated, intrinsic, amorphous silicon (a-Si: H(i)), a 10-50 nm doped, hydrogenated amorphous silicon layer (a-Si: H), and a transparent conductive oxide (TCO) layer on the front surface, and a-Si: H(i), 10-50 nm, doped, hydrogenated amorphous silicon layer (a-Si: H) and a TCO layer on the rear surface. In some embodiments, the substrate is n-type. In some embodiments, the doped, hydrogenated, amorphous silicon on the front surface is p-type and the doped, hydrogenated, amorphous silicon layer on the rear surface is n⁺-type. In some embodiments, the doped, hydrogenated, amorphous silicon layer on the front surface is n⁺-type and the doped, hydrogenated, amorphous silicon layer on the rear surface is p-type. In some embodiments, the TCO layer is typically from 50 to 100 nm thick and made of indium tin oxide.

It should be noted that similar passivation schemes may be used for asymmetric solar cells such as, but not limited to, interdigitated back contact (IBC) cells. In some embodiments, the IBC solar cells may be made with a doped substrate, with SiOₓ (1 nm-5 nm), n⁺ poly-Si (50 nm-200 nm), AlOₓ (2 nm-7 nm), and/or SiNₓ/SiON (50 nm-100 nm) used to passivate a portion of the solar cell comprising the rear surface. In some embodiments, the IBC solar cell is p-type. In some embodiments, portions of the rear surface of the IBC solar cell is n-type and portions of the rear surface of the IBC solar cell is p-type.

### Metallization Layers on Silicon Solar Cells

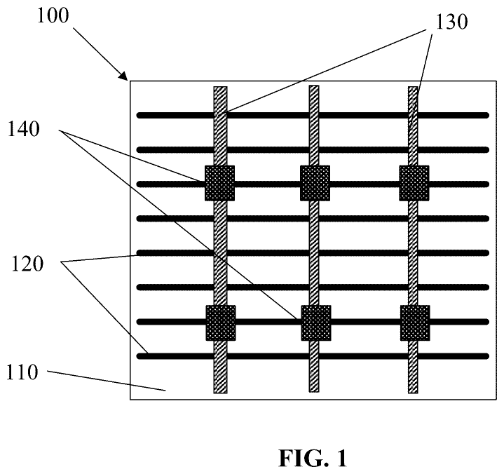

Silicon solar cells comprise multiple metallization layers to transport electric charge from the silicon wafer to the components of a solar cell module. FIG. 1 is a schematic of a conventional silicon solar cell 100 comprising a silicon substrate 110 and three metallization layers: fine grid lines 120, busbars 130, and solder pads 140. Fine grid lines 120 provide Ohmic contact with silicon substrate 110 and transport charge to busbars 130, which are connected to solder pads 140. As used herein, a “fine grid line” (often called “fingers”) may be understood to mean a metallized line directly on a solar cell that collects current from the silicon wafer. As used herein, a “busbar” may be understood to mean a metallized line on a solar cell that is connected to a “fine grid line,” typically runs perpendicular to the “fine grid line,” and transports the collected current from the “fine grid line” to another component of the solar cell or solar module. As used herein, a “solder pad” may be understood to mean a metallized surface of a solar cell that allows an electrical interconnection between solar cells. It is appreciated that, in some embodiments, a “fine grid line” or a “busbar” is a conductive multilayer line, as described herein, or is made of standard materials known in the art. Conventional solar cells are interconnected by soldering wires from the solder pads of one solar cell to the solder pads of adjoining solar cells. Solar cells such as PERC and TOPCon contain fine grid lines, busbars, and solder pads on both front (i.e., light-facing) and rear surfaces of the cell. Solar cells such as IBC cells contain fine grid lines, busbars, and/or solder pads only on a rear surface of the cell. Metallization layers can be fabricated with different metals including silver, aluminum, and copper. Silver is commonly used to fabricate silver fine grid lines, silver busbars, and silver solder pads on solar cells.

Silver metallization layers may be formed on a solar cell by screen printing silver pastes, which are subsequently dried and co-fired. For screen printing, silver pastes are commonly composed of silver particles, glass frits, organic binders, and additives that are well known in the art. During co-firing, the silver metallization layer is annealed in air using a spike fire profile with a peak temperature ranging from 650° C. to 820° C. and a ramp up and cool down rate greater than 10° C./sec. The term “co-fired” describes annealing the silicon substrate at a temperature greater than 400° C., greater than 600° C., or greater than 700° C. for a period from 1 second to 60 minutes, or any range subsumed therein.

During co-firing, glass frits melt and silver particles sinter, resulting in a silver contact layer structure where a thin glass frit sublayer is in contact with a portion of the silicon substrate (or a portion of a passivation layer thereon) and a silver sublayer formed on the thin glass frit sublayer. Glass frits (e.g., bismuth oxide and lead oxide) in silver paste can be designed to etch through passivation layers (e.g., SiNₓ, AlOₓ) to directly contact silicon, which may be useful for fine grid lines. Frits that etch through passivation layers to the silicon surface may reduce Ohmic contact between the silver sublayer and the silicon substrate, and may increase the surface recombination velocity in the etched region, which can lower the open-circuit voltage. It is known that glass frits may be modified to significantly reduce etching of passivation layers and maintain a low surface recombination velocity. These paste formulations may be useful for solder pads and busbars, which do not need to extract charge from silicon wafer. For solder pads and busbars, a silver contact layer is disposed on the silicon substrate and may be in direct contact with the passivation layer or silicon substrate depending on the metallization layer function and frit formulation. The glass frit sublayer comprises at least one material selected from bismuth (Bi), lead (Pb), tin (Sn), tellurium (Te), antimony (Sb), lead (Pb), oxygen (O), thallium (Tl), vanadium (V), silver (Ag), phosphorous (P), silicon (Si), alloys thereof, oxides thereof, composites thereof, and combinations thereof.

The glass frit sublayer may be thin, ranging from 1 nm to 3 μm, from 1 nm to 1 μm, or from 1 nm to 200 nm. The glass frit sublayer is less conductive than the silver sublayer, so it may be desirable to minimize the glass frit sublayer thickness. Thin glass frit sublayers may be discontinuous, and silver may appear to be directly in contact with the silicon wafer when using cross-sectional scanning electron microscopy with energy dispersive x-ray spectroscopy (SEM/EDX). Glass frits are generally designed to have some silver solubility at elevated temperatures resulting in silver precipitate formation inside the frit sublayer and at the silicon/glass frit sublayer interface. The silver precipitates can be measured by performing transmission electron microscopy (TEM) on a cross section of the conductive multilayer stack. The silver precipitates are believed to reduce Ohmic contact between the silver contact layer and the silicon substrate and improve conductivity through the glass frit sublayer.

A thickness of a silver sublayer may range from 3 μm to 30 μm, from 5 μm to 25 μm, from 5 μm to 20 μm, or from 5 μm to 15 μm depending on the metallization layer. The thickness of the silver sublayer may be dependent upon the silver loading in the paste and the printed film thickness. For solder pads, the silver sublayer thickness may be designed to be as thin as possible while maintaining good solderability and adhesion when tabbed, such as by solder coated wires. Silver sublayers for solder pads may have a thickness from 4 μm to 8 μm when using tin-lead based solder wires. For fine grid lines, the silver sublayer thickness may be optimized to minimize silver consumption (e.g., on the front side) while maintaining a low series resistance. Silver layers for fine grid lines may have a thickness from 4 μm to 20 μm. Silver pastes often contain a multimodal distribution of silver particle diameters to increase green film density and minimize porosity during co-firing. The resulting silver sublayer structure may contain small voids and have a porosity less than 15%, less than 10%, less than 5%, or less than 2% by volume. It should be noted that metal layers that are electroplated are solid with porosity less than 0.25% by volume and pores are not generally visible under cross-sectional SEM/EDX. The porosity of various layers can be measured either using a mercury porosimeter such as a CE instrument Pascal 140 (low pressure) or Pascal 440 (high pressure) in a range from 0.01 kPa to 2 MPa. Porosity can also be observed via cross-sectional SEM to identify if any pores exist in the films and image processing such as ImageJ can be used to calculate the porous fraction.

Aluminum metallization layers may also be formed on solar cells by screen printing aluminum pastes, which are subsequently dried and co-fired. Aluminum-based metallization layers have several disadvantages compared silver-based systems. For example, co-fired aluminum layers have a significantly higher bulk resistivity compared to silver layers. Aluminum pastes are made of Al particles that do not completely sinter during firing, thus resulting in lower conductivities. Al particles are generally larger than Ag particles resulting in wider fine grid lines, greater solar cell shadowing, and lower short-circuit current density captured from the solar cell. Furthermore, aluminum forms a eutectic with silicon at 577° C., which forms a highly p-type back-surface field (BSF) that can penetrate microns into the silicon substrate. PN junctions are typically less than 200 nm and can be shunted by the BSF. The BSF has a high defect density resulting in high minority carrier recombination, which may be undesirable.

Meier, et al. describe how to use four-point probe electrical measurements to determine the resistivity of each metallization layer and contribution to the total series resistance on a completed solar cell. See Meier, et al. “Determining components of series resistance from measurements on a finished cell”, IEEE (2006) pp. 1315-1318, which is incorporated by reference herein in its entirety. The bulk resistance of a metallization layer is directly related to the bulk resistance of the material from which it is made. Pure Ag has a bulk resistance 1.5×10⁻⁸ Ω-m, whereas pure Ag metallization layers used for conventional solar cells have a bulk resistance that is 1.2 times to 5 times higher. The bulk resistance may be important for fine grid lines, which must transport current over a relatively long (e.g., more than 1 cm) length. The bulk resistance of the front busbars and rear tabbing layers may be less important when the cells are tabbed in a module.

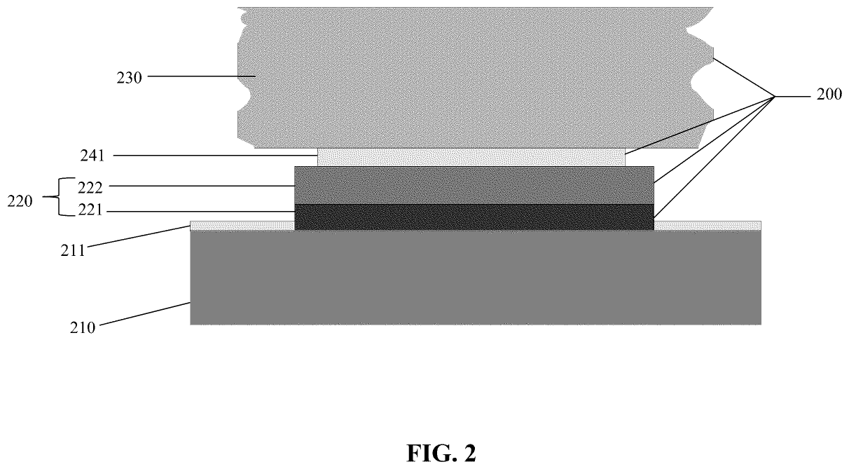

Embodiments of the present disclosure provide a conductive multilayer stack, which may replace silver fine grid lines and busbars in a conventional solar cell and enable a significant reduction in silver consumption in solar cell metallization. Reference is now made to FIG. 2, which is a schematic cross-section of a conductive multilayer stack, consistent with some embodiments of the present disclosure. FIG. 2 illustrates a conductive multilayer stack 200, comprising a metal layer 230, a solderable layer 241, and a silver contact layer 220. In some embodiments, the silver contact layer 220 comprises a glass frit sublayer 221 and a silver sublayer 222 on the glass frit sublayer 221. In some embodiments, silver contact layer 220 may comprise silver sublayer 222 and does not include glass frit sublayer 221. In some embodiments, glass frit sublayer 221 penetrates through at least one passivation layer 211. In some embodiments, glass frit sublayer 221 penetrates through at least one passivation layer 211 and contacts substrate 210. In some embodiments, silver contact layer 220 may be a continuous, thin silver fine grid line (e.g., 5 microns thick). In some embodiments, silver contact layer 220 may be a discrete silver contact pad. Thus, it is understood that silver contact layer 220 may be continuous or discontinuous. In some embodiments, conductive multilayer stack 200 may be disposed on a surface of substrate 210, where the surface of substrate 210 contains at least one passivation layer 211 on a surface (e.g., front surface or rear surface) of substrate 210, and/or disposed on a surface of at least one passivation layer 211 on a surface (e.g., front surface or rear surface) of substrate 210.

In some embodiments, metal layer 230 in FIG. 2 comprises an aluminum layer and at least one corrosion resistant joining (CRJ) layer. In some embodiments, the aluminum layer comprises a 30 μm thick aluminum alloy with low porosity (e.g., less than 0.25%). In some embodiments, the at least one CRJ layer comprises a 50 nm thick titanium layer, wherein the aluminum layer is on the at least one CRJ layer. In some embodiments, the aluminum layer comprises an exposed surface that contains a native oxide and is not solderable. In some embodiments, metal layer 230 comprises a copper layer and does not contain any CRJ layers. In some embodiments, metal layer 230 has a thickness from 4 μm to 100 μm, 4 μm to 50 μm, from 4 μm to 40 μm, from 4 μm to 30 μm, from 4 μm to 25 μm, from 4 μm to 20 μm, from 4 μm to 10 μm, or from 4 μm to 6 μm. In some embodiments, metal layer 230 has a thickness from 4 μm to 100 μm, from 4 μm to 50 μm, from 4 μm to 25 μm, from 4 μm to 10 μm, or from 4 μm to 6 μm. In some embodiments, metal layer 230 has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm or from 50 μm to 75 μm. In some embodiments, silver sublayer 222 has a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm. In some embodiments, solderable layer 241 has a thickness less than 40 μm, less than 30 μm, less than 25 μm, less than 20 μm, or less than 10 μm. In some embodiments, solderable layer 241 has a thickness from 3 μm to 50 μm, from 4 μm to 40 μm, from 4 μm to 30 μm, from 4 μm to 20 μm, or from 4 μm to 10 μm. In some embodiments, solderable layer 241 is a 15 μm thick layer comprising Sn₉₇Cu_{2.75}Ag_{0.25} (SAC305), which is adhered to silver sublayer 222. A SAC305 solder has a higher melting point than SnPb based solders and enables cells to be soldered together using tabbing wires with conventional module manufacturing tools. In some embodiments, solderable layer 241 is a 15 μm thick layer comprising Bi₅₈Sn₄₂ (BiSn), which is adhered to silver sublayer 222. A tin bismuth solder has a low melting point, which may put less thermal stress on the system. Tin bismuth solders are commonly used on tabbing wires to join HJT cells. BiSn solders may be effective for low temperature applications and when eliminating traditional silver solder pads from the solar cell.

In some embodiments, substrate 210 is a silicon substrate for a solar cell and at least one passivation layer 211 is an at least one passivation layer for a solar cell. In some embodiments, at least one passivation layer 211 may comprise a tunnel oxide layer, a doped layer comprising an n-type doped polysilicon (poly-Si) on at least a portion of the tunnel oxide layer, and at least one SiOxNy passivation layer on at least a portion of the doped layer. In some embodiments, glass frit sublayer 221 may penetrate through the at least one SiOxNy passivation layer and contact the doped layer. In some embodiments, the tunnel oxide layer comprises SiOₓ. The at least one SiOxNy passivation layer may comprise SiOₓ, SiN_{y}, SiON, or a combination thereof. In some embodiments, the tunnel oxide layer is from 1 nm to 5 nm thick, the doped layer is from 50 nm to 200 nm thick, and/or the at least one SiOxNy passivation layer is from 50 nm to 100 nm thick.

In some embodiments, at least one passivation layer 211 comprises SiOₓ, AlOₓ, and/or SiOxNy. In some embodiments, at least one passivation layer 211 comprises a first passivation layer comprising SiOₓ and at least one second passivation layer comprising SiOxNy, where the at least one second passivation layer is on at least a portion of the first passivation layer. In some embodiments, at least one passivation layer 211 comprises a first passivation layer comprising AlOₓ and at least one second passivation layer comprising SiOxNy, where the at least one second passivation layer is on at least a portion of the first passivation layer. The at least one second passivation layer comprising SiOxNy may comprise SiOₓ, SiN_{y}, SiON, or a combination thereof. The first passivation layer may be from 1 nm to 5 nm thick and/or the at least one second passivation layer may be from 50 nm to 100 nm thick. In some embodiments, the at least one second passivation layer is directly on the first passivation layer. In some embodiments, an intermediate passivation layer may be between the first passivation layer and the at least one second passivation layer, where the intermediate passivation layer comprises AlOₓ. The intermediate passivation layer may have a thickness ranging from 1 nm to 5 nm. In some embodiments, glass frit sublayer 221 may penetrate through at least one passivation layer comprising SiOₓ, AlOₓ, and/or SiOxNy.

In some embodiments, a surface (e.g., front and/or rear surface) of silicon substrate 210 may further comprise a doped layer (not illustrated) and at least one passivation layer 211 is on the doped layer. Silicon substrate 210 may be doped with a dopant and the doped layer may have a different dopant, a different dopant type, and/or a different dopant concentration from silicon substrate 210. In some embodiments, at least one passivation layer 211 may comprise SiOₓ, AlOₓ, or SiOxNy. In some embodiments, at least one passivation layer 211 comprises a first passivation layer comprising SiOₓ and at least one second passivation layer comprising SiOxNy, where the at least one second passivation layer is on at least a portion of the first passivation layer. In some embodiments, the first passivation layer has a thickness ranging from 1 nm to 5 nm. In some embodiments, the at least one second passivation layer has a thickness ranging from 50 nm to 100 nm. In some embodiments, the at least one second passivation layer is directly on the first passivation layer. In some embodiments, an intermediate passivation layer may be between the first passivation layer and the at least one second passivation layer, where the intermediate passivation layer comprises AlOₓ. The intermediate passivation layer may have a thickness ranging from 1 nm to 5 nm. In some embodiments, glass frit sublayer 221 may penetrate through at least one passivation layer 211 and contacts the doped layer. In some embodiments, the doped layer may be from 30 nm to 200 nm thick. In some embodiments, the doped layer comprises an n-type dopant or a p-type dopant.

In some embodiments, at least one passivation layer 211 and conductive multilayer stack 200 are on a rear surface of silicon substrate 210. In some embodiments, a rear surface of silicon substrate 210 may further comprise at least one doped layer (not illustrated) and at least one passivation layer 211 is on the at least one doped layer. In some embodiments, the at least one doped layer comprises an at least one doped region and at least one oppositely-doped region. The at least one doped region may comprise a p-type dopant and the at least one oppositely-doped region may comprise an n-type dopant, or vice versa. In some embodiments, glass frit sublayer 221 may penetrate through at least one passivation layer 211 and contact the at least one oppositely-doped region. In some embodiments, glass frit sublayer 221 may penetrate through at least one passivation layer 211 and contact the at least one doped region. The at least one doped region or the at least one oppositely-doped region may have a thickness ranging from 30 nm to 200 nm.

In some embodiments, silicon substrate 210 is a silicon substrate for a HJT solar cell and conductive multilayer stack 200 does not comprise glass frit sublayer 221. In some embodiments, at least one passivation layer 211 comprises an intrinsic amorphous layer on at least a portion of silicon substrate 210 and a doped layer on at least a portion of the intrinsic amorphous layer. A transparent conductive oxide layer (not illustrated) may be on at least a portion of the doped layer of at least one passivation layer 211. Silver contact layer 220 may contact at least a portion of the transparent conductive oxide layer. In some embodiments, silicon substrate 210 may be doped and the doped layer may contain a different dopant, a different dopant type, and/or a different dopant concentration from silicon substrate 210. In some embodiments, the doped layer comprises a p-type doped, hydrogenated amorphous silicon (a-Si: H(p)) or an n-type doped, hydrogenated amorphous silicon (a-Si: H(n)). In some embodiments, the transparent conductive oxide layer comprises indium tin oxide. In some embodiments, the intrinsic amorphous layer contacts at least a portion of silicon substrate 210, the doped layer contacts at least a portion of the intrinsic amorphous layer, and the transparent conductive oxide layer contacts at least a portion of the doped layer. In some embodiments, the transparent conductive oxide layer is between and contacts at least a portion of the at least one doped region and at least a portion of silver contact layer 220. In some embodiments, the transparent conductive oxide layer is between and contacts at least a portion of the at least one oppositely-doped region and at least a portion of silver contact layer 220. In some embodiments, at least one passivation layer 211 is on a front and/or rear surface of the silicon substrate for a HJT solar cell. In some embodiments, the doped layer comprises at least one doped region and at least one oppositely-doped region. The at least one doped region may comprise a p-type dopant and the at least one oppositely-doped region may comprise an n-type dopant, or vice versa. In some embodiments, the at least one doped region may be separated from the at least one oppositely-doped region. In some embodiments, a thickness of the intrinsic amorphous layer ranges from 2 nm to 5 nm, a thickness of the doped layer ranges from 10 nm to 50 nm, or a thickness of the transparent conductive oxide layer ranges from 50 nm to 100 nm.

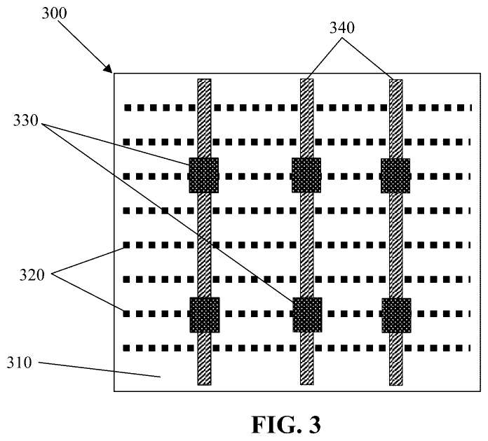

Conductive multilayer stacks of the present disclosure may be fabricated on a solar cell by first manufacturing a silver contact layer (e.g., silver contact layer 220 in FIG. 2). Reference is now made to FIG. 3, which is a schematic of a silicon solar cell comprising silver contact pads, busbars, and solder pads, consistent with some embodiments of the present disclosure. FIG. 3 illustrates a solar cell 300 that comprises a silicon substrate 310, busbars 340 and solder pads 330; however, the continuous fine grid lines conventionally used in solar cells (e.g., fine grid lines 120 in FIG. 1) are replaced by a discontinuous line of silver contact pads 320. It is appreciated that solar cell 300 may comprise at least one passivation layer, as described above, on silicon substrate 310. In some embodiments, the discontinuous line of silver contact pads 320 is a straight line running parallel to an edge of silicon substrate 310. Although not illustrated in FIG. 3, the discontinuous line of silver contact pads 320 can be a zigzag, curved, or any other line shape. In some embodiments, a first silver contact pad of silver contact pads 320 may be separated from a second silver contact pad of silver contact pads 320 by, for example, more than 200 μm, more than 500 μm, more than 1 mm, more than 2 mm, or more than 3 mm. In some embodiments, a first silver contact pad of silver contact pads 320 may be separated from a second silver contact pad of silver contact pads 320 by a distance from 200 μm to 2 mm, from 200 μm to 1 mm, from 300 μm to 1 mm, from 400 μm to 1 mm, or from 400 μm to 900 μm. The first and second silver contact pads of silver contact pads 320 being consecutive silver contact pads in the discontinuous line.

It is appreciated that the description herein for silver contact pads 320 may apply to one or more silver contact pads of silver contact pads 320. In some embodiments, each silver contact pad of silver contact pads 320 may have a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm. In some embodiments, each silver contact pad of silver contact pads 320 may have a length ranging from 30 μm to 250 μm, from 30 μm to 225 μm, from 30 μm to 200 μm, from 30 μm to 175 μm, from 30 μm to 150 μm, from 30 μm to 125 μm, from 30 μm to 100 μm, from 30 μm to 75 μm, from 30 μm to 60 μm, from 30 μm to 50 μm, or from 30 μm to 40 μm. In some embodiments, each silver contact pad of silver contact pads 320 may be square with a length greater than 20 μm, 30 μm, 40 μm, 50 μm, 60 μm, 75 μm, 100μ, 125 μm, 150μ, or 200 μm. Silver contact pads 320 may be of any shape (e.g., circular, rectangular, oblong, etc., or a combination thereof). In some embodiments, each silver contact pad of silver contact pads 320 may have a thickness from 4 μm to 10 μm, or a first silver contact pad of silver contact pads 320 may have a thickness from 4 μm to 10 μm and a second silver contact pad of silver contact pads 320 may have a thickness from 4 μm to 15 μm.

Silver contact pads 320 may be fabricated by modifying the fine grid line screen pattern on screen printing lines to form a desirable size, number, and/or shape. In some embodiments, silver contact pads 320 may comprise a glass frit sublayer (e.g., glass frit sublayer 221 in FIG. 2) and a silver sublayer (e.g., silver sublayer 222 in FIG. 2) on the glass frit sublayer. In some embodiments, silver contact pads 320 may comprise a silver sublayer and no glass frit. It may be desirable to minimize surface area and/or thickness of silver contact pads 320 to reduce silver consumption. Existing silver metallization pastes may be used in conjunction with drying and co-firing to form silver contact pads 320. It may also be desirable to modify existing silver pastes to improve adhesion, passivation layer etching, and/or improve contact resistance. For example, to change thickness, one could change the silver loading in the paste (e.g., from 90 wt. % Ag particles to 85 wt. % Ag particles). As another example, one could change adhesion by changing the loading of glass frit in the paste (e.g., from 1 wt. % to 2 wt. %) or change the type of frit. In some embodiments, one could improve contact resistance by lowering glass frit concentration in the paste and/or changing the glass frit type. Conventional symmetric solar cells may contain from 80 to 200 silver fine grid lines per side and are responsible for the highest silver usage. In contrast, some embodiments of the present disclosure provide a discontinuous line of silver contact pads (e.g., silver contact pads 320 in FIG. 3), which may use 25% less, 50% less, 60% less, 75% less, 90% less, or 95% less silver than continuous fine grid lines in conventional solar cells (e.g., fine grid lines 120 in FIG. 1).

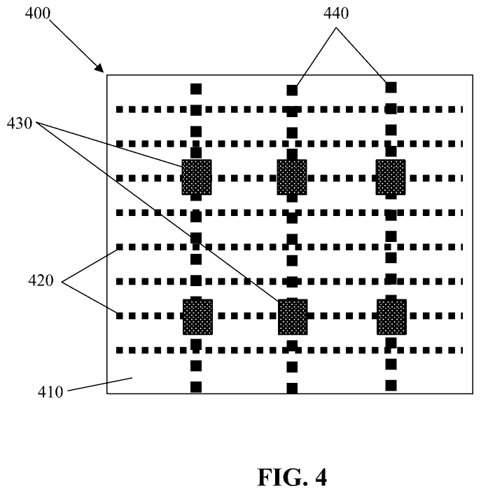

Reference is now made to FIG. 4, which is a schematic of a silicon solar cell 400 comprising a silicon substrate 410, a first plurality of silver contact pads 420, a second plurality of silver contact pads 440, and solder pads 430, consistent with some embodiments of the present disclosure. FIG. 4 illustrates that it is possible to further reduce silver consumption by replacing continuous silver busbars used in conventional solar cells (e.g., busbars 130 in FIG. 1) with second plurality of silver contact pads 440. In some embodiments, second plurality of silver contact pads 440 is a discontinuous line of silver contact pads. It is appreciated that solar cell 400 may comprise at least one passivation layer, as described above, on silicon substrate 410. In some embodiments, the discontinuous line of second plurality of silver contact pads 440 is a straight line running parallel to an edge of silicon substrate 410. Although not illustrated in FIG. 4, the discontinuous line of second plurality of silver contact pads 440 can be a zigzag, curved, or any other line shape. It is appreciated that the description herein for second plurality of silver contact pads 440 may apply to one or more silver contact pads of second plurality of silver contact pads 440. It is further appreciated that in some embodiments, the first plurality of silver contact pads 420 is a discontinuous line of silver contact pads that are perpendicular to the discontinuous line of second plurality of silver contact pads 440. In some embodiments, the silver contact pads of second plurality of silver contact pads 440 may be separated by more than 200 μm, more than 500 μm, more than 1 mm, more than 2 mm, or more than 3 mm. In some embodiments, the silver contact pads of second plurality of silver contact pads 440 may be separated by a distance from 200 μm to 2 mm, from 200 μm to 1 mm, from 300 μm to 1 mm, from 400 μm to 1 mm, or from 400 μm to 900 μm. In some embodiments, a silver contact pad of second plurality of silver contact pads 440 may have a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm. In some embodiments, a silver contact pad of second plurality of silver contact pads 440 may have a length ranging from 30 μm to 250 μm, from 30 μm to 225 μm, from 30 μm to 200 μm, from 30 μm to 175 μm, from 30 μm to 150 μm, from 30 μm to 125 μm, from 30 μm to 100 μm, from 30 μm to 75 μm, from 30 μm to 60 μm, from 30 μm to 50 μm, or from 30 μm to 40 μm In some embodiments, silver contact pads of second plurality of silver contact pads 440 may be square with a length greater than 10 μm, 15 μm, 20 μm, 30 μm, 40 μm, 50 μm, 60 μm, 75 μm, 100 μm, 125 μm, 150 μm, or 200 μm. Second plurality of silver contact pads 440 may be of any shape (e.g., circular, rectangular, oblong, etc., or a combination thereof) that reduces silver consumption. In some embodiments, second plurality of silver contact pads 440 may be fabricated by modifying the busbar screen pattern on screen printing lines to form a desirable size, number, and/or shape. Existing silver metallization pastes may be used in conjunction with drying and co-firing to form second plurality of silver contact pads 440. In some embodiments, it may be beneficial to use “floating busbar” pastes that contain non-fire through glass frits. First plurality of silver contact pads 420 is as described above (e.g., silver contact pads 320 in FIG. 3).

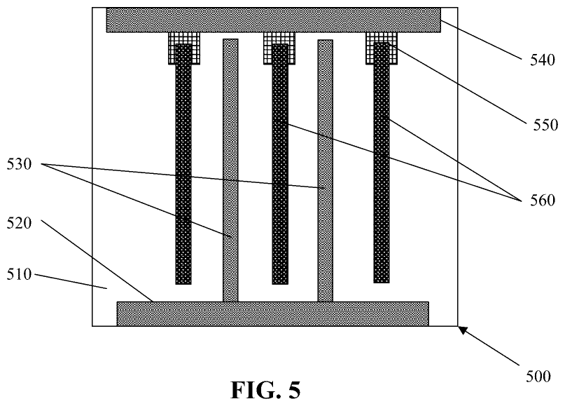

As described above, asymmetric solar cells (e.g., Interdigitated Back Contact (IBC) cells) may be designed to maximize light absorption on the front side of the solar cell and metallize the rear side. Reference is now made to FIG. 5, which is a schematic of a conventional asymmetric solar cell 500 design that comprises aluminum fine grid lines 560 contacting a p-type region and silver fine grid lines 530 contacting an n-type region on a rear surface 510 of asymmetric solar cell 500. Aluminum fine grid lines 560 are not solderable, so aluminum fine grid lines 560 are connected to silver pads 550, which can be soldered to make contact to silver solder pad 540 on one end of asymmetric solar cell 500. Silver fine grid lines 530 are connected to solder pad 520 on an opposite end of asymmetric solar cell 500. It is appreciated that FIG. 5 illustrates an asymmetric solar cell design for a p-type cell. For an n-type asymmetric solar cell, silver fine grid lines may replace aluminum fine grid lines 560, silver pads 550 may be removed, and the replacement silver fine grid lines may be soldered to silver solder pad 540.

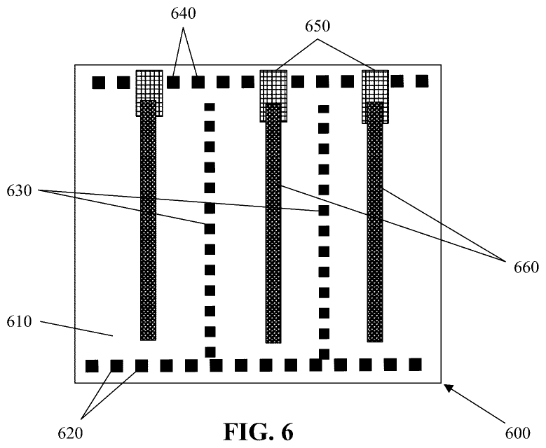

Reference is now made to FIG. 6, which is a schematic of an example asymmetric solar cell comprising silver contact pads, consistent with some embodiments of the present disclosure. FIG. 6 illustrates an example p-type asymmetric solar cell 600, which has a first plurality of silver contact pads 630 contacting an n-type region on a rear surface 610 of p-type asymmetric solar cell 600, and aluminum fine grid lines 660 contacting a p-type region of on the rear surface 610 of p-type asymmetric solar cell 600. It is appreciated that asymmetric solar cell 600 may comprise at least one passivation layer, as described above, on rear surface 610. Additionally, p-type asymmetric solar cell 600 may comprise a second plurality of silver contact pads 620 and a third plurality of silver contacts pads 640, which may replace silver solder pads 520 and 540, respectively (FIG. 5). After metallization (described further below), first plurality of silver contact pads 620 may be connected to third plurality of silver contact pads 640 and aluminum fine grid lines 660 may be connected to second plurality of silver contact pads 620. It is appreciated that for an n-type asymmetric cell, aluminum fine grid lines 660 may be replaced with a fourth plurality of silver contact pads (not shown) and silver pads 650 may be removed.

Thus, FIGS. 2-4 and FIG. 6 demonstrate that conductive multilayer stacks can be applied to conventional solar cell designs with minimal processing adjustments to greatly reduce silver consumption.

Silver contact pads provided by embodiments of the present disclosure may make Ohmic contact to a silicon substrate (e.g., for a solar cell), but an additional metal layer (e.g., metal layer 230 in FIG. 2) is needed to transport the charge away from the silicon substrate. For example, the solar cell schematics illustrated in FIGS. 2-4 and 6 all contain silver contact pads to extract charge from the silicon substrate but a continuous electrical connection between the silver contact pads may be needed to transfer charge from the wafer to other components of a solar cell module.

Conductive multilayer stacks of the present disclosure may be electrically connected to busbars, which are electrically connected to at least one solder pad or interconnect pad. In some embodiments, a method is provided for fabricating solar cell metallization layers including the steps of providing a silicon substrate, applying a silver metallization paste in a discontinuous pad design onto the surface of the silicon substrate, drying the silver layer and co-firing the silicon wafer to form silver contact pads. A solderable paste that melts below 450° C. may be printed on top of silver contact pads and may be subsequently dried or cured to form a solderable layer. In some embodiments, a metal layer may be placed on the solderable layer and subsequently heated to mechanically join the metal layer to the silver contact pads and subsequently laser cut to form a narrow line shape. In some embodiments, a metal layer may be first laser cut and then subsequently placed on top of the solderable layer before being soldered to the silver contact pads. In some embodiments, the metal layer comprises copper. In some embodiments, the metal layer is a pure copper or copper alloy foil. In some embodiments, the metal layer is a copper foil. In some embodiments, a flux (e.g., Alpha NR205) may be added to the coated aluminum foil or directly onto the silver contact pad to aid in soldering. In some embodiments, the solderable layer contains fluxes that can clean the metal layer surface and silver contact pad surface during soldering.

### Conductive Multilayer Stack Process and Resulting Structure for Metal Lines on Silicon Solar Cells

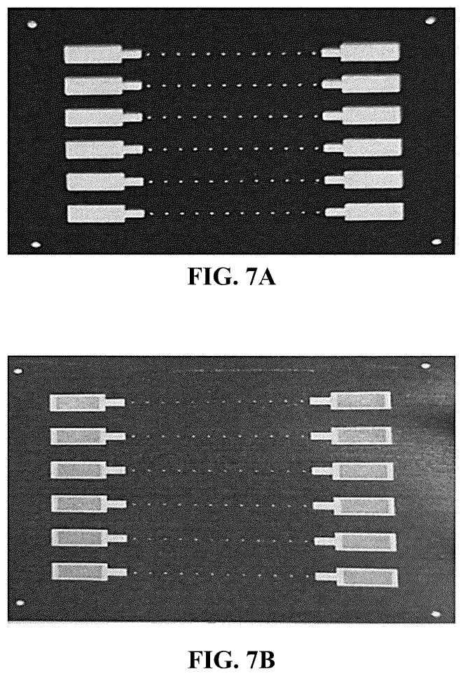

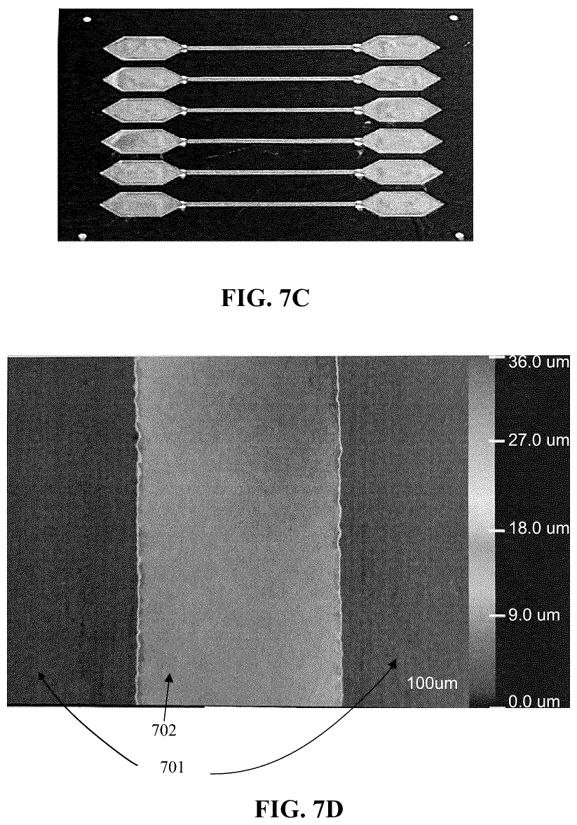

Reference is now made to FIGS. 7A-7C, which are top-view images of a metallized solar cell at different phases of fabricating a conductive multilayer stack. FIG. 7A is a top-view microscope image of silver contact pads printed on a silicon wafer coated with at least one passivation layer. A silver contact pad in a row is separated from a nearest neighbor by 500 μm on a silicon wafer coated with at least one passivation layer. Silver contact pads are the dots between the larger pads of FIG. 7A. The larger pads on the left and right of each horizontal row of silver contact pads are for support structures for measuring properties of the conductive multilayer lines of FIG. 7C. A silver contact pad in a row is separated from a silver contact pad in the adjacent column (e.g., directly above or directly below) by 1400 μm. The silver contact pads in FIG. 7A have an average diameter of 79.7 μm, and an average thickness of 7 μm. Solder paste (SAC305) is subsequently screen printed on the silver contact pads and larger contact pads as shown in FIG. 7B. The thickness of the SAC35 solder layer is approximately 25 μm (prior to soldering) and may completely cover a silver contact pad. Finally, a copper foil is placed on top of the solder coated, silver contact pads (and larger contact pads) and soldered at temperature below 300° C. for less than five seconds. The copper foil is held under tension and subsequently laser cut with a 70 W fiber laser (1064 nm wavelength, 30 μm focal spot size) in pulse mode with 200 ns pulse duration, 250 kHz repetition rate, and a scanning speed of 1 m/s to form the desirable line shape. FIG. 7C illustrates six conductive multilayer lines with twelve conductive multilayer stacks, which comprise a metal layer (e.g., copper), a solderable layer, and a silver contact pad on a passivated silicon wafer. Each conductive multilayer line illustrated in FIG. 7C has a metal layer that is a continuous layer that connects, in this case, the conductive multilayer stacks and constitutes the respective metal layer 230 of each conductive multilayer stack 200 (see FIG. 2) of the conductive multilayer line. A conductive multilayer line may comprise a plurality of conductive multilayer stacks. The metal (e.g., copper) layer may have a line width that is less than 250 μm. For fine grid lines it may be desirable to reduce the conductive multilayer line width to less than 500 μm, 450 μm, 400 μm, 350 μm, 300 μm, 250 μm, 200 μm, 150 μm, 125 μm, 100 μm, 75 μm, 60 μm, 50 μm, 40 μm, or 30 μm. The laser cut edges may have an in-plane edge roughness of less than 10 μm Ra when measured using confocal microscopy. The burr mean height may be less than 6 μm. The conductive multilayer line can be flat and, in some embodiments, elevated over the silicon substrate. FIG. 7D is a 3D map created using a confocal microscope (20× magnification). Portion 701 of the image is the silicon wafer and portion 702 is the copper foil, which is relatively flat and 25 μm above the silicon wafer. The conductive multilayer line has a height that is determined by the solderable layer thickness, soldering conditions, metal foil tension, and/or metal foil thickness. In some embodiments, the conductive multilayer line height may be less than 60 μm above a silicon substrate, less than 50 μm above a silicon substrate, less than 40 μm above a silicon substrates, less than 30 μm above a silicon substrate, less than 25 μm above a silicon substrate, less than 20 μm above a silicon substrate, less than 15 μm above a silicon substrate, or less than 10 μm above a silicon substrate.

### Laser Cutting Conductive Multilayer Lines Enables New Cell Geometries and Significant Silver Savings

Embodiments of the present disclosure may reduce an overall metallization area on a solar cell and thus silver consumption by more than 90 wt. %, more than 80 wt. %, more than 70 wt. %, or more than 50 wt. % by converting continuous metal lines (e.g., fine grid lines and/or busbars) to discrete silver contact pads. An amount of metallization on a solar cell can be quantified by, for example, determining a mass of silver paste applied per cell (mg/cell) before and after screen sprinting metallization pastes, determining a percentage of metallized area (e.g., 7%), or determining a metallization volume on a solar cell. A percentage of metallized area may be determined using a flatbed scanner, imaging software, or other equipment used to determine a surface area percentage. A metallization volume may be determined using a confocal microscope. In some embodiments, a size of silver contact pads and separation distance between silver contact pads may determine total silver savings. In some embodiments, a total silver paste consumption on a solar cell comprising a conductive multilayer stack ranges from 5 mg/cell to 120 mg/cell, from 5 mg/cell to 90 mg/cell, from 5 mg/cell to 75 mg/cell, from 5 mg/cell to 60 mg/cell, from 10 mg/cell to 50 mg/cell, from 10 mg/cell to 40 mg/cell, or from 20 mg/cell to 50 mg/cell. In some embodiments, an overall metallization area on a solar cell comprising a conductive multilayer stack (e.g., comprising silver contact pads) may range from 0.5% to 7%, from 0.5% to 6%, from 0.5% to 5%, from 0.5% to 4%, from 0.5% to 3%, from 0.5% to 2%, from 0.5% to 1%, or from 0.5% to 0.75%. In comparison, a conventional solar cell may use 140 mg/cell of silver and exhibit an overall metallization area of 8-9%.

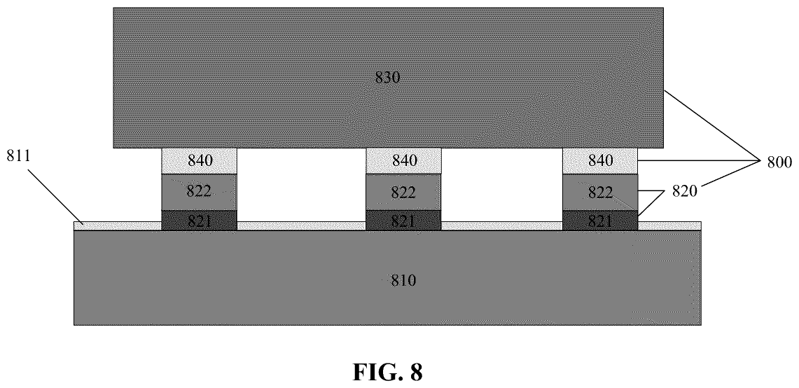

Reference is now made to FIG. 8, which is a schematic cross-section of a conductive multilayer line 800 comprising a metal layer 830, a solderable layer 840, a silver contact pads 820, comprising a glass frit sublayer 821 and a silver sublayer 822, on a substrate 810 containing at least one passivation layer 811 on a surface of substrate 810, consistent with some embodiments of the present disclosure. It is appreciated that metal layer 830, solderable layer 840, substrate 810, and at least one passivation layer 811 are as described above in, e.g., FIG. 2 and silver contact pads 820 are as described above in FIGS. 3, 4, and 6. As illustrated in FIG. 8, the exemplified conductive multilayer line 800 comprises three conductive multilayer stacks identified by three silver contact pads 820, where the solderable layer 840 comprises three regions formed on the three silver contact pads 820, and the conductive multilayer stacks have a continuous, common metal layer 830 that constitutes the respective metal layer 230 of each conductive multilayer stack 200 (see FIG. 2) of the conductive multilayer line. In this way, conductive multilayer line 800 connects a series of silver contact pads 820. In some embodiments, silver contact pads 820 may be separated by more than 200 μm, more than 300 μm, more than 400 μm, more than 500 μm, more than 700 μm, more than 800 μm, more than 1 mm and more than 2 mm from their nearest neighbor, which is the closest silver contact pad. In some embodiments, silver contact pads 820 may be separated by 200 μm to 2 mm, 300 μm to 1 mm, 300 μm to 1 mm, 400 μm to 1 mm, or 400 μm to 900 μm.

In some embodiments, a metal layer of a conductive multilayer stack or conductive multilayer line may be formed by laser cutting coated aluminum foils. The aluminum surface may have a native oxide that is difficult to solder directly to silver. Laser welding may be used to directly weld silver to aluminum, but laser welds can result in thermal shock and the area of the weld is quite small. This may result in weak, inconsistent welds and make it challenging to consistently pass thermal cycling tests. Furthermore, aluminum and silver are galvanically dissimilar materials and may corrode under damp heat conditions. Solar modules are often required to pass >1000 hours of damp heat (85° C./85% Relative Humidity). Coating aluminum foils may enable fabrication of metal lines with laser cutting on silicon solar cells. The coated aluminum layer may comprise an aluminum layer and at least one corrosion resistant joining (CRJ) layer on at least one side.

In some embodiments, the aluminum layer has a thickness from 3 μm to 200 μm, from 10 μm to 100 μm, from 10 μm to 75 μm, or from 10 μm to 30 μm. Rolled aluminum alloy foil that is 30 μm thick can act as the aluminum layer. Rolled aluminum foil is not porous and has a high bulk conductivity. The aluminum alloy layer composition and thickness may be optimized to be strong, relatively conductive, and sufficiently pliable to be rolled and positioned above the solar cell. The aluminum layer may comprise aluminum and copper (Cu), magnesium (Mg), manganese (Mn), silicon (Si), tin (Sn), zinc (Zn), or a combination thereof, such as alloys, to strengthen the foil and improve laser cutting properties. Aluminum foils may be substantially more conductive than films created by printing and firing metal particles. Bulk resistivity may be a useful property that can be measured using a four-point probe system to determine the sheet resistance and dividing by the film thickness. The bulk resistivity of pure aluminum is 2.6E-6 Ohm-cm. Aluminum particle films may have a bulk resistance that is 10 to 100 times higher than that of pure aluminum. In some embodiments, the aluminum layer is a solid metal that has no porosity or a porosity of less than 0.25%. Pure aluminum has the highest conductivity but relatively low ultimate tensile strength (<200 MPa), so special handling may be needed. Alloying aluminum often increases the bulk resistivity but reduces pliability. In some embodiments, the metal layer has a bulk resistivity from 2.6E-6 Ohm-cm to 13E-6 Ohm-cm, from 2.6E-6 Ohm-cm to 6.2E-6 Ohm-cm, or from 2.6E-6 Ohm-cm to 3.9E-6 Ohm-cm. Higher strength aluminum alloys such as 1100, 0303, 0304, 5083, 7075, and 8079 series also have good corrosion resistance and reasonable conductivity. A metal a may be selected based on the metal alloy and thickness that results in negligible series resistance after fabrication and may continue to perform well after damp heat testing (85° C., 85% relative humidity for 1000-4000 hrs).

A surface roughness of the metal foil may be an important consideration to conformally coating thin layers onto the foil. The surface roughness can be measured using a Keyence laser profilometer. Laser profilometers can measure the average roughness (Ra), RMS roughness (Rq) and peak height (Rz). A smooth foil may minimize the coating thickness. Common “converter” aluminum foils have significantly higher roughness (i.e., Ra≥400 nm) and finer structural tears; physical vapor deposited coatings below 200 nm may not sufficiently conformally coat these foils, resulting in pinholes in the coating. The exposed aluminum foil at these pin holes may react with silver or solder materials and increase contact resistance when exposed to damp heat. Thus, it is desirable to minimize the surface roughness and minimize coating thicknesses to conformally coat the aluminum layer. Smooth rollers may be used during cold rolling the foil to minimize surface roughness. When the average surface roughness is >400 nm, it may be desirable to planarize the surface by depositing aluminum to smooth the surface or via chemical and mechanical means (e.g., chemical mechanical polishing). In some embodiments, the average surface roughness is below 450 nm, below 400 nm, below 350 nm, below 300 nm, below 250 nm, and/or below 20 nm. In some embodiments, the aluminum foils have a roughness of less than 10 nm. Herein, a solderable layer is a layer that includes a solder material. A solderable layer is a layer that can be soldered. For example, a layer of electronic ink may be soldered and is therefore a solderable layer. A solderable layer may include solder material layers as well as layers that may be soldered but do not include a solder material.

In some embodiments, a metal layer may be selected from foils that have a smooth side with a low surface roughness. In some embodiments, a metal layer may be a 30-μm-thick aluminum alloy (8079 series) foil. Table 1 shows the Keyence surface image for a shiny side of a metal foil having a Ra=175 nm, Rq=214 nm, and Rz=1,196 nm. Table 1 shows the Keyence surface image for a matte side of a metal foil having a Ra=458 nm, Rq=573 nm, and Rz=3,270 nm. It may be desirable to coat the metal foil with an average surface roughness of less than 500 nm, less than 400 nm, or less than 300 nm to prevent pinholes. It is appreciated that only one side of the aluminum metal layer may be coated with a corrosion resistant joining layer to permit joining to silver contact pads. The exposed surface of an aluminum metal layer (e.g., the surface facing away from the silver contact layer/silver contact pad) may comprise a native oxide, or a layer to absorb laser power (e.g., carbon black, titanium, or nickel), or a corrosion resistance layer (e.g., titanium nitride). It is appreciated that it may not necessary to use corrosion resistant joining layers on the exposed surface of the aluminum layer.

TABLE 1
Foil Roughness Metrics for Solar Grade Aluminum Foil

| | | | | | | Line |
|---|---|---|---|---|---|---|
| | | | Ra | Rq | Rz | roughness |
| Foil | Material | Thickness | (nm) | (nm) | (nm) | orientation |
| Toyal- | Al | 33 um | 458 | 573 | 3,270 | NA |
| Matte side | | | | | | |
| Toyal- | Al | 33 um | 175 | 214 | 1,196 | perp to roll |
| Shiny side | | | | | | |

In some embodiments, coated aluminum layers comprise at least one corrosion resistant joining (CRJ) layer. The CRJ layer may comprise materials that are distinct from the aluminum layer. In some embodiments, a first CRJ layer, which is in contact with an aluminum layer (or coated aluminum layer), may comprise chromium (Cr), cobalt (Co), molybdenum (Mo), nickel (Ni), tantalum (Ta), titanium (Ti), tungsten (W), alloys thereof, nitrides thereof, borides thereof, composites thereof, or combinations thereof. A first CRJ layer has, in some embodiments, a thickness from 1 nm to 2 μm, or from 5 nm to 1 μm, from 10 nm to 200 nm, or from 20 nm to 150 nm. The at least one CRJ may be deposited via evaporative deposition, sputter deposition, ALD, electroplating, or electroless deposition. In some embodiments, a 30-μm-thick aluminum alloy (8079 series) foil is first plasma etched in vacuum to remove the native oxide (Al₂O₃) before a 75 nm thick layer of titanium layer is sputtered directly onto the bare aluminum surface.

In some embodiments, solderable materials such as silver and copper can also be used as the at least one CRJ layer. In some embodiments, a first CRJ layer is applied to prevent corrosion and interdiffusion of additional coating layers. In some embodiments, the aluminum metal layer is a 30-μm-thick, 8079 aluminum alloy, a first CRJ layer is a 20-100 nm thick layer of titanium, and a second (exterior facing) coating is a 100 nm thick, solderable material comprising copper. A second (exterior facing) CRJ layer may be in contact with the first CRJ layer. The second CRJ layer may comprise silver (Ag), copper (Cu), alloys thereof, composites thereof, or combinations thereof. The second (exterior facing) CRJ layer has, in some embodiments, a thickness from 2 nm to 2 μm, from 5 nm to 1 μm, from 20 nm to 250 nm, or from 40 nm to 250 nm. The at least one CRJ layer may be deposited via evaporative deposition, sputter deposition, ALD, electroplating, or electroless deposition. In some embodiments, the second (exterior facing) coating comprises 200 nm of copper. In some embodiments, the coated aluminum layer comprises a 30-μm aluminum foil, coated with a first CRJ layer of 50 nm titanium and a second (exterior facing) coating of 200 nm of copper. In some embodiments, a third CRJ layer may be applied to prevent copper diffusion. In some embodiments, a first CRJ layer is 50 nm of titanium, a second CRJ layer is 200 nm of copper, and a third CRJ layer is 10 nm of silver. It may be desirable to minimize the at least one CRJ layer thickness to below 500 nm, below 400 nm, below 350 nm, below 300 nm, below 250 nm, or below 200 nm. Glass/glass encapsulation (i.e., solar cells are sandwiched between two sheets of glass) can be used to dramatically reduce moisture ingress inside the module. For glass/glass modules, it may be possible to use aluminum foil with a thin (50-500 nm) coating of copper as the only CRJ layer.

In some embodiments, a metal layer of a conductive multilayer stack or conductive multilayer line may be a copper metal layer, such as formed by laser cutting copper foil. Copper foil may be formed via electrodeposition on titanium drums with a thickness from 4 μm to 100 μm. In some embodiments, the copper metal layer has a thickness from 4 μm to 100 μm, from 4 μm to 50 μm, from 4 μm to 25 μm, from 4 μm to 10 μm, or from 4 μm to 6 μm. Copper foils can achieve ultimate tensile strength greater than 400 MPa and have good temperature stability. Copper foils are generally treated with thin metal oxide layers for battery foil and printed circuit board applications. These coatings are well known in the copper foil art and some coatings are meant to make copper foil more solderable. Electrodeposited copper foils often have at least one smooth (also called bright) side and can have a matte (also called dark) side. Keyence surface imaging of the bright side of a copper foil has measured Ra=260 nm, Rq=320 nm and Rz=2120 nm. Keyence surface imaging on the matte side of copper foil has measured Ra=1370 nm, Rq=1760 nm and Rz=14290 nm. It may be desired for a copper foil to be smooth to improve soldering to achieve strong adhesion, exhibit low contact resistance, and exhibit excellent damp heat reliability. Copper is solderable and chemically compatible with silver. For an identical thickness, copper foil can be ten times more expensive than aluminum on a per area ($/m²) basis. The thickness of silver metallization lines has steadily reduced over the last decade to 5-12 μm and it may be possible to replace these silver lines with 4-10 μm copper foils and maintain equivalent (or higher) conductivity. In some embodiments, thin copper foils can be economically used to replace metallization layers on silicon cells.

In some embodiments, solder pastes are composed of solder particles, organic binders, fluxes or activation agents, and additives that are well known in the solder art. Dissimilar metals may be joined by soldering, which is a different process than welding. Silver contact layers and silver contact pads may be strongly bonded to the silicon wafer after co-firing, but the coefficient of thermal expansion of silicon is different from the coefficient of thermal expansion of the silver sublayer and glass frit sublayer, which makes the silver contact layer prone to thermal shock. In some embodiments, a copper foil and a silver contact pad are joined at temperatures below 500° C., below 450° C., below 400° C., below 350° C., below 300° C., below 250° C., or below 150° C. In some embodiments, the solar cells are soldered with tabbing wires coated with a 20 μm to 40 μm layer of Sn₆₀Pb₄₀ (SnPb), which has a liquidous point near 190° C. Solar cells are typically soldered together via infrared heating on hot stages; the soldering conditions can exceed the liquidous point by 10-50 degrees. Therefore, solder materials may have liquidous points above 200° C. after initial soldering. The solderable material may have a liquidous point to allow for joining at temperatures from 130° C. to 500° C., from 130° C. to 400° C., or from 190° C. to 350° C.

Solder particles may comprise, for example, compositions described in Table 2. Solder particles can vary in diameter from 1 μm to 25 μm, from 5 μm to 20 μm, or from 5 μm to 10 μm. In some embodiments, the solder particle diameter may be minimized and printed as thin layers that minimize material usage. The fluxes included in the solder pastes may be designed to clean silver and copper surfaces.

TABLE 2
Soldering compounds

| Composition by weight % | Solidus Point (° C.) | Liquidus Point (° C.) |
|---|---|---|
| Sn₅₀Zn₄₉Cu₁ | 200° C. | 300° C. |
| Pb₉₀Sn₁₀ | 268° C. | 302° C. |
| Pb₈₈Sn₁₂ | 254° C. | 296° C. |
| Pb₈₅Sn₁₅ | 227° C. | 288° C. |
| Pb₈₀Sn₂₀ | 183° C. | 280° C. |
| Pb₇₅Sn₂₅ | 183° C. | 266° C. |
| Sn₃₀Pb₅₀Zn₂₀ | 177° C. | 288° C. |
| Sn₃₃Pb₄₀Zn₂₈ | 230° C. | 275° C. |
| Pb₆₀Sn₄₀ | 183° C. | 247° C. |
| Sn₉₀Pb₁₀ | 183° C. | 213° C. |
| Pb₉₂Sn_{5.5}Ag_{2.5} | 286° C. | 301° C. |
| Pb₈₀Sn₁₈Ag₂ | 252° C. | 260° C. |
| Pb₈₈Sn₁₀Ag₂ | 267° C. | 299° C. |
| Pb_{92.5}Sn₅Ag_{2.5} | 300° C. | 304° C. |
| Pb_{93.5}Sn₅Ag_{1.5} | 305° C. | 306° C. |
| Pb_{95.5}Sn₂Ag_{2.5} | 299° C. | 304° C. |
| Pb_{94.5}Ag_{5.5} | 305° C. | 364° C. |
| Pb₉₅Ag₅ | 305° C. | 364° C. |
| Sn_{97.5}Pb₁Ag_{1.5} | 305° C. | 305° C. |
| Pb_{97.5}Ag_{1.5}Sn₁ | 309° C. | 309° C. |
| Pb₉₆Ag₄ | 305° C. | 305° C. |
| Pb₉₆Sn₂Ag₂ | 252° C. | 295° C. |
| Sn_{96.5}Ag_{3.0}Cu_{0.5} | 217° C. | 220° C. |
| Sn_{98.5}Ag_{1.0}Cu_{0.5} | 220° C. | 225° C. |
| Sn_{95.8}Ag_{3.5}Cu_{0.7} | 217° C. | 218° C. |
| Sn₉₆Ag₄ | 221° C. | 230° C. |
| Sn₉₅Ag₅ | 221° C. | 254° C. |
| Sn₉₄Ag₆ | 221° C. | 279° C. |
| Sn₉₃Ag₇ | 221° C. | 302° C. |
| Sn₉₇Cu₃ | 227° C. | 332° C. |
| Sn₉₇Cu_{2.75}Ag_{0.25} | 228° C. | 314° C. |
| Zn₁₀₀ | 419° C. | 419° C. |
| Sn₈₅Zn₁₅ | 199° C. | 260° C. |
| Zn₉₅Al₅ | 382° C. | 382° C. |
| Sn₇₀Zn₃₀ | 199° C. | 316° C. |
| Sn₈₀Zn₂₀ | 199° C. | 288° C. |
| Sn₆₀Zn₄₀ | 199° C. | 343° C. |
| Sn_{86.9}In₁₀Ag_{3.1} | 204° C. | 205° C. |
| Sn₉₅Ag_{3.5}Zn₁Cu_{0.5} | 221° C. | 221° C. |
| Sn_{96.2}Ag_{2.5}Cu_{0.8}Sb_{0.5} | 217° C. | 225° C. |
| Sn₈₈In8.0Ag_{3.5}Bi_{0.5} | 197° C. | 208° C. |
| Zn₇₀Sn₃₀ | 199° C. | 376° C. |
| Zn₆₀Sn₄₀ | 199° C. | 341° C. |
| Zn₉₅Sn₅ | 382° C. | 382° C. |
| Bi₅₈Sn₄₂ | 138° C. | 138° C. |
| Bi₅₇Sn₄₂Ag₁ | 137° C. | 140° C. |

Alternative solder pastes, often called conductive inks, can also be used that do not comprise solder particles and can be used to solder at low temperatures (e.g., below 300° C.). Examples of these solder pastes are described in U.S. Pat. No. 10,301,497, U.S. Patent Application Publication No. 2015/0298248 A1, and U.S. Patent Application Publication No. 2023/0242783, each of which is incorporated by reference in their entireties. These conductive inks can be deposited via screen printing, dried below 150° C., or UV cured and subsequently heated to below 300° C. to solder to copper or coated aluminum foil. These conductive inks may also form the solderable layer in the conductive multilayer stack and conductive multilayer line described herein.

### Methods to Form CMS and Cut Narrow Metal Lines on Solar Cells

In some embodiments, fabricating a conductive multilayer stack or a conductive multilayer line with narrow line widths on solar cells may include: 1) precise solar cell positioning underneath the foil for a metal layer, 2) soldering, and 3) laser cutting. In some embodiments, a conductive multilayer stack or a conductive multilayer line may be formed either by soldering metal foils first and subsequently laser cutting, or by laser cutting metal foils first to form narrow lines that are subsequently soldered. Laser cutting first may be beneficial because the foil can be cut under a wide variety of processing conditions without damaging surface passivation lasers on the silicon wafer

Fiducial marks may be added onto solar cells during screen printing that can be used to orient the wafer under the foil and identify the location of the silver contact layer of silver contact pads on the silicon wafers. Openings are laser cut from the foil prior to positioning for the soldering and laser cutting tool to get visual registry with the fiducial marks on the wafer. Wafer alignment is well known in the solar cell art and it possible to achieve sub-20-micron precision when screen printing solder pastes on top of the silver contact layer or silver contact pads.

Soldering may be used to join the metal layer, solderable layer, and silver contact layer (or silver contact pads) to form the conductive multilayer stack or conductive multilayer line. The silicon wafer can be pre-heated using a heated chuck during cell positioning. The pre-heating temperature should not exceed the activation temperature of the flux. In some embodiments, the wafer is heated to a temperature greater than 100° C., greater than 130° C., greater than 150° C., greater than 175° C., greater than 200° C., or greater than 250° C. to solder. Once the wafer has been moved into contact with the metal layer, the foil can be heated to greater than 150° C., greater than 200° C., greater than 250° C., greater than 300° C., greater than 350° C., or greater than 400° C. for a period of less than 1 second, less than 2 seconds, less than 3 seconds, or less than 180 seconds. Foil may be heated via infrared heating, hot air, or a heating block. Foils may be held under tension but may not always be perfectly level when in contact with the silicon wafer. Heating blocks may be made by placing resistive heaters into solid blocks of metal (e.g., copper) or ceramics and can be used to gently press the foil onto the silicon substrate resulting in more even soldering. In some embodiments, the heating block is not transparent and does not move away from the cell after soldering to allow for laser cutting from above. Hot air can also be used to heat and apply gentle pressure on the foil to improve joining over a wide area.

Laser cutting may be used to form the metallization lines on the conductive multilayer stack or conductive multilayer line. In some embodiments, continuous and pulsed laser beams are focused to a spot size less than 100 μm, less than 80 μm, less than 60 μm, less than 40 μm, or less than 30 μm and used to cut metal foils. The laser beam may be steered using galvo-scanning mirrors with a constant scanning speed from 0.5 m/s to 100 m/s, which results in the desired line shape. A wide variety of cutting conditions can be used (e.g., when the metal foil is cut prior to soldering and the foil is far away from the silicon wafer surface).

In some embodiments, a laser is used to cut foil for a metal layer in free space into narrow fine grid lines. In some embodiments, a 100 W fiber laser may be used in a pulse mode, where the repetition rate is set at 250 kHz and the pulse duration at 200 ns. The laser beam may be steered at the front surface of the metal foil at a speed≥1 m/s using galvo-scanning mirrors. In some embodiments, a fine line of 100 μm width may be formed by separating laser cut lines by 150 μm. Laser cutting processes may result in material being ejected in the solid, liquid, or plasma phase, or a combination thereof. Laser cutting may result in the accumulation of material in the upward direction (away from the substrate) and in the downward direction (toward the substrate). This results in out-of-plane material accumulation along the cut line, which may depend on the laser processing settings such as laser power, repetition rate, pulse duration, scanning speed, wavelength, focal spot size, foil thickness, or foil material. The burr is defined as the material resulting from the cutting process that remains and accumulates above the metal foil. When the cut is done in free space with no underlying substrate material, material from the coated based metal also builds up at the back surface of the metal layer. This back surface accumulation is called the dross. The burr mean height is the average height of the burr from the coated metal front surface plane. The dross mean height is the average height of the dross from the metal layer back surface plane. The burr is also characterized by its roughness, which is quantified by the burr roughness average (burr Ra) value. The burr Ra is the arithmetic average of the absolute values of the burr profile deviations from the mean of the burr height. The dross is also characterized by its roughness, which is quantified by the dross roughness average (dross Ra) value. Laser cutting may also result in in-plane edge roughness, along the cut line path, in the plane parallel to the substrate plane. The in-plane edge roughness is quantified by the in-plane roughness average (in-plane Ra) value.

Confocal microscopy (e.g., a 3D Surface Profiler, VK-X3000 series from Keyence) can be used to measure the laser cut line attributes, which include the in-plane edge roughness, burr mean height, burr roughness, dross mean height, and dross roughness. The confocal microscope can be positioned around a region of interest (ROI) where a laser beam scans the surface of the object, in a confocal configuration, and thereby renders a 3D quantitative representation of the cut, with nanometer elevation precision in the vertical direction and micron resolution in the horizontal plane. The burr average height and roughness can be calculated from elevation profile data obtained by confocal microscopy on the incident side of the metal layer. In-plane edge roughness can be calculated from the in-plane, in-face image of the cut line by image processing and edge detection. The burr Ra can be calculated from the edge line profile extracted from the image processing

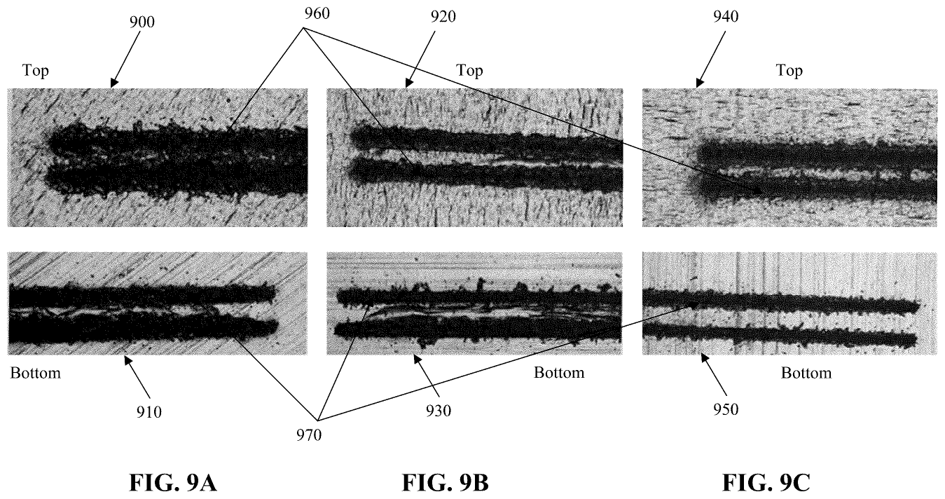

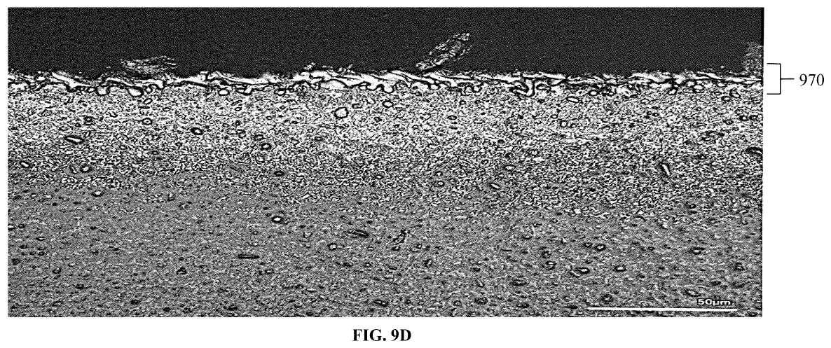

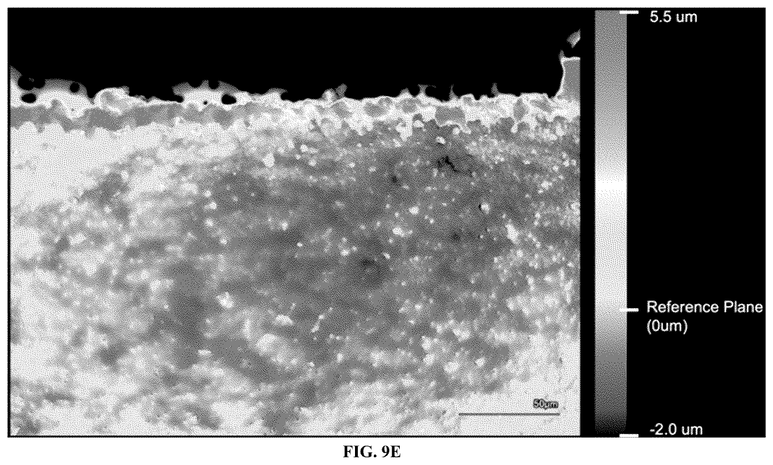

It may be possible to control burr, dross, and edge roughness by decreasing the pulse duration of the laser (e.g., going from a nanosecond to a picosecond or femtosecond laser), decreasing the laser spot size, other laser processing parameters (e.g., repetition rate, pulse mode, galvo scanning speed), by varying the metal foil thickness and material. Reference is now made to FIGS. 9A-9C, which are top-view confocal microscope images (20× objective, all at the same magnification) of an metal layer with two horizontal laser cuts separated by 75 μm using nanosecond (900, top of metal layer, 910, bottom of metal layer), picosecond (920, top of metal layer, 930, bottom of metal layer), and femtosecond (940, top of metal layer, 950, bottom of metal layer) laser pulse durations, consistent with some embodiments of the present disclosure. Top of the metal layer refers to the surface of the metal layer facing the laser beam. The burr 960 and dross 970 are visible at the edge the cut lines. The in-plane edge roughness from the nanosecond laser cut, obtained from 900, is about 40 μm. It is about 30 μm for the picosecond laser cut 920, and about 20 μm for the femtosecond laser cut 920. The burr mean height is about 20 μm for the nanosecond laser, about 15 μm for the picosecond laser, and about 15 μm for the femtosecond laser. The burr roughness is about 6 μm Ra for the nanosecond laser, about 4 μm Ra for the picosecond laser, and about 3 μm Ra for the femtosecond laser. The dross mean height is about 7 μm for the nanosecond laser, about 5 μm for the picosecond laser, and about 5 μm for the femtosecond laser. The dross roughness is about 4 μm Ra for the nanosecond laser, about 3 μm Ra for the picosecond laser, and about 2.5 μm Ra for the femtosecond laser. It should be noted that the burr and dross mean height and roughness can be further reduced by changing the laser parameters (pulse duration, repetition rate, wavelength, scanning speed) and optical configuration (focal spot size, beam shape).

Reference is now made to FIG. 9D, which is a top-view, confocal microscope image (50× magnification) of a 6-μm copper foil that was cut with a pulsed nanosecond laser, consistent with some embodiments of the present disclosure. The burr 970 is clearly seen at the edge of the copper foil and has a maximum height of about 5.5 μm, and is further demonstrated in the color, z-scale map in FIG. 9E. Nanosecond lasers cut by partially melting the material, which is visible in FIG. 9D. The in-plane edge roughness can be measured in either Keyence software and calculated by binarizing the image such that pixels containing copper are one color and pixels not containing copper are the other. This binarization can be done in software such as ImageJ. The cut edge's profile can then be found using the marching squares algorithm, which is implemented in many software packages including the scikit-image Python package. This profile can be fit to a line, and displacements of this profile from the line can be used to calculate roughness values such as Ra and Rz. Using this method, the calculated Ra of the cut lines is 1 μm. It should be noted that the foil is relatively flat (<2 μm curvature). This looks fundamentally different than screen printed silver lines, solder wires and electroplated copper lines, which can have a trapezoidal and/or rounded height profiles.

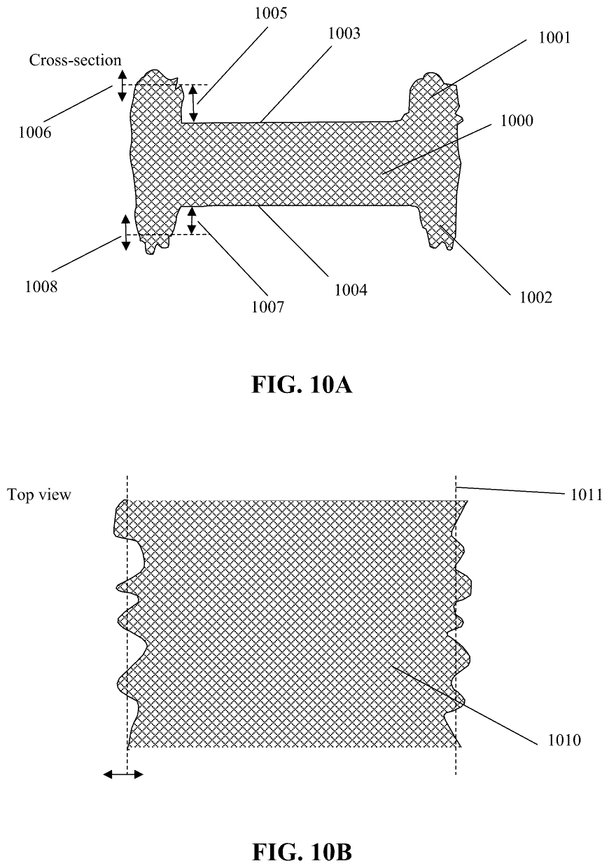

Reference is now made to FIG. 10A, which is a schematic cross-section of a laser-cut metal foil 1000 for a metal layer; the burr 1001, the dross 1002, the front surface 1003 of the metal foil; and the back surface 1004 of the metal foil, consistent with some embodiments of the present disclosure. In some embodiments, the burr possesses a mean height 1005 and a roughness 1006 and the dross possesses a mean height 1007 and a roughness 1008. Reference is now made to FIG. 10B, which is a schematic top-view of a laser-cut metal foil 1010 for a metal layer and the in-plane edge of the cut line 1011, consistent with some embodiments of the present disclosure. In some embodiments, the metal layer has an in-plane edge roughness greater than 1 μm, greater than 2 μm, greater than 5 μm, greater 10 μm, greater 20 μm, or greater 30 μm. In some embodiments, the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm. In some embodiments, the metal layer has a burr mean height from 200 nm to 20 μm, from 1 μm to 10 μm, or from 1 μm to 5 μm. In some embodiments, the metal layer has a burr roughness from 200 nm to 20 μm, from 1 μm to 10 μm, or from 1 μm to 5 μm. In some embodiments, the metal layer has a dross mean height from 200 nm to 20 μm, from 1 μm to 10 μm, or from 1 μm to 5 μm. In some embodiments, the metal layer has a dross roughness from 200 nm to 20 μm, from 1 μm to 10 μm, or from 1 μm to 5 μm.

Laser Cutting after Foil Soldering and Subsequent Metal Line Morphology

In some embodiments, after a metal foil has been soldered to form the metal layer of the conductive multilayer stack or conductive multilayer line, the metal foil may be in contact with the solar cell. Milliwatts of laser power can damage passivation layers on solar cells. Care should be taken in cutting the foil to form the desired metallization patterns. Galvo scanners are relatively inexpensive and capable of move at >50 m/sec. Laser beam parameters can be tuned to thin regions on the foil rather than completely cut through. This can be done in one pass or via successive laser passes. If the laser impacted area is sufficiently thin and damaged enough it may be removed with very little force, which is referred to as “kiss cutting.” Solder joints are relatively strong and can assist in kiss cutting by holding the metal line in place when the foil raised above the wafer after kiss cutting. Kiss cutting can be used to prevent passivation layer damage post conductive multilayer stack or conductive multilayer line formation.

If the laser cut is performed prior to joining the metal layer to the silver contact layer (or silver contact pad), a dross height that is higher than the silver sublayer thickness may prevent good contact between the metal layer and the silver contact layer (or silver contact pad) and negatively impact joining. The dross average height and average roughness can be measured by applying the same measurements used to calculate burr morphological characteristics on the rear side (e.g., side facing away from the incident laser) of coated metal foils after laser cutting. It may be desirable to minimize the average dross height and roughness to improve joining. In some embodiments, picosecond and nanosecond lasers may be used to reduce dross average height and roughness. It should also be noted that laser cut CMS layers have a unique morphology that differs from screen printed and electroplated metallization layers, which often look like trapezoids when viewed as cross-sections. Screen printed and electroplated metallization layers do not have burrs on the edge. Screen printed and electroplated metallization lines also have relatively low in-plane line roughness, which is believed be less than 10 μm, less than 5 μm, or less than 2 μm, depending on paste rheology and printing/electroplating technique. Laser cut metallization layers for conductive multilayer stacks and conductive multilayer lines may have edges that contain material build up out-of-plane (e.g., burr) and in-plane roughness, which distinguish laser cut lines from screen printed and electroplated lines.

### Silicon Solar Cell Fabrication

Methods for fabrication of PN junction silicon solar cells are known in the art. Shah, Arvind, ed. Solar Cells and Modules. Springer International Publishing, 2020, which is incorporated by reference herein in its entirety, provides a process flow to fabricate different types of solar cells including PERC, TOPCon, HJT, and IBC. In some embodiments, a method for fabricating a solar cell includes the steps of providing a silicon wafer substrate, texturing, dopant diffusion, etching, polishing, and passivation layer deposition on front and rear surfaces. In some embodiments, the silicon wafer substrate is monocrystalline and doped either n-type or p-type. In some embodiments, the substrate is a monocrystalline, n-type silicon wafer with a p-type emitter.

Metallization layers may be made by depositing silver metallization (and optionally aluminum) pastes onto at least one surface of the solar cell, drying, and co-firing the solar cell. Different metallization pastes be used to form fine grid lines, connecting busbars, and solder pads. Methods such as screen printing, gravure printing, spray deposition, slot coating, transfer printing, 3D printing, and/or inkjet printing can be used to apply the various layers. As a non-limiting example, Maxwell and AMAT screen printers can be used to deposit silver pastes to form silver contact pads and busbar. In some embodiments, the solar cell has at least one passivation layer covering at least a portion of the rear surface of the silicon wafer. Drying various layers of a solar cell may be done in a belt furnace at temperatures ranging from 150° C. to 300° C. for 30 seconds to 15 minutes. In some embodiments, a Despatch CDF 7210 belt furnace may be used to co-fire the silicon solar cells that contain fired conductive multilayer stacks or conductive multilayer lines as described herein. In some embodiments, co-firing may be done using a rapid heating technique and heating to a temperature greater than 760° C. for between 0.5 and 3 seconds in air, which are common temperature profiles for aluminum back-surface field silicon solar cells. The temperature profile of a wafer is often calibrated using a DataPaq® system with a thermocouple attached to the bare wafer. For symmetric solar cells, such as PERC and TOPCon, metallization layers are applied on the front and rear side. For asymmetric solar cells, such as IBC, metallization layers are applied on the rear side only.

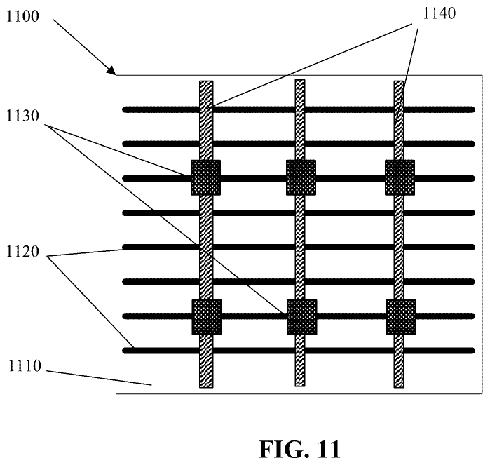

In some embodiments, a solar cell may be fabricated to form silver contact pads 320) shown in FIG. 3. After co-firing, the solar cell shown in FIG. 3 may be placed into a screen-printing tool and solder paste may be printed on top of silver contact pads 320 and optionally dried or cured. A metal foil (e.g., copper foil) may be subsequently placed on the silicon cell, where a heating press is applied at 280° C. for one second to solder the foil onto the silver contact pads of the solar cells and a nanosecond pulsed laser is subsequently used to cut a desired, continuous fine grid line shape. Reference is now made to FIG. 11, which is a schematic of a silicon solar cell 1100 (e.g., a symmetric solar cell) comprising fine grid lines 1120 that are conductive multilayer lines comprising conductive multilayer stacks, as described above, busbars 1140, and solder pads 1130 on a silicon substrate 1110, consistent with some embodiments of the present disclosure. It is appreciated that silicon solar cell 1100 may comprise at least one passivation layer, as described above, on silicon substrate 1110. In some embodiments, the metal layer of fine grid lines 1120 may have a width that is less than 500 μm, 450 μm, 400 μm, 350 μm, 300 μm, 250 μm, 200 μm 150 μm, 125 μm, 100 μm, 75 μm, 60 μm, 50 μm, 40 μm, or 30 μm. In some embodiments, the metal layer of fine grid lines 1120 may have a width that ranges from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm. In some embodiments, the metal layer of fine grid lines 1120 may have a thickness ranging from 4 μm to 100 μm, from 4 μm to 50 μm, from 4 μm to 25 μm, from 4 μm to 10 μm, or from 4 μm to 6 μm. In some embodiments, fine grid lines 1120 may use 25% less, 50% less, 60% less, 75% less, 90% less, or 95% less silver than continuous fine grid lines (e.g., fine grid lines 120 in FIG. 1). It is appreciated that the schematic illustrated in FIG. 11 may also apply for silicon solar cell 1110 comprising fine grid lines 1120 that are conductive multilayer lines comprising conductive multilayer stacks, as described above, that do not comprise a glass frit sublayer.

Some embodiments of the present disclosure provide fine grid lines comprising at least one conductive multilayer stack (e.g., a conductive multilayer line) that reduces silver consumption in solar cells. In some embodiments, the fine grid lines comprising at least one conductive multilayer stack are rear surface fine grid lines on TOPCon cells, where the rear surface fine grid lines have a width that range from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm. In some embodiments, the at least one conductive multilayer stack of the rear surface fine grid line comprises a 6-μm-thick copper foil, a solderable layer comprising a 20-μm-thick SAC305 layer, and a silver contact pad comprising a 5 μm silver sublayer and a sub-100 nm glass frit sublayer. In some embodiments, the solar cell may comprise a silicon wafer substrate with at least one passivation layer thereon, where the at least one passivation layer comprises a doped poly-Si layer. It is possible to use one metal foil multiple times to apply fine grid lines to several cells. This may greatly reduce the cost of using coated aluminum foils or copper foils and the required amount of metal foil required per day for each production line.

It should be noted that conventional front-surface fine grid lines are typically less than 50 μm wide. Rear-surface fine grid lines, comprising at least one conductive multilayer stack, that are wider than 50 μm would not impede front side efficiency of the solar cell because solar cell efficiency may be measured by measuring light impact on the front surface. Front-surface fine grid lines may have a width of 50 μm or greater. If the front-surface fine grid lines have a width greater than 50 μm, then the number of fine grid lines may be reduced to compensate for any front surface shading issues.

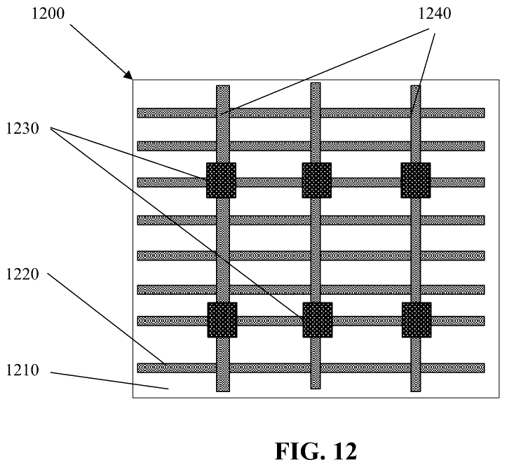

In some embodiments, a solar cell is fabricated to form at least one fine grid line from a first plurality of silver contact pads 420 and at least one busbar from a second plurality of silver contact pads 440 shown in FIG. 4. After co-firing, the solar cell shown in FIG. 4 may be placed into a screen-printing tool and solder paste may be printed on top of first plurality of silver contact pads 420 and second plurality of silver contact pads 440 and optionally dried or cured. A metal foil may be subsequently placed on the silicon cell, where a heating press is applied at 350° C. for one second to solder the foil onto the solar cells and a nanosecond pulsed laser is subsequently used to cut the desired continuous at least one fine grid line and the desired continuous busbar. Reference is now made to FIG. 12, which is a schematic of a silicon solar cell 1200 (e.g., a symmetric solar cell) comprising fine grid lines 1220 that are conductive multilayer lines comprising at least one conductive multilayer stack, as described above, busbars 1240 that are conductive multilayer lines comprising at least one conductive multilayer stack, as described above, and solder pads 1230 on a silicon substrate 1210, consistent with some embodiments of the present disclosure. It is appreciated that silicon solar cell 1200 may comprise at least one passivation layer, as described above, on silicon substrate 1210. In some embodiments, the metal layers of fine grid lines 1220 may have a width that range from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm. In some embodiments, the metal layers of fine grid lines 1220 may have a thickness from 4 μm to 100 μm, from 4 μm to 50 μm, from 4 μm to 25 μm, from 4 μm to 10 μm, or from 4 μm to 6 μm. In some embodiments, fine grid lines 1220 may contain 25% less, 50% less, 60% less, 75% less, 90% less, or 95% less silver than continuous fine grid lines (e.g., fine grid lines 120 in FIG. 1). In some embodiments, the metal layers of busbars 1240 may have a width that are less than 500 μm, 450 μm, 400 μm, 350 μm, 300 μm, 250 μm, 200 μm, 150 μm, or 100 μm. In some embodiments, the metal layers of busbars 1240 may have a width from 4 μm to 500 μm, from 4 μm to 450 μm, from 4 μm to 400 μm, from 4 μm to 350 μm, from 4 μm to 300 μm, from 4 μm to 250 μm, from 4 μm to 200 μm, from 4 μm to 150 μm, from 4 μm to 100 μm, from 4 μm to 500 μm, from 4 μm to 50 μm, from 4 μm to 25 μm, from 4 μm to 10 μm, or from 4 μm to 6 μm. In some embodiments, the metal layers of busbars 1240 may have a thickness from 4 μm to 100 μm, from 4 μm to 50 μm, from 4 μm to 25 μm, from 4 μm to 10 μm, or from 4 μm to 6 μm. In some embodiments, busbars 1240 may contain 25% less, 50% less, 60% less, 75% less, 90% less, or 95% less silver than continuous busbars (e.g., busbar 140 in FIG. 1). In some embodiments, busbars 1240 may be perpendicular to fine grid lines 1220, and it may not be possible to reuse foil several times if fine grid lines 1220 and busbars 1240 are cut from the same foil at the same time. In some embodiments, it is preferred to split fine grid line and busbar formation and cutting steps into separate processes (e.g., after fine grid lines 1220 formation, rotate wafer 90 degrees, apply solder paste, solder, and then laser cut in the same direction as fine grid lines 1220) to increase foil utilization.

Conventional Solar Modules and Cell Interconnections with CMS Layers

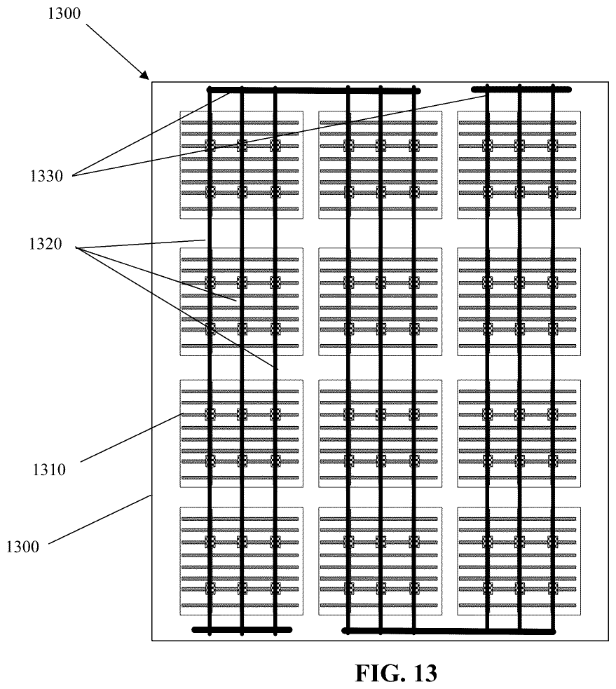

Solar modules may comprise a front sheet, front encapsulant layer, silicon solar cells, cell interconnects, a rear encapsulant layer and a back-sheet. There are many possible module designs in which such solar cells can be used, as would be known to a person with ordinary skill in the solar module art. A first solar cell in a solar module may be connected to a second solar cell in the solar module using an interconnect. In some embodiments, the interconnect may comprise a tabbing wire connected to a solder pad on the first solar cell and a solder pad on the second solar cell. Reference is now made to FIG. 13, which is a schematic of a solar cell module 1300 comprising symmetric silicon solar cells 1310 and an interconnect comprising tabbing wires 1320 electrically connected to solder pads of solar cells 1310 and bus ribbons 1330 in electrical contact with tabbing wires 1320, consistent with some embodiments of the present disclosure. Typically, 60 or 72 solar cells are incorporated into commercial modules, but it may be possible to incorporate more or fewer solar cells depending on the application (e.g., consumer electronics, residential, commercial, utility, etc.). The number of solar cells 1310 in solar cell module 1300 is not intended to be limited. A solar cell length may vary from 125 mm to 500 mm, or any range subsumed and may also be cut in halves, thirds, quarters, or other fractions to decrease the current density and increase the operating voltage when connected in series. It is appreciated that symmetric solar cells 1310 may comprise fine grid lines that are conductive multilayer lines (e.g., fine grid lines 1220 in FIG. 12) and/or busbars that are conductive multilayer lines (e.g., busbars 1240 in FIG. 12). It is appreciated that symmetric solar cells 1310 may comprise at least one passivation layer, as described above, thereon.

Copper tabbing wires that are 280-micron diameter with a Sn₆₀Pb₄₀ coating are typically joined to solder pads on conventional PERC and TOPCon solar cells to extract charge. Work is underway to further reduce the diameter of these tabbing wires to use them more extensively across the cell. “Micro-wire” technologies soldered to solder pads may be promising but there are challenges associated with soldering tabbing wires to solder pads versus embodiments of the present disclosure (e.g., a metal foil interconnect). When using embodiments of the present disclosure as interconnects (e.g., a metal foil interconnect), it is possible to attach many segmented lines across the solar cell while applying uniform tension because the lines can be supported on more than two sides. For conventional tabbing wire interconnection schemes, it is challenging to segment the tabbing wires along the tabbing wire direction. Perpendicular line patterns are often required to efficiently extract charge from the cell. Tabbing wires that cannot be segmented would require overlapping points when placed perpendicular to other tabbing wires. This can cause stress points that increase cell fracturing. It should be noted that tabbing wires have a curvature that can apply pressure on the solar cell that can increase cracking and is generally harder to solder than flat surfaces. In contrast, by using a metal foil interconnect, for example, it was found it is straightforward to build an interconnection scheme over a wide variety of angles in the same plane. Foils are flat, which can minimize stress on the solar cell and be an easier surface to solder than curved wires. Finally, it is also easier to align one piece of foil than more than 100 individual tabbing wires with sub-20-micron precision. Foil based strategies may be preferable over conventional tabbing wire interconnection schemes due to reduced process complexity and better wafer yields.

CMS-containing solar cells that have solder pads (e.g., FIG. 11 and FIG. 12) can use tabbing wires as interconnects and conventional module stringing/tabbing equipment to interconnect solar cells. In some embodiments of the present disclosure, solar cells that comprise fine grid lines that are conductive multilayer lines comprising conductive multilayer stacks and/or busbars that are conductive multilayer lines comprising conductive multilayer stacks can be incorporated into solar modules. Interconnects may be used to electrically connect solar cells to other components of the module, such as bypass diodes (not shown) and junction boxes (not shown). In some embodiments, an interconnect may comprise tabbing wires 1320 and one or more bus ribbons 1330. Solar cells in a solar module can be electrically coupled together using tabbing wires 1320 as interconnects. In some embodiments of the disclosure herein, a tabbing wire is a metal core with a solder coating. The metal core may comprise copper, aluminum, carbon, tin, iron, an alloy thereof, a composite thereof, or a combination thereof. In some embodiments, a tabbing wire may have a diameter from 80 μm to 1000 μm, from 100 μm to 300 μm, from 120 μm to 200 μm, or any range subsumed therein. The solder coating may have a thickness from 0.5 μm to 100 μm, from 10 to 50 μm, or any range subsumed therein. The solder coating may contain tin, lead, silver, bismuth, copper, zinc, antimony, manganese, indium, an alloy thereof, a composite thereof, or a combination thereof. In some embodiments, a tabbing wire is a copper ribbon that is 150 μm-diameter and is coated with a 20 μm thick tin:lead (60:40 wt %) solder coating. The length of the tabbing wire may be determined by application, design, and substrate dimensions. Modules typically contain bypass diodes, junction boxes and a supporting frame that do not directly contact the solar cell. Bypass diodes and the junction box may also be considered as part of an interconnect.

The front sheet provides some mechanical support to the solar module and has desirable optical transmission properties over the portion of the solar spectrum the solar cell is designed to absorb. Solar modules are positioned so that the front sheet faces a source of illumination, such as sunlight. The front sheet is typically made of low-iron content soda-lime glass. The front encapsulant layer and the rear encapsulant layer protect the solar cell from electrical, chemical, physical, and environmental stressors during operation. Encapsulants are typically in the form of polymeric sheets. Examples of materials that can be used as encapsulants include, but are not limited to, ethylene vinyl acetate (EVA), poly-ethylene-co-methacrylic acid (ionomer), polyvinyl butyral (PVB), thermoplastic urethane (TPU), poly-α-olefin, poly-dimethylsiloxane (PDMS), other polysiloxanes (i.e., silicone), and combinations thereof. The back-sheet provides protection to the solar cell from the rear side and may or may not be optically transparent. Solar modules are positioned so that the back-sheet faces away from a source of illumination. A back-sheet may be a multilayer structure made of three polymeric films. DuPont™ Tedlar® polyvinyl fluoride (PVF) films are typically used in the back sheet. Fluoropolymers and polyethylene terephthalates (PET) can also be used in the back-sheet. Bifacial modules often use transparent back sheet to increase light harvesting on the rear side of the module. A glass sheet may also be used as the back-sheet, which can aid in providing structural support to the solar module. Clear Tedlar may also be used as a polymeric, transparent back-sheet. A supporting frame (not shown) may also be used to improve structure support; supporting frames are typically made of aluminum.

In some embodiments of the present disclosure, a method for forming a solar cell module is provided. The tabbing wires may be soldered to solder pads on a front and/or rear surface of a first solar cell. A subsequent solar cell may be placed adjacent to the first solar cell and the tabbing wire contacting the front and/or rear surface of the first solar cell may be soldered to the solder pads of the rear and/or front surface of the adjacent solar cell. The resulting structure of the tabbing wire, the first solar cell, and the second solar cell may be referred to as a “cell string”. Tabbing wires may be soldered manually with a soldering iron or using an automated tabbing or stringing machine that heats the substrate on the bottom and on the top typically with near infrared heating. Multiple cell strings may be arranged onto a front encapsulation layer that has been applied to a front sheet. These multiple cell strings may be connected to one another by soldering the tabbing wires to bus ribbons to create an electrical circuit. The bus ribbons may be wider than the tabbing wires used in the cell strings. After the electrical circuit between all cell strings is complete, the rear encapsulation material may be applied to the back of the connected cell strings and the back-sheet may be placed on the rear encapsulation material. The assembly is then sealed using a vacuum lamination process and heated (typically below 200° C.) to polymerize the encapsulating material. A frame is typically attached around the front sheet to provide structural support. Finally, a junction box is connected to the cell interconnects and is attached to the solar module. Bypass diodes may be in the junction box or may be attached inside the module during cell interconnection processing.

Both FIG. 3 and FIG. 4 illustrate silver solder pads (e.g., silver solder pads 330 and silver solder pads 430). Accordingly, the solar cells illustrated in FIG. 3 and FIG. 4 may be placed in conventional tabbing wire equipment during solar module fabrication. For conventional solar cells, it may be desirable for a solder pad to have high adhesion to the silicon substrate after soldering a tabbing wire to the solder pad. Poor adhesion at any interface of the tabbing wire/solder pad joint could cause the tabbing wire to detach from the cell (e.g., during thermal cycling) and reduce solar module power conversion efficiency. Soldering tabbing wires to solder pads on solar cells is a challenging process that may result in poor attachment (e.g., cold joint failures) or cell cracking, both of which can be observed using electroluminescence measurements on solar modules before completion. Poorly soldered tabbing wires or damaged solar cells are generally removed and replaced by hand, which reduces solar cell production throughput and increases maintenance costs. Thus, it may be desirable to develop an alternative solar cell interconnect or interconnection process that does not require heating the entire wafer and a high degree of wire placement precision and uses a technique that is more robust than soldering a tabbing wire to a solder pad.

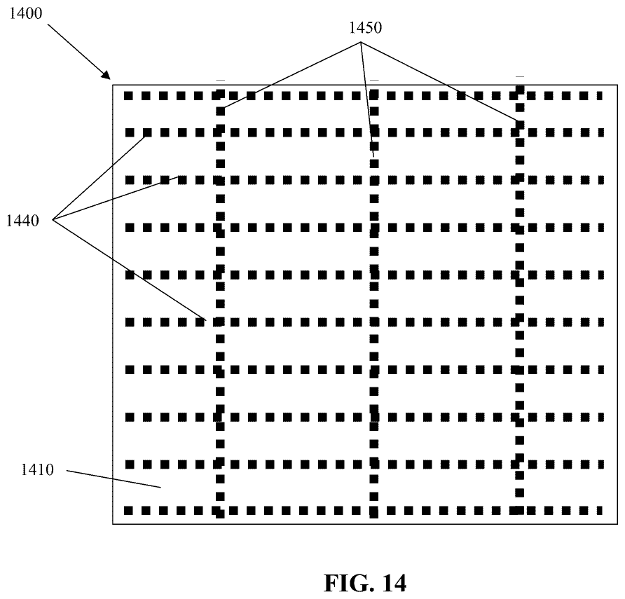

Reference is now made to FIG. 14, which is a schematic of a silicon solar cell 1400 comprising a silicon substrate 1410, a first plurality of silver contact pads 1440, and a second plurality of silver contact pads 1450, consistent with some embodiments of the present disclosure. It is appreciated that silicon solar cell 1400 may comprise at least one passivation layer, as described above, on silicon substrate 1410. First plurality of silver contacts 1440 may be as described above (e.g., silver contact pads 320 in FIG. 3 or first plurality of silver contact pads 420 in FIG. 4). Second plurality of silver contact pads 1450 may be as described above (e.g., second plurality of silver contact pads 440 in FIG. 4). In this cell schematic, solder pads have been completely removed and silicon solar cell 1400 may be interconnected with other solar cells in a module in a different method described below that does not require tabbing wires.

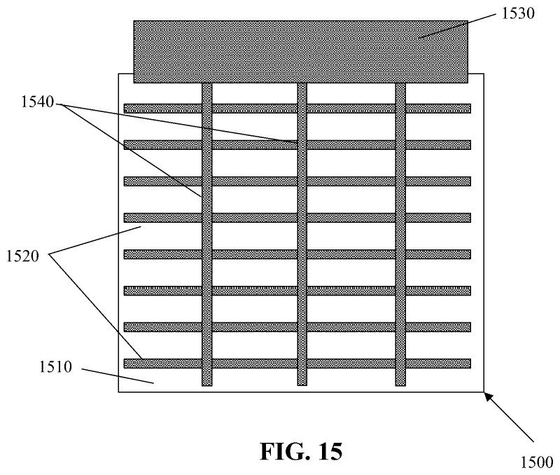

In some embodiments, a solar cell may be fabricated to contain silver contact pads 1440 as shown in FIG. 14. Solar cell 1400 does not have solder pads and may not be connected to a second solar cell using traditional interconnection equipment. After co-firing, solar cell 1400 shown in FIG. 14 may be placed into a screen-printing tool and solder paste may printed on first plurality of silver contact pads 1440 and on second plurality of silver contact pads 1450. A metal foil may be subsequently placed on solar cell 1400, where a heating press is applied at 350° C. for one second to solder the foil onto solar cell 1400 and a nanosecond pulsed laser is subsequently used to cut the desired foil shape shown in FIG. 15. FIG. 15 is a schematic of a silicon solar cell 1500 comprising busbars 1540 that are conductive multilayer lines comprising at least one conductive multilayer stack, as described above, and fine grid lines 1520 that are conductive multilayer lines comprising at least one conductive multilayer stack, as described above, on a silicon substrate 1510, consistent with some embodiments of the present disclosure. It is appreciated that silicon solar cell 1500 may comprise at least one passivation layer, as described above, on silicon substrate 1510. In FIG. 15, solder pads are absent, and an interconnection pad 1530 may be used to electrically connect busbars 1540 . . . . In some embodiments, to connect one silicon solar cell to another, interconnection pad 1530 may be placed on one end of the solar cell, and there may be another interconnection pad on the opposite end of the solar cell (not shown in FIG. 15).

In some embodiments, the metal layers of fine grid lines 1520 may have a width that is less than 500 μm, 450 μm, 400 μm, 350 μm, 300 μm, 250 μm, 200 μm 150 μm, 125 μm, 100 μm, 75 μm, 60 μm, 50 μm, 40 μm, or 30 μm. In some embodiments, the metal layers of fine grid lines 1520 may have a width that range from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm. In some embodiments, the metal layers of fine grid lines 1520 may have a thickness from 4 μm to 100 μm, from 4 μm to 50 μm, from 4 μm to 25 μm, from 4 μm to 10 μm, or from 4 μm to 6 μm. In some embodiments, fine grid lines 1520 contain 25% less, 50% less, 60% less, 75% less, 90% less, or 95% less silver than continuous fine grid lines (e.g., fine grid lines 120 in FIG. 1). In some embodiments, the metal layers of busbars 1540 may have a width that is less than 500 μm, 450 μm, 400 μm, 350 μm, 300 μm, 250 μm, 200 μm, 150 μm, or 100 μm. In some embodiments, the metal layers of busbars 1540 may have a width that is from 4 μm to 500 μm, from 4 μm to 450 μm, from 4 μm to 400 μm, from 4 μm to 350 μm, from 4 μm to 300 μm, from 4 μm to 250 μm, from 4 μm to 200 μm, from 4 μm to 150 μm, from 4 μm to 100 μm, 4 μm to 500 μm, from 4 μm to 50 μm, from 4 μm to 25 μm, from 4 μm to 10 μm, or from 4 μm to 6 μm. In some embodiments, the metal layers of busbars 1540 may have a thickness from 4 μm to 100 μm, from 4 μm to 50 μm, from 4 μm to 25 μm, from 4 μm to 10 μm, or from 4 μm to 6 μm. In some embodiments, busbars 1540 may contain 25% less, 50% less, 60% less, 75% less, 90% less, or 95% less silver than conventional busbars (e.g., busbars 140 in FIG. 1).

Interconnection pad 1530 may be connected at multiple points to busbars 1540 and/or fine grid lines 1520. In some embodiments, interconnection pad 1530 may be a copper foil or an aluminum foil. In some embodiments, interconnection pad 1530 may be welded to the metal layer of busbars 1540 and/or fine grid lines 1520. In some embodiments, interconnection pad 1530 may be a conductive multilayer line comprising at least two conductive multilayer stacks, as described above. FIG. 15 illustrates that silver consumption can be dramatically reduced. Low foil utilization can be supported by reducing silver consumption by at least 30 wt. %, at least 50 wt. %, at least 60 wt. %, at least 75 wt. %, at least 80 wt. %, or at least 90 wt. % versus solar cells that use conventional fine grid lines and/or conventional busbars, and solder pads.

Copper foil and aluminum foil can be ultrasonically welded or laser welded to the same metal (e.g., copper/copper and aluminum/aluminum joints). These techniques can enable solder free interconnections where a metal foil may extend beyond the solar cell edge. Herein are set forth processes for making and using copper foils or coated aluminum foils that can be ultrasonically welded to a metal layer in a conductive multilayer stack or conductive multilayer line to enable novel solar cell interconnection schemes for symmetric and asymmetric solar cell modules.

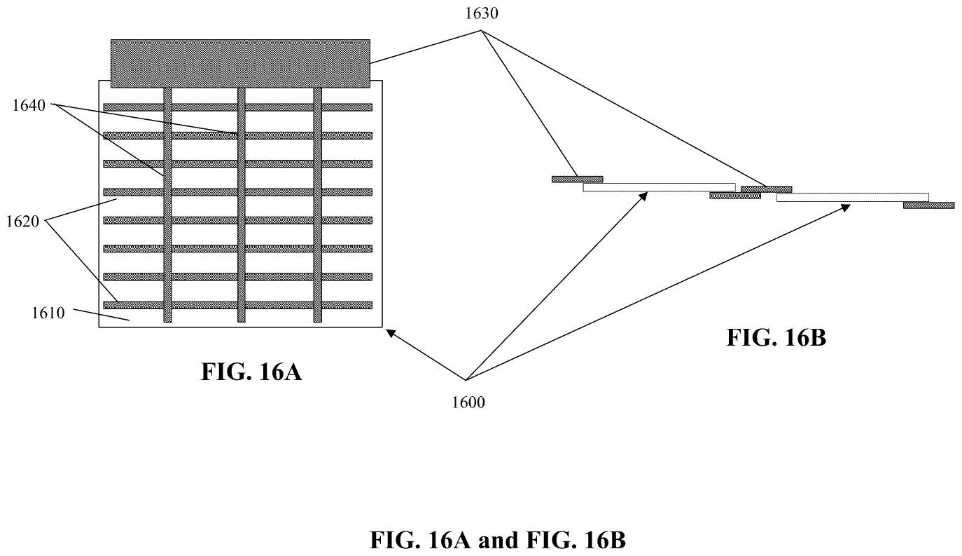

In some embodiments, an interconnect in a solar module comprises an interconnection pad on a first solar cell that is connected to an interconnection pad on a second solar cell. Symmetric solar cells comprising fine grid lines that are conductive multilayer lines, as described above and busbars that are conductive multilayer lines, as described above, and no solder pads (e.g., FIG. 15) may further comprise interconnection pads 1530 made from base metals that extend beyond an edge of the solar cell. Reference is now made to FIG. 16A, which is a schematic of a silicon solar cell 1600 comprising fine grid lines 1620 that are conductive multilayer lines comprising at least one conductive multilayer stack, as described above, and busbars 1640 that are conductive multilayer lines comprising at least one conductive multilayer stack, as described above, on a silicon substrate 1610, consistent with some embodiments of the present disclosure. It is appreciated that silicon solar cell 1600 may comprise at least one passivation layer, as described above, on silicon substrate 1610. As illustrated in FIG. 16A, interconnection pads 1630 extend past an edge of silicon substrate 1610. In some embodiments, symmetric solar cells may be joined together using interconnection pads as shown in FIG. 16B. In some embodiments, a first silicon solar cell of FIG. 16A may be connected to a second silicon solar cell of FIG. 16A via interconnection pads 1630. FIG. 16B illustrates interconnection pad 1630 on one end of the rear surface of a solar cell in contact with another interconnection pad 1630 on the front surface of a second solar cell, consistent with some embodiments of the present disclosure. In some embodiments, interconnection pads 1630 may be ultrasonically welded together. In some embodiments, interconnection pads 1630 may be laser welded together. In some embodiments, no solder material is needed to connect the interconnection pads 1630. Thus, some embodiments in the present disclosure (e.g., as illustrated in FIG. 16B) may eliminate lead (Pb) from the solar cell modules because tabbing wires are conventionally made using a tin (Sn) and Pb solder.

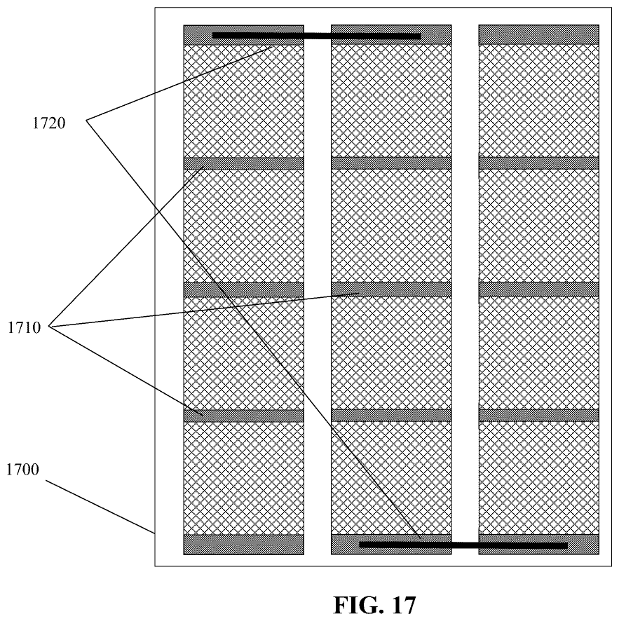

Reference is now made to FIG. 17, which is a schematic of a solar cell module 1700 comprising symmetric solar cells with interconnection pads, consistent with some embodiments of the present disclosure. FIG. 17 illustrates stacking of solar cells in series without the need for tabbing wires. FIG. 17 also illustrates bus ribbon 1720, which electrically connects two interconnection pads from adjacent serially-stacked solar cell stacks. The welded joints 1710 are formed by welding the interconnection pads. Welded joints 1710 may join the front of one solar cell to the rear of another (adjacent) solar cell. It is appreciated that solar cells of solar cell module 1700 may comprise at least one passivation layer, as described above, thereon. It is appreciated that solar cells of solar cell module 1700 may comprise fine grid lines that are conductive multilayer lines (e.g., fine grid lines 1620 in FIG. 16A) comprising at least one conductive multilayer stack, as described above. It is appreciated that solar cells of solar cell module 1700 may comprise busbars that are conductive multilayer lines (e.g., busbars 1640 in FIG. 16A) comprising at least one conductive multilayer stack, as described above.

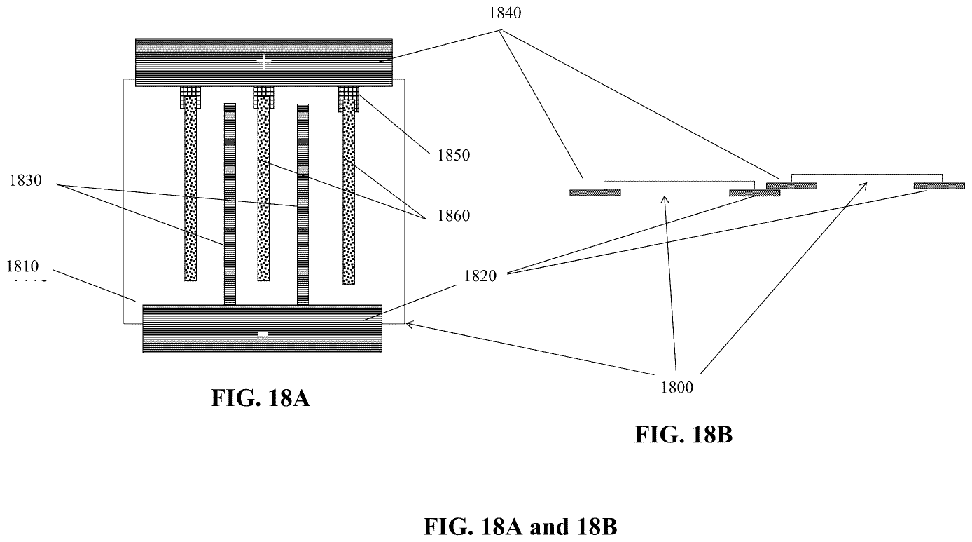

A similar technique as described in FIGS. 16A, 16B, and 17 can be used for asymmetric cells. Reference is now made to FIG. 18A, which is a schematic of an asymmetric silicon solar cell 1800 comprising fine grid lines 1830 that are conductive multilayer lines comprising at least two conductive multilayer stacks, as described above, and interconnection pads 1820 and 1840 on a silicon substrate 1810, consistent with some embodiments of the present disclosure. It is appreciated that asymmetric silicon solar cell 1800 may comprise at least one passivation layer, as described above, on silicon substrate 1810. FIG. 18A also illustrates aluminum fine grid lines 1860 connected to silver pads 1850, which are connected to interconnection pad 1840. Aluminum fine grid lines 1860 may be on at least one first portion of silicon wafer 1820 and fine grid lines 1830 may on at least one second portion of silicon wafer 1820. In some embodiments, the at least one first portion of silicon wafer 1820 is a doped region and the at least one second portion of silicon wafer 1820 is an oppositely-doped region. It is appreciated that FIG. 18A is not intended to be limiting with respect to asymmetric solar cell designs. As a non-limiting example, and as described above in FIG. 5 and FIG. 6, aluminum fine grid lines 1860 and silver pads 1850 may be replaced with fine grid lines that are conductive multilayer lines comprising at least two conductive multilayer stacks, as described above.

As illustrated in FIGS. 18A and 18B, interconnection pads 1820 and 1840 may extend past an edge of silicon substrate 1810. In some embodiments, interconnection pads 1820 and 1840 may be a metal foil welded to fine grid lines 1830 and silver pads 1850, respectively. In some embodiments, interconnection pads 1820 and 1840 may be conductive multilayer lines comprising at least two conductive multilayer stacks, as described above. For example, interconnection pad 1820 may comprise a metal foil soldered to a solderable layer on a plurality of silver contact pads (e.g., second plurality of silver contact pads 620 in FIG. 6). In some embodiments, asymmetric solar cells as illustrated in FIG. 18A may be joined together using interconnection pads 1820 and 1840 as shown in FIG. 18B. FIG. 18B illustrates interconnection pad 1820 on a rear surface of a first solar cell that may be welded to interconnection pad 1840 on the rear surface of a second solar cell, consistent with some embodiments of the present disclosure.

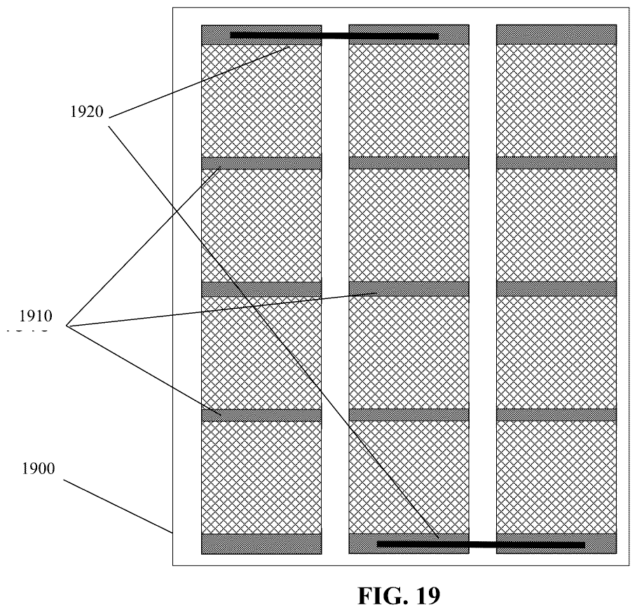

Reference is now made to FIG. 19, which is a schematic of a solar cell module 1900 comprising asymmetric solar cells with interconnection pads, consistent with some embodiments of the present disclosure. FIG. 19 illustrates stacking of solar cells in series without the need for tabbing wires. FIG. 19 also illustrates bus ribbons 1920, which electrically connects two interconnection pads from adjacent serially-stacked solar cell stacks. The welded joints 1910 may be formed by welding the interconnection pads. Welded joints 1910 may join the front of one solar cell to the rear of another (adjacent) solar cell. In some embodiments, stacking asymmetric solar cells in series using welded joints 1910 may be advantageous because asymmetric cells may not experience any excess heat resulting from applying conventional tabbing wires and can remain flat after interconnection (e.g., may not experience significant bowing). It is appreciated that asymmetric solar cells of solar cell module 1900 may comprise at least one passivation layer, as described above, thereon. It is appreciated that asymmetric solar cells of solar cell module 1900 may comprise fine grid lines that are conductive multilayer lines (e.g., fine grid lines 1830 in FIG. 18A) comprising at least one conductive multilayer stack, as described above.

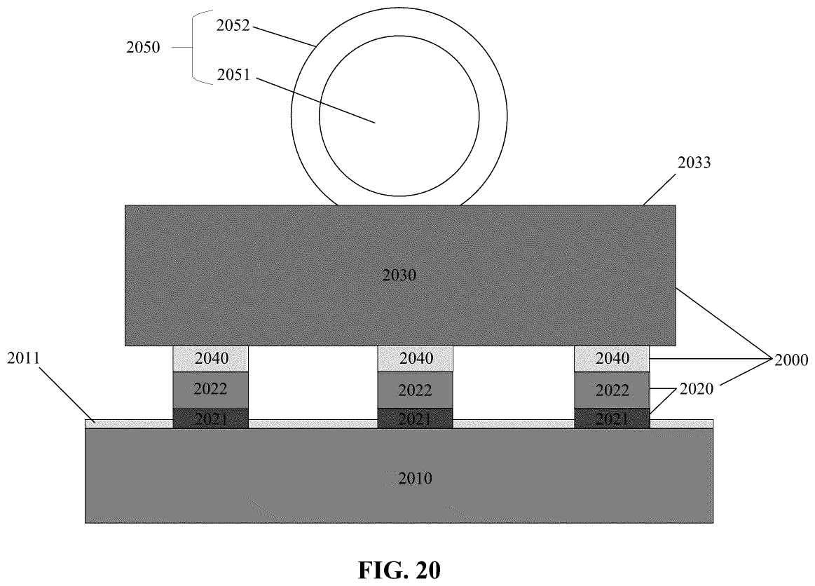

In addition to the above, it was found that tabbing wires may be easily soldered onto a surface of a solar cell that does not include a solder pad, which simplifies tabbing wire soldering with traditional module fabrication equipment. As described above, a common yield issue with a traditional tabbing wire interconnection scheme using a solder pad is that cold joints that may occur when a tabbing wire and solder pad are misaligned or do not completely solder. It was found that, in some embodiments, a tabbing wire may be soldered onto a metal layer, such as of copper foil, of a conductive multilayer stack or conductive multilayer line without the use of a solder pad. Reference is now made to FIG. 20, which is a cross-section schematic of a conductive multilayer line 2000 further comprising a tabbing wire 2050, consistent with some embodiments of the present disclosure. FIG. 20 illustrates a copper metal layer 2030, which has a solderable exposed surface 2033, and tabbing wire 2050 comprises a metal core 2051 and a solder coating 2052, wherein tabbing wire 2050 is soldered to copper metal layer 2030. Conductive multilayer line 2000 may be fabricated as described above, silicon substrate 2010 may be as described above, tabbing wire 2050 may be as described above, and at least one passivation layer 2011 may be as described above. Tabbing wire 2050 may be soldered to copper metal layer 2030 by applying flux between tabbing wire 2050 and metal surface 2033, placing tabbing wire 2050 on conductive multilayer line 2000, and then applying heat. It may be desirable for solder coating 2052 to have a lower liquidus point than solderable layer 2040 to prevent changes to the underlying conductive multilayer line 2000 during soldering.

In some embodiments, an interconnect for a solar cell module (e.g., a solar module comprising symmetric solar cells as described above) may comprise a tabbing wire that contacts a first fine grid line that is a conductive multilayer line, as described above, on a first solar cell and contacts a second fine grid line that is a conductive multilayer line, as described above, on a second solar cell, and wherein the interconnect further comprises a bus ribbon contacting the tabbing wire.

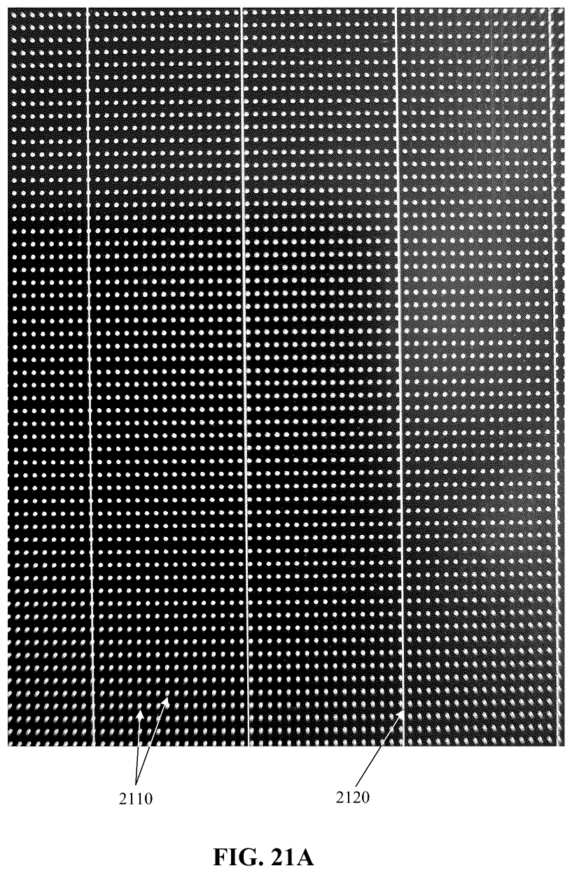

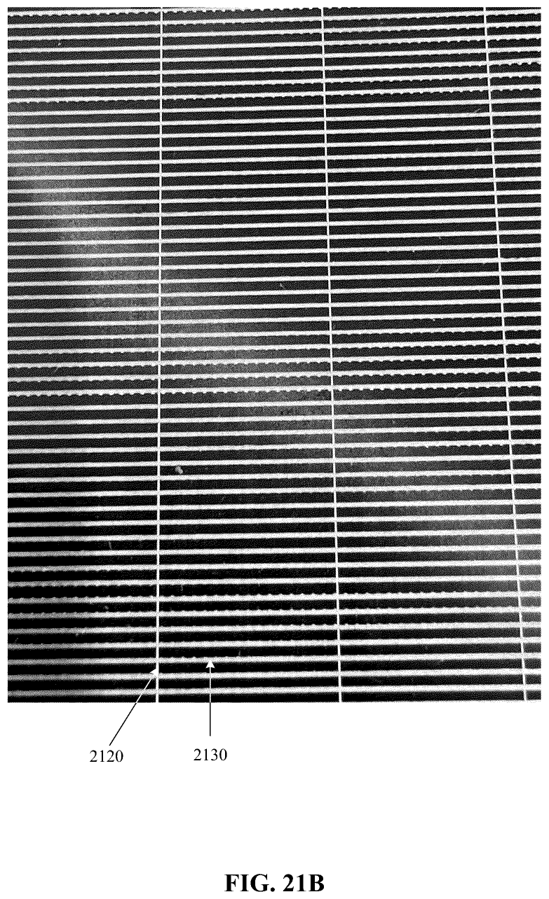

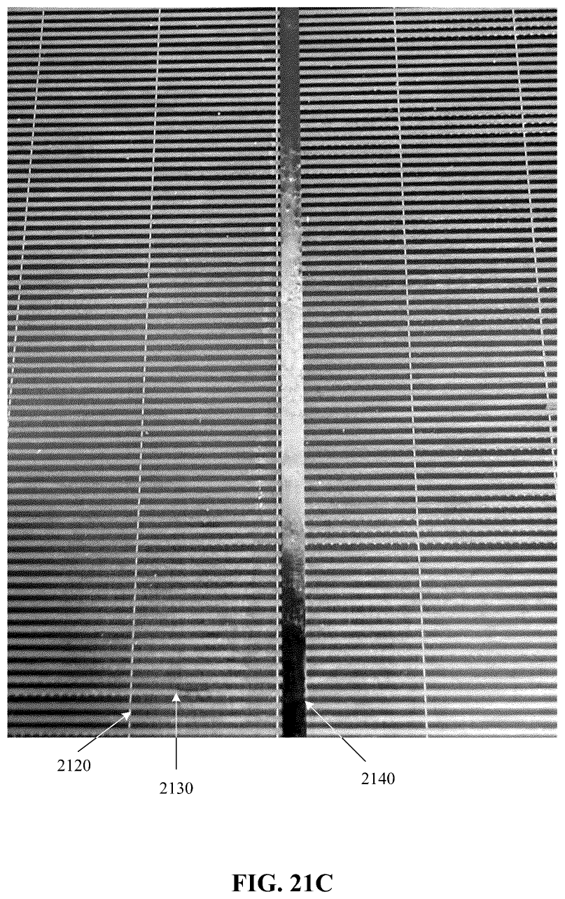

Reference is now made to FIGS. 21A-21C, which are top-view images of a metallized solar cell, consistent with some embodiments of the present disclosure. FIG. 21A is a top-view image of a solar cell and illustrates a plurality of silver contact pads 2110 that are printed throughout a surface of the solar cell, consistent with some embodiments of the present disclosure. In some embodiments, FIG. 21A may be a front surface of the solar cell. In some embodiments, FIG. 21A may be a rear surface of the solar cell. Plurality of silver contact pads 2110 may be as described above. In FIG. 21A, the silver contact pads of plurality of silver contact pads 2110 have a diameter of about 150 microns. In some embodiments, a first silver contact pad of plurality of silver contact pads 2110 may be separated from a second silver contact pad of plurality of silver contact pads 2110 by a distance of 400 microns. In FIG. 21A, an edge of the first silver contact pad of plurality of silver contact pads 2110 may be separated from an edge of the second silver contact pad of plurality of silver contact pads 2110 by a distance of about 400 microns. FIG. 21A further illustrates a busbar 2120, which may be a conductive multilayer line, as described above, or may be comprised of standard materials known in the art.

FIG. 21B is a top-view image of a solar cell as illustrated in FIG. 21A that contains conductive multilayer lines, consistent with some embodiments of the present disclosure. FIG. 21B illustrates conductive multilayer lines 2130 that include plurality of silver contact pads 2110 in FIG. 21A. Specifically, a solderable layer is applied to plurality of silver contact pads 2110, as described above, and a metal layer is applied to the solderable layer, as described above. In some embodiments, conductive multilayer lines 2130 comprise a copper metal layer. In some embodiments, conductive multilayer lines 2130 comprise a copper foil metal layer. In some embodiments, conductive multilayer lines 2130 comprise a metal layer that has a width of 200 microns. In FIG. 21B, the metal layer is a copper foil that has a width of about 200 microns. As seen in FIG. 21B, the metal layer for each conductive multilayer line of conductive multilayer lines 2130 extends across a row of silver contact pads (e.g., a row of plurality of silver contact pads 2110 of FIG. 21A). Conductive multilayer lines 2130 may be connected to busbars 2120.

FIG. 21C is a top-view image of a solar cell as illustrated in FIG. 21B. FIG. 21C illustrates a tabbing wire that contacts a conductive multilayer line, consistent with some embodiments of the present disclosure. Tabbing wire 2140 is shown to contact conductive multilayer lines 2130, as described above. FIG. 21C illustrates that tabbing wire 2140 is soldered to a copper metal layer of a conductive multilayer line of conductive multilayer lines 2130. In some embodiments, tabbing wire 2140 is soldered to a copper metal layer of each conductive multilayer line 2130. In FIG. 21C, tabbing wire 2140 is a tabbing ribbon of SnPb about 0.9 mm wide.

In some embodiments, tabbing wire 2140 may also be an interconnect for the solar cell in FIG. 21C and extend (e.g., up and below view of image in FIG. 21C) to an adjacent solar cell in a solar module. In some embodiments, FIG. 21C shows a rear surface of a solar cell, and tabbing wire 2140 may extend to an adjacent solar cell, where tabbing wire 2140 contacts a solder pad on a front surface of the adjacent solar cell. In some embodiments, FIG. 21C shows a rear surface of a solar cell with at least one passivation layer thereon as described above, and the adjacent solar cell may have at least one passivation layer thereon as described above. In some embodiments, busbars 2120 may not be necessary for a solar cell as illustrated in FIG. 21C, as tabbing wire 2140 may be contacted to each conductive multilayer line of conductive multilayer lines 2130. Thus, busbars 2120 may be optional for a solar cell as shown in FIG. 21C. In some embodiments, silver contact pads that are used to make busbar conductive multilayer lines (e.g., second plurality of silver contact pads 1450 in FIG. 14) may be optional, as FIG. 21C demonstrates that busbars (made of standard materials or conductive multilayer lines) may not be needed to electrically connect fine grid lines on a solar cell.

In some embodiments, applying tabbing wires over multiple conductive multilayer lines may eliminate the need for a solder pad and connect multiple solar cells in a solar module, eliminate busbars, improve yield of tabbing wire contact to a solar cell, and further reduce silver consumption in a solar cell. Tabbing wires are usually joined to solder pads, which may normally require 15-20 mg silver/cell. Solder pads are normally >2 mm wide to ensure tabbing wires can be consistently soldered to the solar cell. In a conventional solar cell, a solder pad is not directly connected to all fine grid lines and require connecting busbars to complete the connection(s). In some embodiments, if one or more tabbing wires are connected to one or more conductive multilayer lines, then a connecting busbar may not be needed.

### Measuring Properties of CMS Layers on Solar Cells

In some embodiments, properties of conductive multilayer stacks and structures comprising conductive multilayer stacks on solar cells may be measured and evaluated.

Stability against corrosion: The contact resistance between layers on solar cells can affect the series resistance and power conversion efficiency. Contact resistance of fine grid lines, busbars, and tabbing layers, with and without one or more conductive multilayer stacks, can be measured using transmission line measurements (TLM) as described by Meier, et al. “Cu Backside Busbar Tape: Eliminating Ag and Enabling Full Al Coverage in Crystalline Silicon Solar Cells”, IEEE Photovoltaic Specialist Conference, Jun. 15-19, 2015, New Orleans, LA, which is included by reference herein. A transmission line plot has a linear behavior with the slope representing the bulk resistivity of the underlying substrate or metal layer and the y-intercept is 2× the contact resistance between the contact layer and the underlying substrate (e.g., silver contact layer/silicon wafer stack). The y-intercept is dependent on the contact area, degree of adhesion and individual layers. During damp heat testing (e.g., 85% relative humidity, 85° C. temperature for 1000-2000 hours) layers can corrode which increases the contact resistance. Corrosion can be a particular problem for metal/metal contacts and the increase in contact resistance increases the series resistance and decreases the fill factor of the module. One of skill in the solar cell art can measure the change in contact resistance due to damp heat testing by performing a TLM on a conductive multilayer stack before and after damp heat testing. The increase in contact resistance may be directly related to the corrosion in the conductive multilayer stack. In some embodiments, the conductive multilayer stack is considered stable against corrosion if the increase in contact resistance of a damp heat-treated sample is less than 5%, less than 10%, less than 15%, less than 20%, less than 25%, less than 50%, less than 100%, less than 200%, less than 400%, less than 500%, or less than 800% versus the pre-treated sample.

Layer thickness: Scanning electron microscopy (SEM) and energy dispersive x-ray spectroscopy (EDX) (referred to collectively as SEM/EDX) can be used to identify individual layers, measure average layer thickness, and thickness variation in structures with and without one or more conductive multilayer stacks. SEM/EDX as used herein were performed using a Zeiss Gemini Ultra-55 analytical field emission scanning electron microscope, equipped with a Bruker XFlash® 6|60 detector. Cross-sectional SEM images of conductive multilayer stack were prepared by ion milling. A thin epoxy layer was applied to the top of the co-fired multilayer stack and dried for at least 30 minutes. The sample was then transferred to a JEOL IB-03010CP ion mill operating at 5 kV and 120 μA for 8 hours to remove 80 microns from the sample edge. Milled samples were stored in a nitrogen glove box prior to SEM/EDX. In addition to cross-section SEM, the film thickness and variation over the described area can be accurately measured using an Olympus LEXT OLS4000 3D Laser Measuring Microscope and/or a profilometer such as a Veeco Dektak 150.

It will be readily apparent to one of ordinary skill in the relevant arts that suitable modifications and adaptations to the structures, methods, and applications described herein can be made without departing from the scope of any embodiments or aspects thereof. The structures and methods provided are exemplary and are not intended to limit the scope of the claimed embodiments. All of the various embodiments, aspects, and options disclosed herein can be combined in all variations. The scope of the structures, methods, and applications described herein include all actual or potential combinations of embodiments, aspects, options, examples, and preferences herein. All patents and publications cited herein are incorporated by reference herein for the specific teachings thereof as noted, unless other specific statements of incorporation are specifically provided.

Before describing exemplary embodiments of the present disclosure, it is to be understood that the disclosure is not limited to the details of construction or process steps set forth in the following examples and is capable of other embodiments and of being practiced or being carried out in various ways. The embodiments may be further described using the following clauses:
1. A conductive multilayer stack comprising:
a metal layer comprising copper (Cu) or coated aluminum;
a silver contact layer comprising a silver sublayer and a glass frit sublayer, wherein the silver sublayer is on the glass frit sublayer; and
a solderable layer between, and contacting, the metal layer and the silver contact layer; and
wherein the glass frit sublayer of the conductive multilayer stack contacts at least a portion of a silicon substrate, contacts at least a portion of an at least one passivation layer on the silicon substrate, or contacts a combination thereof.
2. The conductive multilayer stack of clause 1, wherein the metal layer has a thickness ranging from 4 μm to 100 μm, from 4 μm to 50 μm, from 4 μm to 25 μm, from 4 μm to 10 μm, or from 4 μm to 6 μm.
3. The conductive multilayer stack of clause 1 or 2, wherein the metal layer has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm.
4. The conductive multilayer stack of any one of clauses 1-3, wherein the substrate has a thickness ranging from 120 μm to 180 μm.
5 The conductive multilayer stack of any one of clauses 1-4, wherein the metal layer comprises, consists of, or consists essentially of Cu.
6 The conductive multilayer stack of any one of clauses 1-5, wherein the metal layer comprises, consists of, or consists essentially of coated aluminum.
7. The conductive multilayer stack of clause 6, wherein the coated aluminum comprises an aluminum layer and, on at least one side of the aluminum layer, at least one corrosion resistant joining layer contacting the solderable layer.
8. The conductive multilayer stack of clause 7, wherein the coated aluminum does not comprise a native oxide between the aluminum layer and the at least one corrosion resistant joining layer.
9. The conductive multilayer stack of clause 7 or 8, wherein the at least one corrosion resistant joining layer is:
an alloy of aluminum and a metal, wherein the metal is:
selected from copper (Cu), magnesium (Mg), manganese (Mn), silicon (Si), tin (Sn), zinc (Zn), and combinations thereof;
selected from chromium (Cr), cobalt (Co), molybdenum (Mo), nickel (Ni), tantalum (Ta), titanium (Ti), tungsten (W), alloys thereof, nitrides thereof, borides thereof, composites thereof, and combinations thereof, or
selected from Ti, alloys thereof, nitrides thereof, borides thereof, composites thereof, and combinations thereof.
10. The conductive multilayer stack of any one of clauses 7 to 9, further comprising a second metal layer between, and contacting, the at least one corrosion resistant joining layer and the solderable layer.
11. The conductive multilayer stack of clause 10, wherein the second metal layer comprises copper.
12. The conductive multilayer stack of any one of clauses 7 to 11, wherein the at least one corrosion resistant joining layer has a thickness, width, or both, ranging from 50 nm to 200 nm, or from 20 nm to 100 nm.
13. The conductive multilayer stack of any one of clauses 1 to 12, wherein the glass frit sublayer penetrates through the at least one passivation layer.
14. The conductive multilayer stack of any one of clauses 1 to 13, wherein the metal layer has a surface roughness Ra ranging from 100 nm to 500 nm, from 200 nm to 500 nm, or from 300 nm to 500 nm.
15. The conductive multilayer stack of any one of clauses 1 to 14, wherein the metal layer is laser cut.
16. The conductive multilayer stack of clause 15, wherein the metal layer has a burr roughness ranging from 200 nm to 20 μm, from 1 μm to 10 μm, or from 1 μm to 5 μm.
17. The conductive multilayer stack of clause 15 or 16, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.
18. The conductive multilayer stack of any one of clauses 15 to 17, wherein the metal layer has a burr mean height ranging from 200 nm to 20 μm, from 1 μm to 10 μm, or from 1 μm to 5 μm.
19. The conductive multilayer stack of any one of clauses 15 to 18, wherein the metal layer has a dross mean height ranging from 200 nm to 20 μm, from 1 μm to 10 μm, or from 1 μm to 5 μm.
20. The conductive multilayer stack of any one of clauses 15 to 19, wherein the metal layer has a dross roughness ranging from 200 nm to 20 μm, from 1 μm to 10 μm, or from 1 μm to 5 μm.
21. The conductive multilayer stack of any one of clauses 1 to 20, wherein the solderable layer has a thickness of less than 40 μm, less than 30 μm, less than 25 μm, less than 20 μm, or less than 10 μm.
22. The conductive multilayer stack of any one of clauses 1 to 21, wherein the silver sublayer has a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.
23. The conductive multilayer stack of any one of clauses 1 to 22, wherein the glass frit sublayer has a thickness from 1 nm to 3 μm, from 1 nm to 1 μm, or from 1 nm to 200 nm.
24 The conductive multilayer stack of any one of clauses 1-23, wherein the solderable layer is a solder layer comprising a solder material.
25. The conductive multilayer stack of clause 24, wherein the solder material is a Silver-Aluminum-Copper (SAC) solder material.
26. The conductive multilayer stack of any one of clauses 1-25, where the silver contact layer is a silver contact pad.
27. The conductive multilayer stack of any one of clauses 1 to 26, wherein the silicon substrate and at least one passivation layer are the silicon substrate and the at least one passivation layer of a solar cell.
28. A solar cell comprising at least two grid lines having two or more conductive multilayer stacks of any one of clauses 1 to 27.
29. The solar cell of clause 28, wherein the at least two grid lines are a fine grid line, a busbar, or a combination thereof.
30 The solar cell of clause 29, wherein a silver contact pad of a first conductive multilayer stack of the two or more conductive multilayer stacks is separated from a silver contact pad of a second conductive multilayer stack of the two or more conductive multilayer stacks by a distance from 200 μm to 2 mm, from 300 μm to 1 mm, from 300 μm to 1 mm, from 400 μm to 1 mm, or from 400 μm to 900 μm.
31. A conductive multilayer line, comprising:
at least two conductive multilayer stacks on a silicon substrate having at least one passivation layer, a conductive multilayer stack of the at least two conductive multilayer stacks comprising:
a metal layer comprising copper (Cu) or coated aluminum;
a silver contact pad comprising a silver sublayer and a glass frit sublayer, wherein the silver sublayer is on the glass frit sublayer; and
a solderable layer between, and contacting, the metal layer and the silver contact pad;
wherein the glass frit sublayer of the conductive multilayer stack contacts at least a portion of the silicon substrate, contacts at least a portion of the at least one passivation layer, or contacts a combination thereof; and
wherein the metal layer of the conductive multilayer stack is a continuous layer that connects the at least two conductive multilayer stacks.
32. The conductive multilayer line of clause 31, wherein a silver contact pad of a first conductive multilayer stack the at least two conductive multilayer stacks is separated from a silver contact pad of a second conductive multilayer stack of the at least two conductive multilayer stacks by a distance from 200 μm to 2 mm, 300 μm to 1 mm, 300 μm to 1 mm, 400 μm to 1 mm, or 400 μm to 900 μm.
33. The conductive multilayer line of clause 31 or 32, wherein the metal layer has a thickness ranging from 4 μm to 100 μm, from 4 μm to 50 μm, from 4 μm to 25 μm, from 4 μm to 10 μm, or from 4 μm to 6 μm.
34 The conductive multilayer line of any one of clauses 31 to 33, wherein the metal layer has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, 50 μm to 100 μm, or from 50 μm to 75 μm.
35. The conductive multilayer line of any one of clauses 31 to 34, wherein the silicon substrate has a thickness ranging from 120 μm to 180 μm.
36. The conductive multilayer line of any one of clauses 31 to 35, wherein the metal layer comprises, consists of, or consists essentially of Cu.
37. The conductive multilayer line of any one of clauses 31 to 35, wherein the metal layer comprises, consists of, or consists essentially of coated aluminum.
38. The conductive multilayer line of clause 37, wherein the coated aluminum comprises an aluminum layer and, on at least one side of the aluminum layer, at least one corrosion resistant joining layer contacting the solderable layer.
39 The conductive multilayer line of clause 38, wherein the coated aluminum layer does not comprise a native oxide between the aluminum layer and the at least one corrosion resistant joining layer.
40 The conductive multilayer line of clause 38 or 39, wherein the at least one corrosion resistant joining layer is:
an alloy of aluminum and a metal, wherein the metal is:
selected from copper (Cu), magnesium (Mg), manganese (Mn), silicon (Si), tin (Sn), zinc (Zn), and a combination thereof;
selected from chromium (Cr), cobalt (Co), molybdenum (Mo), nickel (Ni), tantalum (Ta), titanium (Ti), tungsten (W), an alloy thereof, a nitride thereof, a boride thereof, a composite thereof, and a combination thereof; or
selected from Ti, an alloy thereof, a nitride thereof, a boride thereof, a composite thereof, and a combination thereof.
41. The conductive multilayer line of any one of clauses 38 to 40, further comprising a second metal layer between, and contacting, the at least one corrosion resistant joining layer and the solderable layer.
42. The conductive multilayer line of clause 41, wherein the second metal layer comprises copper.
43. The conductive multilayer line of any one of clauses 38 to 42, wherein the at least one corrosion resistant joining layer has a thickness, width, or both, ranging from 50 nm to 200 nm, or from 20 nm to 100 nm.
44. The conductive multilayer line of any one of clauses 31 to 43, wherein the glass frit sublayer penetrates through the at least one passivation layer.
45. The conductive multilayer line of any one of clauses 31 to 44, wherein the metal layer has a surface roughness Ra ranging from 100 nm to 500 nm, from 200 nm to 500 nm, or from 300 nm to 500 nm.
46. The conductive multilayer line of any one of clauses 31 to 45, wherein the metal layer is laser cut.
47. The conductive multilayer line of clause 46, wherein the metal layer has a burr roughness ranging from 200 nm to 20 μm, from 1 μm to 10 μm, or from 1 μm to 5 μm.
48. The conductive multilayer line of clause 46 or 47, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.
49. The conductive multilayer line of any one of clauses 46 to 48, wherein the metal layer has a burr mean height ranging from 200 nm to 20 μm, from 1 μm to 10 μm, or from 1 μm to 5 μm.
50. The conductive multilayer line of any one of clauses 46 to 49, wherein the metal layer has a dross mean height ranging from 200 nm to 20 μm, from 1 μm to 10 μm, or from 1 μm to 5 μm.
51. The conductive multilayer line of any one of clauses 46 to 50, wherein the metal layer has a dross roughness ranging from 200 nm to 20 μm, from 1 μm to 10 μm, or from 1 μm to 5 μm.
52. The conductive multilayer line of any one of clauses 46 to 51, wherein the solderable layer has a thickness of less than 40 μm, less than 30 μm, less than 25 μm, less than 20 μm, or less than 10 μm.
53. The conductive multilayer line of any one of clauses 31 to 52, wherein the silver contact pad has a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm
54. The conductive multilayer line of any one of clauses 31 to 53, wherein the glass frit sublayer has a thickness from 1 nm to 3 μm, from 1 nm to 1 μm, or from 1 nm to 200 nm.
55. The conductive multilayer line of any one of clauses 31 to 54, wherein the solderable layer is a solder layer comprising a solder material.
56 The conductive multilayer line of clause 55, wherein the solder material is a Silver-Aluminum-Copper (SAC) solder material.
57. The conductive multilayer line of any one of clauses 31 to 56, wherein the metal layer is flat.
58. The conductive multilayer line of any one of clauses 31 to 57, wherein the silicon substrate and at least one passivation layer are the silicon substrate and the at least one passivation layer of a solar cell.
59. The conductive multilayer line of any one of clauses 31 to 58, wherein the conductive multilayer line is a fine grid line, a busbar, or a combination thereof of a solar cell.
60. The conductive multilayer line of any one of clauses 31 to 59, wherein the conductive multilayer line comprises at least three conductive multilayer stacks, wherein the metal layer of the conductive multilayer stack is a continuous layer that connects the at least three conductive multilayer stacks.
61. A conductive multilayer stack on a solar cell, the conductive multilayer stack comprising:
a metal layer comprising copper (Cu) or coated aluminum;
a silver contact layer comprising a silver sublayer and a glass frit sublayer, wherein the silver sublayer is on the glass frit sublayer; and
a solderable layer between, and contacting, the metal layer and the silver contact layer; and
wherein the solar cell has a doped silicon substrate with a front surface and a rear surface, wherein the front surface of the doped silicon substrate is a light-facing surface, and wherein the rear surface of the doped silicon substrate is opposite of the light-facing surface of the doped silicon substrate;
wherein the front and/or rear surface of the doped silicon substrate has at least one passivation layer thereon; and
wherein the glass frit sublayer of the conductive multilayer stack contacts at least a portion of the front and/or rear surface of the doped silicon substrate, contacts at least a portion of the at least one passivation layer, or contacts a combination of both.
62. The conductive multilayer stack of clause 61, wherein the at least one passivation layer comprises a tunnel oxide layer, a doped layer on at least a portion of the tunnel oxide layer, wherein the doped layer comprises an n-type doped polysilicon (poly-Si), and at least one SiOxNy passivation layer on at least a portion of the doped layer.
63. The conductive multilayer stack of clause 62, wherein the glass frit sublayer penetrates through the at least one SiOxNy passivation layer and contacts the doped layer.
64. The conductive multilayer stack of clause 62 or 63, wherein the tunnel oxide layer comprises SiOₓ.
65. The conductive multilayer stack of any one of clauses 62 to 64, wherein the at least one SiOxNy passivation layer comprises SiOₓ, SiN_{y}, SiON, or combinations thereof.
66. The conductive multilayer stack of any one of clauses 62 to 65, wherein the tunnel oxide layer has a thickness that ranges from 1 nm to 5 nm.
67. The conductive multilayer stack of any one of clauses 62 to 66, wherein the doped layer has a thickness that ranges from 50 nm to 200 nm.
68. The conductive multilayer stack of any one of clauses 62 to 67, wherein the at least one SiOxNy passivation layer has a thickness that ranges from 50 nm to 100 nm.
69. The conductive multilayer stack of clause 61, wherein the at least one passivation layer comprises SiOₓ, AlOₓ, or SiOxNy.
70 The conductive multilayer stack of clause 69, wherein the at least one passivation layer comprises a first passivation layer comprising SiOₓ and at least one second passivation layer comprising SiOxNy, wherein the at least one second passivation layer is on at least a portion of the first passivation layer.
71. The conductive multilayer stack of clause 69, wherein the at least one passivation layer comprises a first passivation layer comprising AlOₓ and at least one second passivation layer comprising SiOxNy, wherein the at least one second passivation layer is on at least a portion of the first passivation layer.
72. The conductive multilayer stack of clause 70 or 71, wherein the at least one second passivation layer comprising SiOxNy comprises SiOₓ, SiN_{y}, SiON, or a combination thereof.
73. The conductive multilayer stack of any one of clauses 70 to 72, wherein the first passivation layer has a thickness ranging from 1 nm to 5 nm.
74. The conductive multilayer stack of any one of clauses 70 to 73, wherein the at least one second passivation layer has a thickness ranging from 50 nm to 100 nm.
75. The conductive multilayer stack of any one of clauses 70 or 72 to 74, further comprising an intermediate passivation layer between the first passivation layer and the at least one second passivation layer, and wherein the intermediate passivation layer comprises AlOₓ.
76 The conductive multilayer stack of clause 75, wherein the intermediate passivation layer has a thickness ranging from 1 nm to 5 nm.
77. The conductive multilayer stack of any one of clauses 69 to 76, wherein the glass frit sublayer penetrates through the at least one passivation layer.
78. The conductive multilayer stack of clause 61, wherein the front and/or rear surface of the doped silicon substrate further comprises a doped layer, and wherein the doped layer has a different dopant, different dopant type, and/or different dopant concentration from the doped silicon substrate.
79. The conductive multilayer stack of clause 78, wherein the at least one passivation layer comprises SiOₓ, AlOₓ, or SiOxNy.
80 The conductive multilayer stack of clause 79, wherein the at least one passivation layer comprises a first passivation layer comprising SiOₓ and at least one second passivation layer comprising SiOxNy, wherein the at least one second passivation layer is on at least a portion of the first passivation layer.
81 The conductive multilayer stack of clause 80, wherein the first passivation layer has a thickness ranging from 1 nm to 5 nm.
82. The conductive multilayer stack of clause 80 or 81, wherein the at least one second passivation layer has a thickness ranging from 50 to 100 nm.
83 The conductive multilayer stack of any one of clauses 80 to 82, further comprising an intermediate passivation layer between the first passivation layer and the at least one second passivation layer, and wherein the intermediate passivation layer comprises AlOₓ.
84. The conductive multilayer stack of clause 83, wherein the intermediate passivation layer has a thickness from 1 nm to 5 nm.
85. The conductive multilayer stack of any one of clauses 78 to 84, wherein the glass frit sublayer penetrates through the at least one passivation layer and contacts the doped layer.
86. The conductive multilayer stack of any one of clauses 78 to 85, wherein a thickness of the doped layer is from 30 nm to 200 nm.
87. The conductive multilayer stack of any one of clauses 78 to 86, wherein the doped layer comprises an n-type dopant.
88. The conductive multilayer stack of any one of clauses 78 to 86, wherein the doped layer comprises a p-type dopant.
89 The conductive multilayer stack of any one of clauses 61 to 89, wherein the at least one passivation layer is on the front surface of the doped silicon substrate.
90. The conductive multilayer stack of any one of clauses 61 to 89, wherein the at least one passivation layer is on the rear surface of the doped silicon substrate.
91. The conductive multilayer stack of any one of clauses 61 or 69 to 90, wherein the at least one passivation layer is on the rear surface of the doped silicon substrate, wherein the rear surface of the doped silicon substrate further comprises at least one doped layer, and wherein the at least one doped layer comprises at least one doped region and at least one oppositely-doped region.
92. The conductive multilayer stack of clause 91, wherein the at least one doped region comprises a p-type dopant and the at least one oppositely-doped region comprises an n-type dopant.
93. The conductive multilayer stack of clause 91 or 92, wherein the glass frit sublayer penetrates through the at least one passivation layer contacts the at least one doped region.
94. The conductive multilayer stack of clause 91 or 92, wherein the glass frit sublayer penetrates through the at least one passivation layer contacts the at least one oppositely-doped region.
95 The conductive multilayer stack of any one of clauses 91 to 94, wherein the at least one doped region has a thickness ranging from 30 nm to 200 nm.
96. The conductive multilayer stack of any one of clauses 91 to 95, wherein the at least one oppositely-doped region has a thickness ranging from 30 nm to 200 nm.
97. The conductive multilayer stack of any one of clauses 61 to 96, wherein the doped silicon substrate comprises an n-type dopant.
98. The conductive multilayer stack of any one of clauses 61 to 96, wherein the doped silicon substrate comprises a p-type dopant.
99. The conductive multilayer stack of any one of clauses 61 to 98, wherein the metal layer has a thickness ranging from 4 μm to 100 μm, from 4 μm to 50 μm, from 4 μm to 25 μm, from 4 μm to 10 μm, or from 4 μm to 6 μm.
100. The conductive multilayer stack of any one of clauses 61 to 99, wherein the metal layer has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm.
101. The conductive multilayer stack of any one of clauses 61 to 100, wherein the substrate has a thickness ranging from 120 μm to 180 μm.
102. The conductive multilayer stack of any one of clauses 61 to 101, wherein the metal layer comprises, consists of, or consists essentially of Cu.
103. The conductive multilayer stack of any one of clauses 61 to 101, wherein the metal layer comprises, consists of, or consists essentially of coated aluminum.
104. The conductive multilayer stack of clause 103, wherein the coated aluminum comprises an aluminum layer and, on at least one side of the aluminum layer, and at least one corrosion resistant joining layer contacting the solderable layer.
105. The conductive multilayer stack of clause 104, wherein the coated aluminum does not comprise a native oxide between the aluminum layer and the at least one corrosion resistant joining layer.
106. The conductive multilayer stack of clause 104 or 105, wherein the at least one corrosion resistant joining layer is:
an alloy of aluminum and a metal, wherein the metal is:
selected from copper (Cu), magnesium (Mg), manganese (Mn), silicon (Si), tin (Sn), zinc (Zn), and a combination thereof; or
selected from chromium (Cr), cobalt (Co), molybdenum (Mo), nickel (Ni), tantalum (Ta), titanium (Ti), tungsten (W), an alloy thereof, a nitride thereof, a boride thereof, a composite thereof, and a combination thereof; or
selected from Ti, an alloy thereof, a nitride thereof, a boride thereof, a composite thereof, and a combination thereof.
107. The conductive multilayer stack of any one of clauses 104 to 106, further comprising a second metal layer between, and contacting, the at least one corrosion resistant joining layer and the solderable layer.
108. The conductive multilayer stack of clause 107, wherein the second metal layer comprises copper.
109. The conductive multilayer stack of any one of clauses 104 to 108, wherein the at least one corrosion resistant joining layer has a thickness, width, or both, ranging from 50 nm to 200 nm, or from 20 nm to 100 nm.
110. The conductive multilayer stack of any one of clauses 61 to 109, wherein the glass frit sublayer penetrates through the at least one passivation layer and contacts the front and/or rear surface of the doped silicon substrate.
111. The conductive multilayer stack of any one of clauses 61 to 110, wherein the metal layer has a surface roughness Ra ranging from 100 nm to 500 nm, from 200 nm to 500 nm, or from 300 nm to 500 nm.
112. The conductive multilayer stack of any one of clauses 61 to 111, wherein the metal layer is laser cut.
113. The conductive multilayer stack of clause 112, wherein the metal layer has a burr roughness ranging from 200 nm to 20 μm, from 1 μm from 10 μm, or from 1 μm to 5 μm.
114. The conductive multilayer stack of clause 112 or 113, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.
115. The conductive multilayer stack of any one of clauses 112 to 114, wherein the metal layer has a burr mean height ranging from 200 nm to 20 μm, from 1 μm to 10 μm, or from 1 μm to 5 μm.
116. The conductive multilayer stack of any one of clauses 112 to 115, wherein the metal layer has a dross mean height ranging from 200 nm to 20 μm, from 1 μm to 10 μm, or from 1 μm to 5 μm.
117. The conductive multilayer stack of any one of clauses 112 to 116, wherein the metal layer has a dross roughness ranging from 200 nm to 20 μm, from 1 μm to 10 μm, or from 1 μm to 5 μm.
118. The conductive multilayer stack of any one of clauses 61 to 117, wherein the solderable layer has a thickness of less than 40 μm, less than 30 μm, less than 25 μm, less than 20 μm, or less than 10 μm.
119. The conductive multilayer stack of any one of clauses 61 to 118, wherein the silver contact layer has a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.
120. The conductive multilayer stack of any one of clauses 61 to 119, wherein the glass frit sublayer has a thickness from 1 nm to 3 μm, from 1 nm to 1 μm, or from 1 nm to 200 nm.
121. The conductive multilayer stack of any one of clauses 61 to 120, wherein the solderable layer is a solder layer comprising a solder material.
122. The conductive multilayer stack of clause 121, wherein the solder material is a Silver-Aluminum-Copper (SAC) solder material.
123. The conductive multilayer stack of any one of clauses 61 to 122, wherein the silver contact layer is a silver contact pad.
124. The conductive multilayer stack of any one of clauses 61 to 123, wherein the silicon substrate and the at least one passivation layer are the silicon substrate and the at least one passivation layer of a solar cell.
125. A solar cell comprising at least two grid lines having two or more conductive multilayer stacks of any one of clauses 61 to 124.
126. The solar cell of clause 125, wherein the at least two grid lines are a fine grid line, a busbar, or combination thereof.
127. The solar cell of clause 125 or 126, wherein a silver contact pad of a first conductive multilayer stack of the two or more conductive multilayer stacks is separated from a silver contact pad of a second conductive multilayer stack of the two or more conductive multilayer stacks by a distance from 200 μm to 2 mm, from 200 μm to 1 mm, from 300 μm to 1 mm, from 400 μm to 1 mm, or from 400 μm to 900 μm.
128. A symmetric solar cell comprising:
a doped silicon substrate having a front surface and a rear surface;
at least one passivation layer on at least a portion of the front and/or rear surface of the doped silicon substrate, wherein the front surface of the doped silicon substrate is a light-facing surface and the rear surface is opposite of the light-facing surface; and
at least one fine grid line on a portion of the front and/or rear surface of the doped silicon substrate;
wherein the at least one fine grid line is a conductive multilayer line comprising at least two conductive multilayer stacks, a conductive multilayer stack of the at least two conductive multilayer stacks comprising:
a metal layer comprising copper (Cu) or coated aluminum;
a silver contact pad comprising a silver sublayer and a glass frit sublayer, wherein the silver sublayer is on the glass frit sublayer; and
a solderable layer between, and contacting, the metal layer and the silver contact pad;
wherein the glass frit sublayer of the conductive multilayer stack contacts at least a portion of the silicon substrate, contacts at least a portion of the at least one passivation layer, or contacts a combination thereof, and
wherein the metal layer of the conductive multilayer stack is a continuous layer that connects the at least two conductive multilayer stacks in the conductive multilayer line.
129. The symmetric solar cell of clause 128, wherein the at least one passivation layer comprises a tunnel oxide layer, a doped layer on top of at least a portion of the tunnel oxide layer, wherein the doped layer comprises an n-type doped polysilicon (poly-Si), and at least one SiOxNy passivation layer on top of at least a portion of the doped layer.
130. The symmetric solar cell of clause 129, wherein the glass frit sublayer penetrates through the at least one SiOxNy passivation layer and contacts the doped layer.
131. The symmetric solar cell of clause 129 or 130, wherein the tunnel oxide layer comprises SiOₓ.
132. The symmetric solar cell of any one of clauses 129 to 131, wherein the at least one SiOxNy passivation layer comprises SiOₓ, SiN_{y}, SiON, or combinations thereof.
133. The symmetric solar cell of any one of clauses 129 to 132, wherein the tunnel oxide layer has a thickness that ranges from 1 nm to 5 nm.
134. The symmetric solar cell of any one of clauses 129 to 133, wherein the doped layer has a thickness that ranges from 50 nm to 200 nm.
135. The symmetric solar cell of any one of clauses 129 to 134, wherein the at least one SiOxNy passivation layer has a thickness that ranges from 50 nm to 100 nm.
136. The symmetric solar cell of clause 128, wherein the at least one passivation layer comprises SiOₓ, AlOₓ, or SiOxNy.
137. The symmetric solar cell of clause 136, wherein the at least one passivation layer comprises a first passivation layer comprising SiOₓ and at least one second passivation layer comprising SiOxNy, wherein the at least one second passivation layer is on at least a portion of the first passivation layer.
138. The symmetric solar cell of clause 136, wherein the at least one passivation layer comprises a first passivation layer comprising AlOₓ and at least one second passivation layer comprising SiOxNy, wherein the at least one second passivation layer is on at least a portion of the first passivation layer.
139. The symmetric solar cell of clause 137 or 138, wherein the at least one second passivation layer comprising SiOxNy comprises SiOₓ, SiN_{y}, SiON, or any combination thereof.
140. The symmetric solar cell of any one of clauses 137 to 139, wherein the first passivation layer has a thickness ranging from 1 nm to 5 nm.
141. The symmetric solar cell of any one of clauses 137 to 140, wherein the at least one second passivation layer has a thickness ranging from 50 nm to 100 nm.
142. The symmetric solar cell of any one of clauses 137 or 139 to 141, further comprising an intermediate passivation layer between the first passivation layer and the second passivation layer, and wherein the intermediate passivation layer comprises AlOₓ.
143. The symmetric solar cell of clause 142, wherein the intermediate passivation layer has a thickness ranging from 1 nm to 5 nm.
144. The symmetric solar cell of any one of clauses 136 to 143, wherein the glass frit sublayer penetrates through the at least one passivation layer.
145. The symmetric solar cell of clause 128, wherein the front and/or rear surface of the doped silicon substrate further comprises a doped layer, and wherein the doped layer has a different dopant, different dopant type, and/or different dopant concentration from the doped silicon substrate.
146. The symmetric solar cell of clause 145, wherein the at least one passivation layer comprises SiOₓ, AlOₓ, or SiOxNy.
147. The symmetric solar cell of clause 146, wherein the at least one passivation layer comprises a first passivation layer comprising SiOₓ and at least one second passivation layer comprising SiOxNy, wherein the at least one second passivation layer is on at least a portion of the first passivation layer.
148. The symmetric solar cell of clause 147, wherein the first passivation layer has a thickness ranging from 1 nm to 5 nm.
149. The symmetric solar cell of clauses 147 or 148, wherein the at least one second passivation layer has a thickness ranging from 50 to 100 nm.
150. The symmetric solar cell of any one of clauses 147 to 149, further comprising an intermediate passivation layer between the first passivation layer and the at least one second passivation layer, and wherein the intermediate passivation layer comprises AlOₓ.
151. The symmetric solar cell of clause 150, wherein the intermediate passivation layer has a thickness from 1 nm to 5 nm.
152. The symmetric solar cell of any one of clauses 145 to 151, wherein the glass frit sublayer penetrates through the at least one passivation layer contacts the doped layer.
153. The symmetric solar cell of any one of clauses 145 to 152, wherein a thickness of the doped layer is from 30 nm to 200 nm.
154. The symmetric solar cell of any one of clauses 145 to 153, wherein the doped layer comprises an n-type dopant.
155. The symmetric solar cell of any one of clauses 145 to 153, wherein the doped layer comprises a p-type dopant.
156. The symmetric solar cell of any one of clauses 128 to 155, wherein the at least one passivation layer is on the front surface of the doped silicon surface.
157. The symmetric solar cell of any one of clauses 128 to 155, wherein the at least one passivation layer is on the rear surface of the doped silicon substrate.
158. The symmetric solar cell of any one of clauses 128 to 157, wherein the doped silicon substrate is n-type doped.
159. The symmetric solar cell of any one of clauses 128 to 157, wherein the doped silicon substrate is p-type doped.
160. The symmetric solar cell of any one of clauses 128 to 159, further comprising at least one solder pad on a portion of the front and/or rear surface of the doped silicon substrate, wherein the at least one fine grid line contacts the at least one solder pad.
161. The symmetric solar cell of any one of clauses 128 to 160, further comprising at least one busbar on a portion of the front and/or rear surface of the doped silicon substrate, wherein the at least one fine grid line contacts the at least one busbar.
162. The symmetric solar cell of clause 161, wherein the at least one busbar comprises at least two conductive multilayer stacks, a conductive multilayer stack of the at least two conductive multilayer stacks comprising:
a metal layer comprising copper (Cu) or coated aluminum;
a silver contact pad comprising a silver sublayer and a glass frit sublayer, wherein the silver sublayer is on the glass frit sublayer; and
a solderable layer between, and contacting, the metal layer and the silver contact pad;
wherein the glass frit sublayer of the conductive multilayer stack contacts at least a portion of the silicon substrate, contacts at least a portion of the at least one passivation layer, or contacts a combination thereof; and
wherein the metal layer of the conductive multilayer stack is a continuous layer that connects the at least two conductive multilayer stacks of the at least one busbar.
163. The symmetric solar cell of any one of clauses 128 to 162, wherein a silver contact pad of a first conductive multilayer stack of the at least two conductive multilayer stacks of the at least one fine grid line is separated from a silver contact pad of a second conductive multilayer stack of the at least two conductive multilayer stacks by a distance from 200 μm to 2 mm, 300 μm to 2 mm, 300 μm to 1 mm, 400 μm to 1 mm, or 400 μm to 900 μm.
164. The symmetric solar cell of any one of clauses 128 to 163, wherein the metal layer of the at least one fine grid line and the at least one busbar, when present, has a thickness ranging from 4 μm to 100 μm, from 4 μm to 50 μm, from 4 μm to 25 μm, from 4 μm to 10 μm, or from 4 μm to 6 μm.
165. The symmetric solar cell of any one of clauses 128 to 164, wherein the metal layer of the at least one fine grid line and the at least one busbar, when present, has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, 50 μm to 100 μm, or from 50 μm to 75 μm.
166. The symmetric solar cell of any one of clauses 128 to 165, wherein the substrate has a thickness ranging from 120 μm to 180 μm.
167. The symmetric solar cell of any one of clauses 128 to 166, wherein the metal layer of the at least one fine grid line and the at least one busbar, when present, comprises, consists of, or consists essentially of Cu.
168. The symmetric solar cell of clause 167, further comprising a tabbing wire contacting the metal layer of the at least one fine grid line, wherein the tabbing wire comprises a metal core and a solder coating.
169. The symmetric solar cell of clause 168, wherein the tabbing wire is soldered to the metal layer of the at least one fine grid line.
170. The symmetric solar cell of clause 168 or 169, wherein the metal core comprises copper, aluminum, carbon, tin, iron, an alloy thereof, a composite thereof, or a combination thereof.
171. The symmetric solar cell of any one of clauses 168 to 170, wherein the metal core comprises copper.
172. The symmetric solar cell of any one of clauses 168 to 171, wherein the tabbing wire has a diameter from 80 μm to 1000 μm, from 100 μm to 300 μm, or from 120 μm to 200 μm.
173. The symmetric solar cell of any one of clauses 168 to 172, wherein the solder coating has a thickness from 0.5 μm to 100 μm or from 10 μm to 50 μm.
174. The symmetric solar cell of any one of clauses 168 to 173, wherein the solder coating comprises tin, lead, bismuth, copper, zinc, antimony, manganese, indium, an alloy thereof, a composite thereof, or any combination thereof.
175. The symmetric solar cell of any one of clauses 128 to 166 wherein the metal layer of the at least one fine grid line and the at least one busbar, when present, comprises, consists of, or consists essentially of coated aluminum.
176. The symmetric solar cell of clause 175, wherein the coated aluminum comprises an aluminum layer and, on at least one side of the aluminum layer, and at least one corrosion resistant joining layer contacting the solderable layer.
177. The symmetric solar cell of clause 176, wherein the coated aluminum does not comprise a native oxide between the aluminum layer and the at least one corrosion resistant joining layer.
178. The symmetric solar cell of clause 176 or 177, wherein the at least one corrosion resistant joining layer is:
an alloy of aluminum and a metal, wherein the metal is:
selected from copper (Cu), magnesium (Mg), manganese (Mn), silicon (Si), tin (Sn), zinc (Zn), and a combination thereof; or
selected from chromium (Cr), cobalt (Co), molybdenum (Mo), nickel (Ni), tantalum (Ta), titanium (Ti), tungsten (W), an alloy thereof, a nitride thereof, a boride thereof, a composite thereof, and a combination thereof; or
selected from Ti, an alloy thereof, a nitride thereof, a boride thereof, a composite thereof, and a combination thereof.
179. The symmetric solar cell of any one of clauses 176 to 178, further comprising a second metal layer between, and contacting, the at least one corrosion resistant joining layer and the solderable layer.
180. The symmetric solar cell of clause 179, wherein the second metal layer comprises copper.
181. The symmetric solar cell of any one of clauses 176 to 180, wherein the at least one corrosion resistant joining layer has a thickness, width, or both, ranging from 50 nm to 200 nm, or from 20 nm to 100 nm.
182. The symmetric solar cell of any one of clauses 128 to 181, wherein the metal layer of the at least one fine grid line and the at least one busbar, when present, has a surface roughness Ra ranging from 100 nm to 500 nm, from 200 nm to 500 nm, or from 300 nm to 500 nm.
183. The symmetric solar cell of any one of clauses 128 to 182, wherein the metal layer of the at least one fine grid line and the at least one busbar, when present, is laser cut.
184. The symmetric solar cell of clause 183, wherein the metal layer has a burr roughness ranging from 200 nm to 20 μm, from 1 μm from 10 μm, or from 1 μm to 5 μm.
185. The symmetric solar cell of clause 183 or 184, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.
186. The symmetric solar cell of any one of clauses 183 to 185, wherein the metal layer has a burr mean height ranging from 200 nm to 20 μm, from 1 μm to 10 μm, or from 1 μm to 5 μm.
187. The conductive multilayer stack of any one of clauses 183 to 186, wherein the metal layer has a dross mean height ranging from 200 nm to 20 μm, from 1 μm to 10 μm, or from 1 μm to 5 μm.
188. The conductive multilayer stack of any one of clauses 183 to 187, wherein the metal layer has a dross roughness ranging from 200 nm to 20 μm, from 1 μm to 10 μm, or from 1 μm to 5 μm.
189. The symmetric solar cell of any one of clauses 128 to 188, wherein the solderable layer of the at least one fine grid line and the at least one busbar, when present, has a thickness of less than 40 μm, less than 30 μm, less than 25 μm, less than 20 μm, or less than 10 μm.
190. The symmetric solar cell of any one of clauses 128 to 189, wherein the silver contact pad of the at least one fine grid line and the at least one busbar, when present, has a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.
191. The symmetric solar cell of any one of clauses 128 to 190, wherein the glass frit sublayer of the at least one fine grid line and the at least one busbar, when present, has a thickness from 1 nm to 3 μm, from 1 nm to 1 μm, or from 1 nm to 200 nm.
192. The symmetric solar cell of any one of clauses 128 to 191, wherein the solderable layer of the at least one fine grid line and the at least one busbar, when present, is a solder layer comprising a solder material.
193. The symmetric solar cell of clause 192, wherein the solder material is a Silver-Aluminum-Copper (SAC) solder material.
194. The symmetric solar cell of any one of clauses 128 to 193, wherein the front and/or rear surface of the doped silicon substrate has a total surface area, wherein the silver contact pads of the at least one fine grid line and the at least one busbar, when present, have a combined surface area, and wherein the combined surface area ranges from 0.5% to 7%, from 0.5% to 6%, from 0.5% to 5%, from 0.5% to 4%, from 0.5% to 3%, from 0.5% to 2%, from 0.5% to 1%, or from 0.5% to 0.75% of the total surface area.
195. An asymmetric solar cell comprising:
a silicon substrate having a front, light-facing surface and a rear surface, wherein the rear surface is opposite of the light-facing surface;
at least one passivation layer directly on at least a portion of the rear surface of the silicon substrate;
at least one first fine grid line on at least a portion of the rear surface of the silicon substrate;
at least one second fine grid line on at least a portion of the rear surface of the silicon substrate;
wherein the at least one first grid line or the at least one second fine grid line is a first conductive multilayer line comprising at least two conductive multilayer stacks;
wherein a conductive multilayer stack of the at least two conductive multilayer stacks comprises:
a metal layer comprising copper (Cu) or coated aluminum;
a silver contact pad comprising a silver sublayer and a glass frit sublayer, wherein the silver sublayer is on the glass frit sublayer; and
a solderable layer between, and contacting, the metal layer and the silver contact pad;
wherein the glass frit sublayer of the conductive multilayer stack contacts the rear surface of the silicon substrate, contacts the at least one passivation layer, or contacts a combination thereof; and
wherein the metal layer of the conductive multilayer stack is a continuous layer that connects the at least two conductive multilayer stacks of the first conductive multilayer line.
196. The asymmetric solar cell of clause 195, wherein either the at least one first fine grid line or the at least one second fine grid line is the first conductive multilayer line and the other comprises sintered aluminum.
197. The asymmetric solar cell of clause 195, wherein the at least one first fine grid line is a first conductive multilayer line comprising at least two conductive multilayer stacks, and wherein the at least one second fine grid line is a second conductive multilayer line comprising at least two conductive multilayer stacks.
198. The asymmetric solar cell of any one of clauses 195 to 197, further comprising:
at least one first interconnection pad contacting the at least one first fine grid line; and
at least one second interconnection pad contacting the at least one second fine grid line;
wherein the at least one first interconnection pad is a third conductive multilayer line comprising at least two conductive multilayer stacks; and
wherein the at least one second interconnection pad is a fourth conductive multilayer line comprising at least two conductive multilayer stacks, a conductive multilayer stack of the at least two conductive multilayer stacks in the third and/or fourth conductive multilayer line comprising:
a metal layer comprising copper (Cu) or coated aluminum;
a silver contact pad comprising a silver sublayer and a glass frit sublayer, wherein the silver sublayer is on the glass frit sublayer; and
a solderable layer between, and contacting, the metal layer and the silver contact pad; and
wherein the glass frit sublayer of the conductive multilayer stack contacts at least a portion of silicon substrate, contacts at least one passivation layer, or contacts a combination thereof; and
wherein the metal layer of the conductive multilayer stack is a continuous layer that connects the at least two conductive multilayer stacks of the at least one first and/or second interconnection pad.
199. The asymmetric solar cell of clause 198, wherein the metal layer of the at least two conductive multilayer stacks of the first conductive multilayer line is a continuous layer that is connected to the at least two conductive multilayer stacks of the third conductive multilayer line.
200. The asymmetric solar cell of clause 198 or 199, wherein the metal layer of the at least two conductive multilayer stacks of the second conductive multilayer line is a continuous layer that is connected to the at least two conductive multilayer stacks of the fourth conductive multilayer line.
201. The asymmetric solar cell clause of any one of clauses 195 to 197, further comprising at least one first solder pad on a first portion of the front and/or rear surface of the silicon substrate and at least one second solder pad on a second portion of the front and/or rear surface of the silicon substrate, wherein the at least one first fine grid line contacts the at least one first solder pad, and wherein the at least one second fine grid line contacts the at least one second solder pad.
202. The asymmetric solar cell of any one of clauses 195 to 201, wherein the rear surface of the doped silicon substrate further comprises at least one doped layer, wherein the at least one doped layer comprises at least one doped region and at least one oppositely-doped region.
203. The asymmetric solar cell of clause 202, wherein the at least one doped region comprises a p-type dopant and the at least one oppositely-doped region comprises an n-type dopant.
204. The asymmetric solar cell of clause 202 or 203, wherein the glass frit sublayer penetrates through the at least one passivation layer and contacts the at least one doped region.
205. The asymmetric solar cell of clause 202 or 203, wherein the glass frit sublayer penetrates through the at least one passivation layer and contacts the at least one oppositely-doped region and the glass frit sublayer.
206. The asymmetric solar cell of any one of clauses 202 to 205, wherein the at least one doped region has a thickness ranging from 30 nm to 200 nm.
207. The asymmetric solar cell of any one of clauses 203 to 207, wherein the at least one oppositely-doped region has a thickness ranging from 30 nm to 200 nm.
208. The asymmetric solar cell of any one of clauses 195 to 201, wherein the at least one passivation layer comprises:
a tunnel oxide layer;
a doped layer on top of at least a first portion of the tunnel oxide layer and an oppositely doped layer on top of at least a second portion of the tunnel oxide layer, wherein the doped layer comprises n-type doped polysilicon (poly-Si), and wherein the oppositely doped layer comprises p-type doped polysilicon (poly-Si); and
at least one SiOxNy passivation layer on top of at least a portion of the doped layer and on at least a portion of the oppositely-doped layer.
209. The asymmetric solar cell of clause 208, wherein the glass frit sublayer of the at least one first fine and/or second fine grid line penetrates through the at least one SiOxNy passivation layer and contacts the doped layer comprising n-type doped poly-Si.
210. The asymmetric solar cell of clause 208, wherein the glass frit sublayer of the at least one first fine and/or second fine grid line penetrates through the at least one SiOxNy passivation layer and contacts the oppositely doped layer comprising p-type doped poly-Si.
211. The asymmetric solar cell of any one of clauses 208 to 210, wherein the tunnel oxide layer comprises SiOₓ.
212. The asymmetric solar cell of any one of clauses 208 to 211, wherein the at least one SiOxNy passivation layer comprises SiOₓ, SiN_{y}, SiON, or combinations thereof.
213. The asymmetric solar cell of any one of clauses 208 to 212, wherein the tunnel oxide layer has a thickness that ranges from 1 nm to 5 nm.
214. The asymmetric solar cell of any one of clauses 208 to 213, wherein the doped layer and/or the oppositely doped layer has a thickness that ranges from 50 nm to 200 nm.
215. The asymmetric solar cell of any one of clauses 208 to 214, wherein the at least one SiOxNy passivation layer has a thickness that ranges from 50 nm to 100 nm.
216. The asymmetric solar cell of any one of clauses 195 to 207, wherein the at least one passivation layer comprises SiOₓ, AlOₓ, or SiOxNy.
217. The asymmetric solar cell of clause 216, wherein the at least one passivation layer comprises a first passivation layer comprising SiOₓ and at least one second passivation layer comprising SiOxNy, wherein the at least one second passivation layer is on at least a portion of the first passivation layer.
218. The asymmetric solar cell of clause 216, wherein the at least one passivation layer comprises a first passivation layer comprising AlOₓ and at least one second passivation layer comprising SiOxNy, wherein the at least one second passivation layer is on at least a portion of the first passivation layer.
219. The asymmetric solar cell of clause 217 or 218, wherein the at least one second passivation layer comprising SiOxNy comprises SiOₓ, SiN_{y}, SiON, or combinations thereof.
220. The asymmetric solar cell of any one of clauses 217 to 219, wherein the first passivation layer has a thickness ranging from 1 nm to 5 nm.
221. The asymmetric solar cell of any one of clauses 217 to 220, wherein the at least one second passivation layer has a thickness ranging from 50 nm to 100 nm.
222. The asymmetric solar cell of any one of clauses 217 or 219 to 221, further comprising an intermediate passivation layer between the first passivation layer and the second passivation layer, and wherein the intermediate passivation layer comprises AlOₓ.
223. The asymmetric solar cell of clause 222, wherein the intermediate passivation layer has a thickness ranging from 1 nm to 5 nm.
224. The asymmetric solar cell of any one of clauses 216 to 223, wherein the glass frit sublayer penetrates through the at least one passivation layer.
225. The asymmetric solar cell of any one of clauses 195 to 224, wherein the silicon substrate is p-type doped.
226. The asymmetric solar cell of any one of clauses 195 to 224 wherein the silicon substrate is n-type doped.
227. The asymmetric solar cell of any one of clauses 195 to 226, wherein a silver contact pad of a first conductive multilayer stack of the at least two conductive multilayer stacks of the conductive multilayer line is separated from a silver contact pad of a second conductive multilayer stack of the at least two conductive multilayer stacks by a distance from 200 μm to 2 mm, 300 μm to 2 mm, 300 μm to 1 mm, 400 μm to 1 mm, or 400 μm to 900 μm.
228. The asymmetric solar cell of any one of clauses 195 to 227, wherein the metal layer of the at least one first and/or second fine grid line and the at least one first and/or second interconnection pad, when present, has a thickness ranging from 4 μm to 100 μm, from 4 μm to 50 μm, from 4 μm to 25 μm, from 4 μm to 10 μm, or from 4 μm to 6 μm.
229. The asymmetric solar cell of any one of clauses 195 to 228, wherein the metal layer of the at least one first and/or second fine grid line and the at least one first and/or second interconnection pad, when present, has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm.
230. The asymmetric solar cell of any one of clauses 195 to 229, wherein the substrate has a thickness ranging from 120 μm to 180 μm.
231. The asymmetric solar cell of any one of clauses 195 to 230, wherein the metal layer of the at least one first and/or second fine grid line and the at least one first and/or second interconnection pad, when present, comprises, consists of, or consists essentially of Cu.
232. The asymmetric solar cell of any one of clauses 195 to 230, wherein the metal layer of the at least one first and/or second fine grid line and the at least one first and/or second interconnection pad, when present, comprises, consists of, or consists essentially of coated aluminum.
233. The asymmetric solar cell of clause 232, wherein the coated aluminum comprises an aluminum layer and, on at least one side of the aluminum layer, and at least one corrosion resistant joining layer contacting the solderable layer.
234. The asymmetric solar cell of clause 233, wherein the coated aluminum does not comprise a native oxide between the aluminum layer and the at least one corrosion resistant joining layer.
235. The asymmetric solar cell of clause 233 or 234, wherein the at least one corrosion resistant joining layer is:
an alloy of aluminum and a metal, wherein the metal is:
selected from copper (Cu), magnesium (Mg), manganese (Mn), silicon (Si), tin (Sn), zinc (Zn), and a combination thereof; or
selected from chromium (Cr), cobalt (Co), molybdenum (Mo), nickel (Ni), tantalum (Ta), titanium (Ti), tungsten (W), an alloy thereof, a nitride thereof, a boride thereof, a composite thereof, and a combination thereof, or
selected from Ti, an alloy thereof, a nitride thereof, a boride thereof, a composite thereof, and a combination thereof.
236. The asymmetric solar cell of any one of clauses 233 to 235, further comprising a second metal layer between, and contacting, the at least one corrosion resistant joining layer and the solderable layer.
237. The asymmetric solar cell of clause 236, wherein the second metal layer comprises copper.
238. The asymmetric solar cell of any one of clauses 233 to 237, wherein the at least one corrosion resistant joining layer has a thickness, width, or both, ranging from 50 nm to 200 nm, or from 20 nm to 100 nm.
239. The asymmetric solar cell of any one of clauses 195 to 238, wherein the metal layer of the at least one first and/or second fine grid line and the at least one first and/or second interconnection pad, when present, has a surface roughness Ra ranging from 100 nm to 500 nm; from 200 nm to 500 nm; or from 300 nm to 500 nm.
240. The asymmetric solar cell of any one of clauses 195 to 239, wherein the metal layer of the at least one first and/or second fine grid line and the at least one first and/or second interconnection pad, when present, is laser cut.
241. The asymmetric solar cell of clause 240, wherein the metal layer has a burr roughness ranging from 200 nm to 20 μm, from 1 μm from 10 μm, or from 1 μm to 5 μm.
242. The asymmetric solar cell of clause 240 or 241, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.
243. The asymmetric solar cell of any one of clauses 240 to 242, wherein the metal layer has a burr mean height ranging from 200 nm to 20 μm, from 1 μm to 10 μm, or from 1 μm to 5 μm.
244. The asymmetric solar cell of any one of clauses 240 to 243, wherein the metal layer has a dross mean height ranging from 200 nm to 20 μm, from 1 μm to 10 μm, or from 1 μm to 5 μm.
245. The asymmetric solar cell of any one of clauses 240 to 244, wherein the metal layer has a dross roughness ranging from 200 nm to 20 μm, from 1 μm to 10 μm, or from 1 μm to 5 μm
246. The asymmetric solar cell of any one of clauses 195 to 245, wherein the solderable layer of the at least one first and/or second fine grid line and the at least one first and/or second interconnection pad, when present, has a thickness of less than 40 μm, less than 30 μm, less than 25 μm, less than 20 μm, or less than 10 μm.
247. The asymmetric solar cell of any one of clauses 195 to 246, wherein the silver contact pad of the at least one first and/or second fine grid line and the at least one first and/or second interconnection pad, when present, has a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.
248. The asymmetric solar cell of any one of clauses 195 to 247, wherein the glass frit sublayer of the at least one first and/or second fine grid line and the at least one first and/or second interconnection pad, when present, has a thickness from 1 nm to 3 μm, from 1 nm to 1 μm, or from 1 nm to 200 nm.
249. The asymmetric solar cell of any one of clauses 195 to 248, wherein the solderable layer of the at least one first and/or second fine grid line and the at least one first and/or second interconnection pad, when present, is a solder layer comprising a solder material.
250. The asymmetric solar cell of clause 249, wherein the solder material is a Silver-Aluminum-Copper (SAC) solder material.
251. The asymmetric solar cell of any one of clauses 195 to 250, wherein the rear surface of the silicon substrate has a total surface area, wherein the silver contact pads of the at least one first and/or second fine grid line and the at least one first and/or second interconnection pad, when present, have a combined surface area, and wherein the combined surface area ranges from 0.5% to 7%, from 0.5% to 6%, from 0.5% to 5%, from 0.5% to 4%, from 0.5% to 3%, from 0.5% to 2%, from 0.5% to 1%, or from 0.5% to 0.75% of the total surface area.
252. A solar cell module comprising:
a first solar cell and a second solar cell;
an interconnect that connects the first solar cell and the second solar cell
wherein the first solar cell and the second solar cell comprise:
a doped silicon substrate having a front surface and a rear surface, wherein the front surface is a light-facing surface, and the rear surface is opposite of the light-facing surface;
at least one passivation layer directly on at least a portion of the front and/or rear surface of the doped silicon substrate; and
at least one fine grid line on a portion of the front and/or rear surface of the doped silicon substrate;
wherein the at least one fine grid line is a conductive multilayer line comprising at least two conductive multilayer stacks, the conductive multilayer stack of the at least two conductive multilayer stacks comprising:
a metal layer comprising copper (Cu) or coated aluminum;
a silver contact pad comprising a silver sublayer and a glass frit sublayer, wherein the silver sublayer is on the glass frit sublayer; and
a solderable layer between, and contacting, the metal layer and the silver contact pad; and
wherein the glass frit sublayer of the conductive multilayer stack contacts at least a portion of silicon substrate, contacts at least one passivation layer, or contacts a combination thereof; and
wherein the metal layer of the conductive multilayer stack is a continuous layer that connects the at least two conductive multilayer stacks of the conductive multilayer line.
253. The solar cell module of clause 252, wherein the first solar cell and the second solar cell further comprise:
at least one solder pad on a portion of the front and/or rear surface of the doped silicon substrate; and
   at least one busbar on a portion of the front and/or rear surface of the doped silicon substrate,
   wherein the at least one busbar contacts the at least one solder pad,
wherein the interconnect comprises a first tabbing wire that contacts the at least one solder pad on the first solar cell and the at least one solder pad on the second solar cell, and a bus ribbon that contacts the first tabbing wire.
254. The solar cell module of clause 253, wherein the at least one fine grid line on the first solar cell contacts the at least one busbar on the first solar cell, and the at least one fine grid line on the second solar cell contacts the at least one busbar on the second solar cell.
255. The solar cell module of clause 253 or 254, wherein the respective at least one busbar on the first solar cell and the second solar cell is a conductive multilayer line comprising at least two conductive multilayer stacks, a conductive multilayer stack of the at least two conductive multilayer stacks comprising:
a metal layer comprising copper (Cu) or coated aluminum;
a silver contact pad comprising a silver sublayer and a glass frit sublayer, wherein the silver sublayer is on the glass frit sublayer; and
a solderable layer between, and contacting, the metal layer and the silver contact pad;
wherein the glass frit sublayer of the conductive multilayer stack contacts at least a portion of silicon substrate, contacts at least one passivation layer, or contacts a combination thereof, and
wherein the metal layer of the conductive multilayer stack is a continuous layer that connects the at least two conductive multilayer stacks of the at least one busbar.
256. The solar cell module of 252, wherein the interconnect comprises a first interconnection pad on the first solar cell and a second interconnection pad on the second solar cell, wherein the first interconnection pad contacts the second interconnection pad to form a contact.
257. The solar cell module of clause 256, wherein the first solar cell and the second solar cell further comprise at least one busbar on a portion of the front and/or rear surface of the doped silicon substrate, wherein the respective at least one fine grid line contacts the respective at least one busbar.
258. The solar cell module of clause 257, wherein the respective at least one busbar on the first solar cell and the second solar cell comprises at least two conductive multilayer stacks, a conductive multilayer stack of the at least two conductive multilayer stacks comprising:
a metal layer comprising copper (Cu) or coated aluminum;
a silver contact pad comprising a silver sublayer and a glass frit sublayer, wherein the silver sublayer is on the glass frit sublayer; and
a solderable layer between, and contacting, the metal layer and the silver contact pad; and
wherein the glass frit sublayer of the conductive multilayer stack contacts at least a portion of silicon substrate, contacts at least one passivation layer, or contacts a combination thereof; and
wherein the metal layer of the conductive multilayer stack is a continuous layer that connects the at least two conductive multilayer stacks of the at least one busbar.
259. The solar cell module of any one of clauses 256 to 258, wherein the first interconnection pad contacts the at least two conductive multilayer stacks of the at least one fine grid line and the at least two conductive multilayer stacks of the at least one busbar of the respective first solar cell and second fine grid line on the first solar cell, and wherein the second interconnection pad contacts the at least two conductive multilayer stacks of the at least one fine grid line and the at least two conductive multilayer stacks of the at least one busbar on the second solar cell.
260. The solar cell module of any one of clauses 256 to 259, wherein the first interconnection pad, the second interconnection pad, or both, are a metal comprising copper (Cu) or coated aluminum.
261. The solar cell module of any one of clauses 256 to 260, wherein the contact of the first interconnection pad and the second interconnection pad is a weld.
262. The solar cell module of any one of clauses 259 to 261, wherein the first interconnection pad contacts the metal layer of the at least two conductive multilayer stacks of the at least one fine grid line and/or the metal layer of the at least two conductive multilayer stacks of the at least one busbar on the first solar cell.
263. The solar cell module of any one of clauses 259 to 262, wherein the second interconnection pad contacts the metal layer of the at least two conductive multilayer stacks of the at least one fine grid line and/or the metal layer of the at least two conductive multilayer stacks of the at least one busbar on the second solar cell.
264. The solar cell module of any one of clauses 257 to 263, wherein the first interconnection pad contacts the at least one busbar on the first solar cell.
265. The solar cell module of any one of clauses 257 to 264, wherein the second interconnection pad contacts the at least one busbar on the second solar cell.
266. The solar cell module of any one of clauses 257 to 265, wherein the first interconnection pad and/or the second interconnection pad is a conductive multilayer line comprising at least two conductive multilayer stacks, a conductive multilayer stack of the at least two conductive multilayer stacks comprising:
a metal layer comprising copper (Cu) or coated aluminum;
a silver contact pad comprising a silver sublayer and a glass frit sublayer, wherein the silver sublayer is on the glass frit sublayer;
a solderable layer between, and contacting, the metal layer and the silver contact pad;
wherein the glass frit sublayer of the conductive multilayer stack contacts at least a portion of silicon substrate, contacts at least one passivation layer, or contacts a combination thereof; and
wherein the metal layer of the conductive multilayer stack is a continuous layer that connects the at least two conductive multilayer stacks of the conductive multilayer line.
267. The solar cell module of clause 252, wherein the interconnect comprises at least one first tabbing wire that contacts the at least one fine grid line on the first solar cell or the at least one fine grid line on the second solar cell, wherein the at least one first tabbing wire comprises a metal core and a solder coating, and wherein the interconnect further comprises a bus ribbon contacting the at least one first tabbing wire.
268. The solar cell module of clause 267, wherein the at least one first tabbing wire contacts the at least one fine grid line on the first solar cell and the at least one fine grid line on the second solar cell.
269. The solar cell module of clause 268, wherein the at least one first tabbing wire is soldered to the respective metal layer of the respective at least one fine grid line of the first solar cell and the second solar cell.
270. The solar cell module of clause 269, wherein the metal layer of the at least two conductive multilayer stacks of the at least one fine grid line comprises copper (Cu) with respect to both the first solar cell and the second solar cell.
271. The solar cell module of any one of clauses 267 to 270, wherein the metal core comprises copper, aluminum, carbon, tin, iron, an alloy thereof, a composite thereof, or a combination thereof.
272. The solar cell module of any one of clauses 267 to 271, wherein the metal core comprises copper.
273. The solar cell module of any one of clauses 267 to 272, wherein the at least one first tabbing wire has a diameter from 80 μm to 1000 μm, from 100 μm to 300 μm, or from 120 μm to 200 μm.
274. The solar cell module of any one of clauses 267 to 273, wherein the solder coating has a thickness from 0.5 μm to 100 μm or from 10 μm to 50 μm.
275. The solar cell module of any one of clauses 267 to 274, wherein the solder coating comprises tin, lead, silver, bismuth, copper, zinc, antimony, manganese, indium, an alloy thereof, a composite thereof, or a combination thereof.
276. The solar cell module of any one of clauses 267 to 275, wherein the first solar cell and the second solar cell further comprise at least one solder pad on the respective front surface and/or rear surface of the first solar cell and the second solar cell.
277. The solar cell module of clause 276, wherein the first solar cell and the second solar cell further comprise at least one second tabbing wire contacting the respective at least one solder pad on the front surface and/or rear surface of the first solar cell and the second solar cell.
278. The solar cell module of any one of clauses 268 to 277, wherein the at least one first tabbing wire contacts the respective at least one fine grid line on the rear surface of the first solar cell and the second solar cell.
279. The solar cell module of any one of clauses 252 to 278, wherein the at least one passivation layer comprises a tunnel oxide layer, a doped layer on top of at least a portion of the tunnel oxide layer, wherein the doped layer comprises an n-type doped polysilicon (poly-Si), and at least one SiOxNy passivation layer on top of at least a portion of the doped layer.
280. The solar cell module of clause 279, wherein the glass frit sublayer penetrates through the at least one SiOxNy passivation layer and contacts the doped layer comprising the n-type doped poly-Si.
281. The solar cell module of clause 279 or 280, wherein the tunnel oxide layer comprises SiOₓ.
282. The solar cell module of any one of clauses 279 to 281, wherein the at least one SiOxNy passivation layer comprises SiOₓ, SiN_{y}, SiON, or combinations thereof.
283. The solar cell module of any one of clauses 279 to 282, wherein the tunnel oxide layer has a thickness that ranges from 1 nm to 5 nm.
284. The solar cell module of any one of clauses 279 to 283, wherein the doped layer has a thickness that ranges from 50 nm to 200 nm.
285. The solar cell module of any one of clauses 279 to 284, wherein the at least one SiOxNy passivation layer has a thickness that ranges from 50 nm to 100 nm.
286. The solar cell module of any one of clauses 252 to 278, wherein the at least one passivation layer comprises SiOₓ, AlOₓ, or SiOxNy.
287. The solar cell module of clause 286, wherein the at least one passivation layer comprises a first passivation layer comprising SiOₓ and at least one second passivation layer comprising SiOxNy, wherein the at least one second passivation layer is on at least a portion of the first passivation layer.
288. The solar cell module of clause 287, wherein the at least one passivation layer comprises a first passivation layer comprising AlOₓ and at least one second passivation layer comprising SiOxNy, wherein the at least one second passivation layer is on at least a portion of the first passivation layer.
289. The solar cell module of clause 287 or 288, wherein the at least one second passivation layer comprising SiOxNy comprises SiOₓ, SiN_{y}, SiON, or any combination thereof.
290. The solar cell module of any one of clauses 287 to 289, wherein the first passivation layer has a thickness ranging from 1 nm to 5 nm.
291. The solar cell module of any one of clauses 287 to 290, wherein the at least one second passivation layer has a thickness ranging from 50 nm to 100 nm.
292. The solar cell module of any one of clauses 287 or 289 to 291, further comprising an intermediate passivation layer between the first passivation layer and the at least one second passivation layer, and wherein the intermediate passivation layer comprises AlOₓ.
293. The solar cell module of clause 292, wherein the intermediate passivation layer has a thickness ranging from 1 nm to 5 nm.
294. The solar cell module of any one of clauses 286 to 293, wherein the glass frit sublayer penetrates through the at least one passivation layer.
295. The solar cell module of any one of clauses 252 to 278, wherein the front and/or rear surface of the doped silicon substrate further comprises a doped layer, and wherein the doped layer has a different dopant, different dopant type, and/or different dopant concentration from the doped silicon substrate.
296. The solar cell module of clause 295, wherein the at least one passivation layer comprises SiOₓ, AlOₓ, or SiOxNy.
297. The solar cell module of clause 296, wherein the at least one passivation layer comprises a first passivation layer comprising SiOₓ and at least one second passivation layer comprising SiOxNy, wherein the at least one second passivation layer is on at least a portion of the first passivation layer.
298. The solar cell module of clause 297, wherein the first passivation layer has a thickness ranging from 1 nm to 5 nm.
299. The solar cell module of clauses 297 or 298, wherein the at least one second passivation layer has a thickness ranging from 50 to 100 nm.
300. The solar cell module of any one of clauses 297 to 299, further comprising an intermediate passivation layer between the first passivation layer and the at least one second passivation layer, and wherein the intermediate passivation layer comprises AlOₓ.
301. The solar cell module of clause 300, wherein the intermediate passivation layer has a thickness from 1 nm to 5 nm.
302. The solar cell module of any one of clauses 295 to 301, wherein the glass frit sublayer penetrates through the at least one passivation layer and contacts the doped layer.
303. The solar cell module of any one of clauses 295 to 302, wherein a thickness of the doped layer is from 30 nm to 200 nm.
304. The solar cell module of any one of clauses 295 to 303, wherein the doped layer comprises an n-type dopant.
305. The solar cell module of any one of clauses 295 to 303, wherein the doped layer comprises a p-type dopant.
306. The solar cell module of any one of clauses 252 to 305, wherein the at least one passivation layer is on the front surface of the doped silicon substrate.
307. The solar cell module of any one of clauses 252 to 305, wherein the at least one passivation layer is on the rear surface of the doped silicon substrate.
308. The solar cell module of any one of clauses 252 to 307, wherein the doped silicon substrate is n-type doped.
309. The solar cell module of any one of clauses 252 to 307, wherein the doped silicon substrate is p-type doped.
310. The solar cell module of any one of clauses 252 to 309, wherein a silver contact pad of a first conductive multilayer stack of the at least two conductive multilayer stacks of the at least one fine grid line is separated from a silver contact pad of a second conductive multilayer stack of the at least two conductive multilayer stacks by a distance from 200 μm to 2 mm, 300 μm to 2 mm, 300 μm to 1 mm, 400 μm to 1 mm, or 400 μm to 900 μm.
311. The solar cell module of any one of clauses 252 to 310, wherein the metal layer of the at least one fine grid line and the at least one busbar, when present, and the first and/or second interconnection pad, when present, has a thickness ranging from 4 μm to 100 μm, from 4 μm to 50 μm, from 4 μm to 25 μm, from 4 μm to 10 μm, or from 4 μm to 6 μm.
312. The solar cell module of any one of clauses 252 to 311, wherein the metal layer of the at least one fine grid line and the at least one busbar, when present, and the first and/or second interconnection pad, when present, has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm.
313. The solar cell module of any one of clauses 252 to 312, wherein the substrate has a thickness ranging from 120 μm to 180 μm.
314. The solar cell module of any one of clauses 252 to 313, wherein the metal layer of the at least one fine grid line and the at least one busbar, when present, and the first and/or second interconnection pad, when present, comprises, consists of, or consists essentially of Cu.
315. The solar cell module of any one of clauses 252 to 313, wherein the metal layer of the at least one fine grid line and the at least one busbar, when present, and the first and/or second interconnection pad, when present, comprises, consists of, or consists essentially of coated aluminum.
316. The solar cell module of clause 315, wherein the coated aluminum comprises an aluminum layer and, on at least one side of the aluminum layer, and at least one corrosion resistant joining layer contacting the solderable layer.
317. The solar cell module of clause 316, wherein the coated aluminum does not comprise a native oxide between the aluminum layer and the at least one corrosion resistant joining layer.
318. The solar cell module of clause 316 or 317, wherein the at least one corrosion resistant joining layer is:
an alloy of aluminum and a metal, wherein the metal is
selected from copper (Cu), magnesium (Mg), manganese (Mn), silicon (Si), tin (Sn), zinc (Zn), and a combination thereof; or
selected from chromium (Cr), cobalt (Co), molybdenum (Mo), nickel (Ni), tantalum (Ta), titanium (Ti), tungsten (W), an alloy thereof, a nitride thereof, a boride thereof, a composite thereof, and a combination thereof; or
selected from Ti, an alloy thereof, a nitride thereof, a boride thereof, a composite thereof, and a combination thereof.
319. The solar cell module of any one of clauses 316 to 318, further comprising a second metal layer between, and contacting, the at least one corrosion resistant joining layer and the solderable layer.
320. The solar cell module of clause 318, wherein the second metal layer comprises copper.
321. The solar cell module of any one of clauses 317 to 320, wherein the at least one corrosion resistant joining layer has a thickness, width, or both, ranging from 50 nm to 200 nm, or from 20 nm to 100 nm.
322. The solar cell module of any one of clauses 252 to 321, wherein the metal layer of the at least one fine grid line and the at least one busbar, when present, and the first and/or second interconnection pad, when present, has a surface roughness Ra ranging from 100 nm to 500 nm; from 200 nm to 500 nm; or from 300 nm to 500 nm.
323. The solar cell module of any one of clauses 252 to 322, wherein the metal layer of the at least one fine grid line and the at least one busbar, when present, and the first and/or second interconnection pad, when present, is laser cut.
324. The solar cell module of clause 323, wherein the metal layer has a burr roughness ranging from 200 nm to 20 μm, from 1 μm from 10 μm, or from 1 μm to 5 μm.
325. The solar cell module of clause 323 or 324, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.
326. The solar cell module of clause any one of clauses 322 to 325, wherein the metal layer has a burr mean height ranging from 200 nm to 20 μm, from 1 μm to 10 μm, or from 1 μm to 5 μm.
327. The conductive multilayer stack of any one of clauses 323 to 326, wherein the metal layer has a dross mean height ranging from 200 nm to 20 μm, from 1 μm to 10 μm, or from 1 μm to 5 μm.
328. The conductive multilayer stack of any one of clauses 323 to 327, wherein the metal layer has a dross roughness ranging from 200 nm to 20 μm, from 1 μm to 10 μm, or from 1 μm to 5 μm
329. The solar cell module of any one of clauses 252 to 328, wherein the solderable layer of the at least one fine grid line and the at least one busbar, when present, and the first and/or second interconnection pad, when present, has a thickness of less than 40 μm, less than 30 μm, less than 25 μm, less than 20 μm, or less than 10 μm.
330. The solar cell module of any one of clauses 252 to 329, wherein the silver contact pad of the at least one fine grid line and the at least one busbar, when present, and the first and/or second interconnection pad, when present, has a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.
331. The solar cell module of any one of clauses 252 to 330, wherein the glass frit sublayer of the at least one fine gride line and the at least one busbar, when present, and the first and/or second interconnection pad, when present, has a thickness from 1 nm to 3 μm, from 1 nm to 1 μm, or from 1 nm to 200 nm.
332. The solar cell module of any one of clauses 252 to 331, wherein the solderable layer of the at least one fine grid line and the at least one busbar, when present, and the first and/or second interconnection pad, when present, is a solder layer comprising a solder material.
333. The solar cell module of clause 332, wherein the solder material is a Silver-Aluminum-Copper (SAC) solder material.
334. A solar cell module comprising:
a first solar cell and a second solar cell;
an interconnect that connects the first solar cell and the second solar cell;
wherein the first solar and the second solar cell comprise:
a silicon substrate having a front, light-facing surface and a rear surface, wherein the rear surface is opposite of the light-facing surface;
at least one passivation layer directly on at least a portion of the rear surface of the silicon substrate;
at least one first fine grid line on at least a portion of the rear surface of the silicon substrate; and
at least one second fine grid line on at least a portion of the rear surface of the silicon substrate;
wherein at least one of the at least one first fine grid line or the at least one second fine grid line is a first conductive multilayer line comprising at least two conductive multilayer stacks; and
wherein a conductive multilayer stack of the at least two conductive multilayer stacks comprises:
a metal layer comprising copper (Cu) or coated aluminum;
a silver contact pad comprising a silver sublayer and a glass frit sublayer, wherein the silver sublayer is on the glass frit sublayer; and
a solderable layer between, and contacting, the metal layer and the silver contact pad;
wherein the glass frit sublayer of the conductive multilayer stack is on the silicon substrate, is on the at least one passivation layer, or is on a combination thereof; and
wherein the metal layer of the conductive multilayer stack is a continuous layer that connects the at least two conductive multilayer stacks.
335. The solar cell module of clause 334, wherein either the at least one first fine grid line or the at least one second fine grid line is the first conductive multilayer line and the other comprises sintered aluminum.
336. The solar cell module of clause 334, wherein the at least one first fine grid line is a first conductive multilayer line comprising at least two conductive multilayer stacks, and wherein the at least one second fine grid line is a second conductive multilayer line comprising at least two conductive multilayer stacks.
337. The solar cell module of any one of clauses 334 to 336, wherein the interconnect comprises:
at least one first interconnection pad on the first solar cell contacting the at least one first fine grid line;
at least one second interconnection pad on the second solar cell contacting the at least one second fine grid line;
wherein the at least one first interconnection pad is connected to the at least one second interconnection pad.
338. The solar cell module of clause 337, wherein the at least one first interconnection pad is a third conductive multilayer line comprising at least two conductive multilayer stacks, and wherein the at least one second interconnection pad is a fourth conductive multilayer line comprising at least two conductive multilayer stacks, a conductive multilayer stack of the at least two conductive multilayer stacks in the third and/or fourth conductive multilayer line comprising:
a metal layer comprising copper (Cu) or coated aluminum;
a silver contact pad comprising a silver sublayer and a glass frit sublayer, wherein the silver sublayer is on the glass frit sublayer; and
a solderable layer between, and contacting, the metal layer and the silver contact pad; and
wherein the glass frit sublayer of the conductive multilayer stack contacts at least a portion of silicon substrate, contacts at least one passivation layer, or contacts a combination thereof; and
wherein the metal layer of the conductive multilayer stack is a continuous layer that connects the at least two conductive multilayer stacks of the at least one first and/or second interconnection pad.
339. The solar cell module of clause 338, wherein the metal layer of the at least two conductive multilayer stacks of the first conductive multilayer line is a continuous layer that is connected to the least two conductive multilayer stacks of the third conductive multilayer line.
340. The solar cell module of clause 338 or 339, wherein the metal layer of the at least two conductive multilayer stacks of the second conductive multilayer is a continuous layer that is connected to the at least two conductive multilayer stacks of the fourth conductive multilayer line.
341. The solar cell module of any one of clauses 338 to 340, wherein the metal layer of the at least one first interconnection pad on the first solar cell is connected to the metal layer of the at least one second interconnection pad on the second solar cell.
342. The solar cell module of clause 341, wherein the metal layer of the at least one first interconnection pad on the first solar cell is welded to the metal layer of the at least one second interconnection pad on the second solar cell.
343. The solar cell module of any one of clauses 334 to 336, further comprising:
at least one first solder pad on a portion of the front and/or rear surface of the silicon substrate on the first solar cell and at least one second solder pad on a portion of the front and/or rear surface of the silicon substrate on the second solar cell,
wherein the at least one first fine grid line on the first solar cell contacts the at least one first solder pad; and
wherein at least one second fine grid line on the second solar cell contacts the at least one second solder pad;
wherein the interconnect comprises a tabbing wire that contacts the at least one first solder pad on the first solar cell and the at least one second solder pad on the second solar cell, and
   wherein a bus ribbon contacts the tabbing wire.
344. The solar cell module of any one of clauses 334 to 343, wherein the rear surface of the doped silicon substrate further comprises at least one doped layer, wherein the at least one doped layer has at least one doped region and at least one oppositely-doped region.
345. The solar cell module of clause 344, wherein the at least one doped region comprises a p-type dopant and the at least one oppositely-doped region comprises an n-type dopant.
346. The solar cell module of clause 344 or 345, wherein the glass frit sublayer penetrates through the at least one passivation layer and contacts the at least one doped region.
347. The solar cell module of clause 344 or 345, wherein the glass frit sublayer penetrates through the at least one passivation layer and contacts the at least one oppositely-doped region.
348. The solar cell module of clause any one of clauses 344 to 347, wherein the at least one doped region has a thickness ranging from 30 nm to 200 nm.
349. The solar cell module of any one of clauses 344 to 348, wherein the at least one oppositely-doped region has a thickness ranging from 30 nm to 200 nm.
350. The solar cell module of any one of clauses 333 to 342, wherein the at least one passivation layer comprises
a tunnel oxide layer;
a doped layer on top of at least a first portion of the tunnel oxide layer and an oppositely doped layer on top of at least a second portion of the tunnel oxide layer, wherein the doped layer comprises n-type doped polysilicon (poly-Si), and wherein the oppositely doped layer comprises p-type doped polysilicon (poly-Si); and
at least one SiOxNy passivation layer on top of at least a portion of the doped layer and on at least a portion of the oppositely-doped layer.
351. The solar cell module of clause 350, wherein the glass frit sublayer of the at least one first fine grid line or the at least one second fine grid line penetrates through the at least one SiOxNy passivation layer and contacts the doped layer comprising n-type doped poly-Si.
352. The solar cell module of clause 350, wherein the glass frit sublayer of the at least one first fine grid line or the at least one second fine grid line penetrates through the at least one SiOxNy passivation layer and contacts the oppositely-doped layer comprising p-type doped poly-Si.
353. The solar cell module of any one of clauses 350 to 352, wherein the tunnel oxide layer comprises SiOₓ.
354. The solar cell module of any one of clauses 350 to 353, wherein the at least one SiOxNy passivation layer comprises SiOₓ, SiN_{y}, SiON, or combinations thereof.
355. The solar cell module of any one of clauses 350 to 354, wherein the tunnel oxide layer has a thickness that ranges from 1 nm to 5 nm.
356. The solar cell module of any one of clauses 350 to 355, wherein the doped layer and/or the oppositely-doped layer has a thickness that ranges from 50 nm to 200 nm.
357. The solar cell module of any one of clauses 350 to 356, wherein the at least one SiOxNy passivation layer has a thickness that ranges from 50 nm to 100 nm.
358. The solar cell module of any one of clauses 334 to 349, wherein the at least one passivation layer comprises SiOₓ, AlOₓ, or SiOxNy.
359. The solar cell module of clause 358, wherein the at least one passivation layer comprises a first passivation layer comprising SiOₓ and at least one second passivation layer comprising SiOxNy, wherein the at least one second passivation layer is on at least a portion of the first passivation layer.
360. The solar cell module of clause 358, wherein the at least one passivation layer comprises a first passivation layer comprising AlOₓ and at least one second passivation layer comprising SiOxNy, wherein the at least one second passivation layer is on at least a portion of the first passivation layer.
361. The solar cell module of clause 359 or 360, wherein the at least one second passivation layer comprising SiOxNy comprises SiOₓ, SiN_{y}, SiON, or any combination thereof.
362. The solar cell module of any one of clauses 359 to 361, wherein the first passivation layer has a thickness ranging from 1 nm to 5 nm.
363. The solar cell module of any one of clauses 359 to 362, wherein the at least one second passivation layer has a thickness ranging from 50 nm to 100 nm.
364. The solar cell module of any one of clauses 359 or 361 to 363, further comprising an intermediate passivation layer between the first passivation layer and the second passivation layer, and wherein the intermediate passivation layer comprises AlOₓ.
365. The solar cell module of clause 364, wherein the intermediate passivation layer has a thickness ranging from 1 nm to 5 nm.
366. The solar cell module of any one of clauses 358 to 365, wherein the glass frit sublayer penetrates through the at least one passivation layer.
367. The solar cell module of any one of clauses 334 to 366, wherein the silicon substrate is p-type doped.
368. The solar cell module of any one of clauses 334 to 366, wherein the silicon substrate is n-type doped.
369. The solar cell module of any one of clauses 334 to 368, wherein a silver contact pad of a first conductive multilayer stack of the at least two conductive multilayer stacks of the first conductive multilayer line is separated from a silver contact pad of a second conductive multilayer stack of the at least two conductive multilayer stacks by distance from 200 μm to 2 mm, 300 μm to 2 mm, 300 μm to 1 mm, 400 μm to 1 mm, or 400 μm to 900 μm.
370. The solar cell module of any one of clauses 334 to 369, wherein the metal layer of the first and/or second fine grid line and the first and/or second interconnection pad, when present, has a thickness ranging from 4 μm to 100 μm, from 4 μm to 50 μm, from 4 μm to 25 μm, from 4 μm to 10 μm, or from 4 μm to 6 μm.
371. The solar cell module of any one of clauses 334 to 370, wherein the metal layer of the first and/or second fine grid line and the first and/or second interconnection pad, when present, has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm.
372. The solar cell module of any one of clauses 334 to 371, wherein the substrate has a thickness ranging from 120 μm to 180 μm.
373. The solar cell module of any one of clauses 334 to 372, wherein the metal layer of the first and/or second fine grid line and the first and/or second interconnection pad, when present, comprises, consists of, or consists essentially of Cu.
374. The solar cell module of any one of clauses 334 to 372, wherein the metal layer of the first and/or second fine grid line and the first and/or second interconnection pad, when present, comprises, consists of, or consists essentially of coated aluminum.
375. The solar cell module of clause 374, wherein the coated aluminum comprises an aluminum layer and, on at least one side of the aluminum layer, and at least one corrosion resistant joining layer contacting the solderable layer.
376. The solar cell module of clause 375, wherein the coated aluminum does not comprise a native oxide between the aluminum layer and the at least one corrosion resistant joining layer.
377. The solar cell module of clause 375 or 376, wherein the at least one corrosion resistant joining layer is:
an alloy of aluminum and a metal, wherein the metal is:
selected from copper (Cu), magnesium (Mg), manganese (Mn), silicon (Si), tin (Sn), zinc (Zn), and a combination thereof; or
selected from chromium (Cr), cobalt (Co), molybdenum (Mo), nickel (Ni), tantalum (Ta), titanium (Ti), tungsten (W), an alloy thereof, a nitride thereof, a boride thereof, a composite thereof, and a combination thereof; or
selected from Ti, an alloy thereof, a nitride thereof, a boride thereof, a composite thereof, and a combination thereof.
378. The solar cell module of any one of clauses 375 to 377, further comprising a second metal layer between, and contacting, the at least one corrosion resistant joining layer and the solderable layer.
379. The solar cell module of clause 378, wherein the second metal layer comprises copper.
380. The solar cell module of any one of clauses 375 to 379, wherein the at least one corrosion resistant joining layer has a thickness, width, or both, ranging from 50 nm to 200 nm, or from 20 nm to 100 nm.
381. The solar cell module of any one of clauses 334 to 380, wherein the metal layer of the first and/or second fine grid line and the first and/or second interconnection pad, when present, has a surface roughness Ra ranging from 100 nm to 500 nm; from 200 nm to 500 nm; or from 300 nm to 500 nm.
382. The solar cell module of any one of clauses 334 to 381, wherein the metal layer of the first and/or second fine grid line and the first and/or second interconnection pad, when present, is laser cut.
383. The solar cell module of clause 382, wherein the metal layer has a burr roughness ranging from 200 nm to 20 μm, from 1 μm from 10 μm, or from 1 μm to 5 μm.
384. The solar cell module of clause 382 or 383, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.
385. The solar cell module of any one of clauses 382 to 384, wherein the metal layer has a burr mean height ranging from 200 nm to 20 μm, from 1 μm to 10 μm, or from 1 μm to 5 μm.
386. The solar cell module of any one of clauses 382 to 385, wherein the metal layer has a dross mean height ranging from 200 nm to 20 μm, from 1 μm to 10 μm, or from 1 μm to 5 μm.
387. The solar cell module of any one of clauses 382 to 386, wherein the metal layer has a dross roughness ranging from 200 nm to 20 μm, from 1 μm to 10 μm, or from 1 μm to 5 μm.
388. The solar cell module of any one of clauses 334 to 387, wherein the solderable layer of the first and/or second fine grid line and the first and/or second interconnection pad, when present, has a thickness of less than 40 μm, less than 30 μm, less than 25 μm, less than 20 μm, or less than 10 μm.
389. The solar cell module of any one of clauses 334 to 388, wherein the silver contact pad of the first and/or second fine grid line and the first and/or second interconnection pad, when present, has a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.
390. The solar cell module of any one of clauses 334 to 389, wherein the glass frit sublayer of the first and/or second fine grid line and the first and/or second interconnection pad, when present, has a thickness from 1 nm to 3 μm, from 1 nm to 1 μm, or from 1 nm to 200 nm.
391. The solar cell module of any one of clauses 334 to 390, wherein the solderable layer of the first and/or second fine grid line and the first and/or second interconnection pad, when present, is a solder layer comprising a solder material.
392. The solar cell module of clause 391, wherein the solder material is a Silver-Aluminum-Copper (SAC) solder material.
393. A method for forming a conductive multilayer stack comprising:
providing a silicon substrate having at least one passivation layer on a front and/or a rear surface of the silicon substrate;
forming a silver contact pad comprising a silver sublayer and a glass frit sublayer, wherein the silver sublayer is on the glass frit sublayer;
forming a solderable layer by applying a solderable paste on the silver contact pad;
applying a metal layer comprising copper (Cu) or coated aluminum on the solderable layer; and
heating the metal layer to mechanically join the metal layer to the solderable layer and the solderable layer to the silver contact pad;
wherein the glass frit sublayer of the conductive multilayer stack contacts at least one portion of the silicon substrate, contacts at least one portion of the at least one passivation layer, or contacts a combination thereof.
394. The method of clause 393, wherein forming the silver contact pad comprises:
applying a silver metallization paste on at least one portion of the silicon substrate or on at least one portion of the at least one passivation layer, the silver metallization paste comprising silver particles and glass frits, and
co-firing the silver metallization paste.
395. A method for forming a conductive multilayer line comprising:
providing a silicon substrate having at least one passivation layer;
forming a discontinuous line of silver contact pads, wherein a silver contact pad of the discontinuous line of silver contact pads comprises a silver sublayer and a glass frit sublayer, wherein the silver sublayer is on the glass frit sublayer;
forming a discontinuous line of solderable pads by applying a discontinuous line of solderable paste on and aligned with the discontinuous line of silver contact pads;
applying a metal layer comprising copper (Cu) or coated aluminum on the discontinuous line of solderable pads; and
heating the metal layer to mechanically join the metal layer to the discontinuous line of solderable pads and the discontinuous line of solderable pads to the discontinuous line of silver contact pads;
wherein the glass frit sublayers of the discontinuous line of silver contact pads contacts at least one portion of the silicon substrate, contact at least one portion of the at least one passivation layer, or contact a combination thereof.
396. The method of clause 395, wherein forming the discontinuous line of silver contact pads comprises:
applying a discontinuous line of silver metallization paste on at least one portion of the silicon substrate or on at least one portion of the at least one passivation layer, the silver metallization paste comprising silver particles and glass frits; and
co-firing the discontinuous line of silver metallization paste.
397. The method of clause 395 or 396, wherein the discontinuous line of silver contact pads comprises a first silver contact pad and a second silver contact pad and wherein the first silver contact pad is separated from a second silver contact pad by a distance from 200 μm to 2 mm, from 300 μm to 1 mm, from 300 μm to 1 mm, from 400 μm to 1 mm, or from 400 μm to 900 μm.
398. The method of any one of clauses 395 to 397, wherein the front and/or rear surface has a total surface are, wherein the silver contact pads have a combined surface area, and wherein the combined surface area ranges from 0.5% to 7%, from 0.5% to 6%, from 0.5% to 5%, from 0.5% to 4%, from 0.5% to 3%, from 0.5% to 2%, from 0.5% to 1%, or from 0.5% to 0.75% of a total surface area.
399. The method of any one of clauses 395 to 398, wherein the silver contact pads have a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.
400. The method of any one of clauses 393 to 399, wherein the glass frit sublayer has a thickness from 1 nm to 3 μm, from 1 nm to 1 μm, or from 1 nm to 200 nm.
401. The method of any one of clauses 393 to 400, wherein the glass frit sublayer is on the at least one portion of the silicon substrate, is on the at least one portion of the at least one passivation layer, or is on a combination thereof.
402. The method of any one of clauses 393 to 401, wherein the metal layer has a thickness ranging from 4 μm to 100 μm, from 4 μm to 50 μm, from 4 μm to 25 μm, from 4 μm to 10 μm, or from 4 μm to 6 μm.
403. The method of any one of clauses 393 to 402, wherein the metal layer has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm.
404. The method of any one of clauses 393 to 403, wherein the silicon substrate has a thickness ranging from 120 μm to 180 μm.
405. The method according to any one of clauses 393 to 404, further comprising laser cutting the metal layer into a pattern prior to applying the metal layer.
406. The method according to clause 405, wherein the metal layer has a burr roughness ranging from 200 nm to 20 μm, from 1 μm to 10 μm, or from 1 μm to 5 μm.
407. The method according to clause 405 or 406, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.
408. The method according to any one of clauses 405 to 407, wherein the metal layer has a burr mean height ranging from 200 nm to 20 μm, from 1 μm to 10 μm, or from 1 μm to 5 μm.
409. The method according to any one of clauses 405 to 408, wherein the metal layer has a dross mean height ranging from 200 nm to 20 μm, from 1 μm to 10 μm, or from 1 μm to 5 μm.
410. The method according to any one of clauses 405 to 409, wherein the metal layer has a dross roughness ranging from 200 nm to 20 μm, from 1 μm to 10 μm, or from 1 μm to 5 μm.
411. The method according to any one of clauses 393 to 410, wherein the conductive multilayer line is a fine grid line or a busbar.
412. The method of any one of clauses 393 to 411, further comprising:
mechanically joining a tabbing wire to the metal layer of the conductive multilayer stack or the conductive multilayer line, wherein the tabbing wire comprises a metal core and a solder coating, wherein the metal layer of the conductive multilayer stack or the conductive multilayer line comprises, consists of, or consists essentially of Cu.
413. The method of clause 412, wherein the tabbing wire is soldered to the metal layer.
414. The method of clause 412 or 413, wherein the metal core comprises:
copper, aluminum, carbon, tin, or iron; or an alloy thereof, a composite thereof, or a combination thereof.
415. The method of any one of clauses 412 to 414, wherein the metal core comprises copper.
416. The method of any one of clauses 412 to 415, wherein the tabbing wire has a diameter from 80 μm to 1000 μm, from 100 μm to 300 μm, or from 120 μm to 200 μm.
417. The method of any one of clauses 412 to 416, wherein the solder coating has a thickness from 0.5 μm to 100 μm or from 10 μm to 50 μm.
418. The method of any one of clauses 412 to 417, wherein the solder coating comprises:
tin, lead, silver, bismuth, copper, zinc, antimony, manganese, or indium; or an alloy thereof, a composite thereof, or a combination thereof.
419. A conductive multilayer stack on a solar cell, the conductive multilayer stack comprising:
a metal layer comprising copper (Cu) or coated aluminum;
a silver contact layer, wherein the silver contact layer does not comprise glass frit; and
a solderable layer between, and contacting, the metal layer and the silver contact layer; and
wherein the solar cell has a doped silicon substrate with a front surface and a rear surface, wherein the front surface of the doped silicon substrate is a light-facing surface, and wherein the rear surface of the doped silicon substrate is opposite of the light-facing surface of the doped silicon substrate;
wherein the front and/or rear surface of the doped silicon substrate has at least one passivation layer thereon,
wherein the at least one passivation layer comprises an intrinsic amorphous layer on at least a portion of the doped silicon substrate, and a doped layer on at least a portion of the intrinsic amorphous layer;
wherein the solar cell has a transparent conductive oxide layer on at least a portion of the doped layer; and
wherein the silver contact layer of the conductive multilayer stack contacts at least a portion of the transparent conductive oxide layer.
420. The conductive multilayer stack of clause 419, wherein the doped layer of the at least one passivation layer contains a different dopant, different dopant type, and/or different dopant concentration from the doped silicon substrate.
421. The conductive multilayer stack of clause 419 or 420, wherein the intrinsic amorphous layer of the at least one passivation layer comprises intrinsic amorphous silicon (a-Si: H(i)).
422. The conductive multilayer stack of any one of clauses 419 to 421, wherein the doped layer of the at least one passivation layer comprises a p-type doped, hydrogenated amorphous silicon (a-Si: H(p)).
423. The conductive multilayer stack of any one of clauses 419 to 421, wherein the doped layer of the at least one passivation layer comprises an n-type doped, hydrogenated amorphous silicon (a-Si: H(n)).
424. The conductive multilayer stack of any one of clauses 419 to 423, wherein the transparent conductive oxide layer comprises indium tin oxide.
425. The conductive multilayer stack of any one of clauses 418 to 424, wherein the intrinsic amorphous layer of the at least one passivation layer contacts at least a portion of the doped silicon substrate, the doped layer of the at least one passivation layer contacts at least a portion of the intrinsic amorphous layer of the at least one passivation layer, and the transparent conductive oxide layer contacts at least a portion of the doped layer of the at least one passivation layer.
426. The conductive multilayer stack of any one of clauses 419 to 425, wherein the at least one passivation layer is on the front surface of the doped silicon substrate.
427. The conductive multilayer stack of any one of clauses 419 to 425, wherein the at least one passivation layer is on the rear surface of the doped silicon substrate.
428. The conductive multilayer stack of clause 427, wherein the doped layer of the at least one passivation layer comprises at least one doped region and at least one oppositely-doped region.
429. The conductive multilayer stack of clause 428, wherein the at least one doped region comprises a p-type dopant and the at least one oppositely-doped region comprises an n-type dopant.
430. The conductive multilayer stack of clause 428 or 429, wherein the transparent conductive oxide layer is between and contacts at least a portion of the at least one doped region and at least a portion of the silver contact layer.
431. The conductive multilayer stack of clause 428 or 429, wherein the transparent conductive oxide layer is between and contacts at least a portion of the at least one oppositely-doped region and at least a portion of the silver contact layer.
432. The conductive multilayer stack of any one of clauses 419 to 431, wherein a thickness of the intrinsic amorphous layer of the at least one passivation layer is from 2 nm to 5 nm.
433. The conductive multilayer stack of any one of clauses 419 to 432, wherein a thickness of the doped layer of the at least one passivation layer is from 10 nm to 50 nm.
434. The conductive multilayer stack of any one of clauses 419 to 433, wherein a thickness of the transparent conductive oxide layer is from 50 nm to 100 nm.
435. The conductive multilayer stack of any one of clauses 419 to 434, wherein the doped silicon substrate comprises an n-type dopant.
436. The conductive multilayer stack of any one of clauses 419 to 435, wherein the doped silicon substrate comprises a p-type dopant.
437. The conductive multilayer stack of any one of clauses 419 to 436, wherein the metal layer has a thickness ranging from 4 μm to 100 μm, from 4 μm to 50 μm, from 4 μm to 25 μm, from 4 μm to 10 μm, or from 4 μm to 6 μm.
438. The conductive multilayer stack of any one of clauses 419 to 437 wherein the metal layer has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm.
439. The conductive multilayer stack of any one of clauses 419 to 438, wherein the substrate has a thickness ranging from 120 μm to 180 μm.
440. The conductive multilayer stack of any one of clauses 419 to 439, wherein the metal layer comprises, consists of, or consists essentially of Cu.
441. The conductive multilayer stack of any one of clauses 419 to 439, wherein the metal layer comprises, consists of, or consists essentially of coated aluminum.
442. The conductive multilayer stack of clause 441, wherein the coated aluminum comprises an aluminum layer and, on at least one side of the aluminum layer, and at least one corrosion resistant joining layer contacting the solderable layer.
443. The conductive multilayer stack of clause 442, wherein the coated aluminum does not comprise a native oxide between the aluminum layer and the at least one corrosion resistant joining layer.
444. The conductive multilayer stack of clause 442 or 443, wherein the at least one corrosion resistant joining layer is:
an alloy of aluminum and a metal, wherein the metal is:
selected from copper (Cu), magnesium (Mg), manganese (Mn), silicon (Si), tin (Sn), zinc (Zn), and a combination thereof; or selected from chromium (Cr), cobalt (Co), molybdenum (Mo), nickel (Ni), tantalum (Ta), titanium (Ti), tungsten (W), an alloy thereof, a nitride thereof, a boride thereof, a composite thereof, and a combination thereof; or selected from Ti, an alloy thereof, a nitride thereof, a boride thereof, a composite thereof, and a combination thereof.
445. The conductive multilayer stack of any one of clauses 442 to 444, further comprising a second metal layer between, and contacting, the at least one corrosion resistant joining layer and the solderable layer.
446. The conductive multilayer stack of clause 445, wherein the second metal layer comprises copper.
447. The conductive multilayer stack of any one of clauses 442 to 446, wherein the at least one corrosion resistant joining layer has a thickness, width, or both, ranging from 50 nm to 200 nm, or from 20 nm to 100 nm.
448. The conductive multilayer stack of any one of clauses 419 to 447, wherein the metal layer has a surface roughness Ra ranging from 100 nm to 500 nm, from 200 nm to 500 nm, or from 300 nm to 500 nm.
449. The conductive multilayer stack of any one of clauses 419 to 448, wherein the metal layer is laser cut.
450. The conductive multilayer stack of clause 449, wherein the metal layer has a burr roughness ranging from 200 nm to 20 μm, from 1 μm from 10 μm, or from 1 μm to 5 μm.
451. The conductive multilayer stack of clause 449 or 450, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.
452. The conductive multilayer stack of any one of clauses 449 to 451, wherein the metal layer has a burr mean height ranging from 200 nm to 20 μm, from 1 μm to 10 μm, or from 1 μm to 5 μm.
453. The conductive multilayer stack of any one of clauses 449 to 452, wherein the metal layer has a dross mean height ranging from 200 nm to 20 μm, from 1 μm to 10 μm, or from 1 μm to 5 μm.
454. The conductive multilayer stack of any one of clauses 449 to 453, wherein the metal layer has a dross roughness ranging from 200 nm to 20 μm, from 1 μm to 10 μm, or from 1 μm to 5 μm.
455. The conductive multilayer stack of any one of clauses 419 to 454, wherein the solderable layer has a thickness of less than 40 μm, less than 30 μm, less than 25 μm, less than 20 μm, or less than 10 μm.
456. The conductive multilayer stack of any one of clauses 419 to 455, wherein the silver contact layer has a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.
457. The conductive multilayer stack of any one of clauses 419 to 456, wherein the solderable layer is a solder layer comprising a solder material.
458. The conductive multilayer stack of clause 457, wherein the solder material is a Silver-Aluminum-Copper (SAC) solder material.
459. The conductive multilayer stack of any one of clause 419 to 458, wherein the silver contact layer is a silver contact pad.
460. The conductive multilayer stack of any one of clauses 419 to 459, wherein the doped silicon substrate and at least one passivation layer are the silicon substrate and the at least one passivation layer of a solar cell.
461. A solar cell comprising at least two grid lines having two or more conductive multilayer stacks of any one of clauses 419 to 460.
462. The solar cell of clause 461, wherein the at least two grid lines are a fine grid line, a busbar, or a combination thereof.
463. The solar cell of clause 461 or 462, wherein a silver contact pad of a first conductive multilayer stack of the two or more conductive multilayer stacks is separated from a silver contact pad of a second conductive multilayer stack of the two or more conductive multilayer stacks by a distance from 200 μm to 2 mm, from 200 μm to 1 mm, from 300 μm to 1 mm, from 400 μm to 1 mm, or from 400 μm to 900 μm.
464. A symmetric solar cell comprising:
a doped silicon substrate having a front surface and a rear surface, wherein the front surface of the doped silicon substrate is a light-facing surface and the rear surface is opposite of the light-facing surface;
at least one passivation layer on at least a portion of the front and/or rear surface of the silicon substrate, wherein the at least one passivation layer comprises an intrinsic amorphous layer on at least a portion of the doped silicon substrate, and a doped layer on at least a portion of the intrinsic amorphous layer;
a transparent conductive oxide layer on at least a portion of the at least one passivation layer; and
at least one fine grid line on at least a portion of the front and/or rear surface of the doped silicon substrate;
wherein the at least one fine grid line is a conductive multilayer line comprising at least two conductive multilayer stacks, a conductive multilayer stack of the at least two conductive multilayer stacks comprising:
a metal layer comprising copper (Cu) or coated aluminum;
a silver contact pad, wherein the silver contact pad does not comprise glass frit; and
a solderable layer between, and contacting, the metal layer and the silver contact pad;
wherein the silver contact pad of the conductive multilayer stack contacts at least a portion of the transparent conductive oxide layer; and
wherein the metal layer of the conductive multilayer stack is a continuous layer that connects the at least two conductive multilayer stacks in the conductive multilayer line.
465. The symmetric solar cell of clause 464, wherein the doped layer of the at least one passivation layer contains a different dopant, different dopant type, and/or different dopant concentration from the doped silicon substrate.
466. The symmetric solar cell of clause 464 or 465, wherein the intrinsic amorphous layer of the at least one passivation layer comprises intrinsic amorphous silicon (a-Si: H(i)).
467. The symmetric solar cell of any one of clauses 464 to 466, wherein the doped layer of the at least one passivation layer comprises a p-type doped hydrogenated amorphous silicon (a-Si: H(p)).
468. The symmetric solar cell of any one of clauses 464 to 466, wherein the doped layer of the at least one passivation layer comprises an n-type doped hydrogenated amorphous silicon (a-Si: H(n)).
469. The symmetric solar cell of any one of clauses 464 to 468, wherein the transparent conductive oxide layer comprises indium tin oxide.
470. The symmetric solar cell of any one of clauses 464 to 469, wherein the intrinsic amorphous layer of the at least one passivation layer contacts at least a portion of the doped silicon substrate, the doped layer of the at least one passivation layer contacts at least a portion of the intrinsic amorphous layer of the at least one passivation layer, and the transparent conductive oxide layer contacts at least a portion of the doped layer of the at least one passivation layer.
471. The symmetric solar cell of any one of clauses 464 to 470, wherein the at least one passivation layer is on the front surface of the doped silicon substrate.
472. The symmetric solar cell of any one of clauses 464 to 471, wherein the at least one passivation layer is on the rear surface of the doped silicon substrate.
473. The symmetric solar cell of any one of clauses 464 to 472, wherein a thickness of the intrinsic amorphous layer of the at least one passivation layer is from 2 nm to 5 nm.
474. The symmetric solar cell of any one of clauses 464 to 473, wherein a thickness of the doped layer of the at least one passivation layer is from 10 nm to 50 nm.
475. The symmetric solar cell of any one of clauses 464 to 474, wherein a thickness of the transparent conductive oxide layer is from 50 nm to 100 nm.
476. The symmetric solar cell of any one of clauses 464 to 475, wherein the doped silicon substrate is n-type doped.
477. The symmetric solar cell of any one of clauses 464 to 475, wherein the doped silicon substrate is p-type doped.
478. The symmetric solar cell of any one of clauses 464 to 477, further comprising at least one busbar on at least a portion of the front and/or rear surface of the doped silicon substrate, wherein the at least one fine grid line contacts the at least one busbar.
479. The symmetric solar cell of clause 478, wherein the at least one busbar is a conductive multilayer line that comprises at least two conductive multilayer stacks, a conductive multilayer stack of the at least two conductive multilayer stacks comprising:
a metal layer comprising copper (Cu) or coated aluminum;
a silver contact pad comprising a silver sublayer and no glass frit; and
a solderable layer between, and contacting, the metal layer and the silver contact pad;
wherein the silver contact pad of the conductive multilayer stack contacts at least a portion of the doped silicon substrate, contacts at least a portion of the at least one passivation layer, or contacts a combination thereof, and
wherein the metal layer of the conductive multilayer stack is a continuous layer that connects the at least two conductive multilayer stacks of the conductive multilayer line.
480. The symmetric solar cell of clause 478 or 479, further comprising at least one solder pad on at least a portion of the front and/or rear surface of the doped silicon substrate, wherein the at least one fine grid line contacts the at least one solder pad, and wherein the at least one solder pad contacts the at least one busbar.
481. The symmetric solar cell of any one of clauses 464 to 480, wherein a silver contact pad of a first conductive multilayer stack of the at least two conductive multilayer stacks of the at least one fine grid line is separated from a silver contact pad of a second conductive multilayer stack of the at least two conductive multilayer stacks by a distance from 200 μm to 2 mm, 300 μm to 2 m, 300 μm to 1 mm, 400 μm to 1 mm, or 400 μm to 900 μm.
482. The symmetric solar cell of any one of clauses 464 to 481, wherein the metal layer of the at least one fine grid line and the at least one busbar, when present, has a thickness ranging from 4 μm to 100 μm, from 4 μm to 50 μm, from 4 μm to 25 μm, from 4 μm to 10 μm, or from 4 μm to 6 μm.
483. The symmetric solar cell of any one of clauses 464 to 482, wherein the metal layer of the at least one fine grid line and the at least one busbar, when present, has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm.
484. The symmetric solar cell of any one of clauses 464 to 483, wherein the substrate has a thickness ranging from 120 μm to 180 μm.
485. The symmetric solar cell of any one of clauses 464 to 484, wherein the metal layer of the at least one fine grid line and the at least one busbar, when present, comprises, consists of, or consists essentially of Cu.
486. The symmetric solar cell of clause 485, further comprising a tabbing wire contacting the metal layer of the at least one fine grid line, wherein the tabbing wire comprises a metal core and a solder coating.
487. The symmetric solar cell of clause 486, wherein the tabbing wire is soldered to the metal layer of the at least one fine grid line.
488. The symmetric solar cell of clause 486 or 487, wherein the metal core comprises copper, aluminum, carbon, tin, iron, an alloy thereof, a composite thereof, or a combination thereof.
489. The symmetric solar cell of any one of clauses 486 to 488, wherein the metal core comprises copper.
490. The symmetric solar cell of any one of clauses 486 to 489, wherein the tabbing wire has a diameter from 80 μm to 1000 μm, from 100 μm to 300 μm, or from 120 μm to 200 μm.
491. The symmetric solar cell of any one of clauses 486 to 490, wherein the tabbing wire has a thickness from 0.5 μm to 100 μm or from 10 μm to 50 μm.
492. The symmetric solar cell of any one of clauses 486 to 491, wherein the solder coating comprises tin, lead, bismuth, copper, zinc, antimony, manganese, indium, an alloy thereof, a composite thereof, or a combination thereof.
493. The symmetric solar cell of any one of clauses 464 to 484, wherein the metal layer of the at least one fine grid line and the at least one busbar, when present, comprises, consists of, or consists essentially of coated aluminum.
494. The symmetric solar cell of clause 493, wherein the coated aluminum comprises an aluminum layer and, on at least one side of the aluminum layer, and at least one corrosion resistant joining layer contacting the solderable layer.
495. The symmetric solar cell of clause 494, wherein the coated aluminum does not comprise a native oxide between the aluminum layer and the at least one corrosion resistant joining layer.
496. The symmetric solar cell of clause 494 or 495, wherein the at least one corrosion resistant joining layer is:
an alloy of aluminum and a metal, wherein the metal is:
selected from copper (Cu), magnesium (Mg), manganese (Mn), silicon (Si), tin (Sn), zinc (Zn), and a combination thereof, or
selected from chromium (Cr), cobalt (Co), molybdenum (Mo), nickel (Ni), tantalum (Ta), titanium (Ti), tungsten (W), an alloy thereof, a nitride thereof, a boride thereof, a composite thereof, and a combination thereof; or
selected from Ti, an alloy thereof, a nitride thereof, a boride thereof, a composite thereof, and a combination thereof.
497. The symmetric solar cell of any one of clauses 494 to 496, further comprising a second metal layer between, and contacting, the at least one corrosion resistant joining layer and the solderable layer.
498. The symmetric solar cell of clause 497, wherein the second metal layer comprises copper.
499. The symmetric solar cell of any one of clauses 494 to 498, wherein the at least one corrosion resistant joining layer has a thickness, width, or both, ranging from 50 nm to 200 nm, or from 20 nm to 100 nm.
500. The symmetric solar cell of any one of clauses 464 to 499, wherein the metal layer of the at least one fine grid line and the at least one busbar, when present, has a surface roughness Ra ranging from 100 nm to 500 nm, from 200 nm to 500 nm, or from 300 nm to 500 nm.
501. The symmetric solar cell of any one of clauses 464 to 500, wherein the metal layer of the at least one fine grid line and the at least one busbar, when present, is laser cut.
502. The symmetric solar cell of clause 501, wherein the metal layer has a burr roughness ranging from 200 nm to 20 μm, from 1 μm from 10 μm, or from 1 μm to 5 μm.
503. The symmetric solar cell of clause 501 or 502, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.
504. The symmetric solar cell of any one of clauses 501 to 503, wherein the metal layer has a burr mean height ranging from 200 nm to 20 μm, from 1 μm to 10 μm, or from 1 μm to 5 μm.
505. The symmetric solar cell of any one of clauses 501 to 504, wherein the metal layer has a dross mean height ranging from 200 nm to 20 μm, from 1 μm to 10 μm, or from 1 μm to 5 μm.
506. The symmetric solar cell of any one of clauses 501 to 505, wherein the metal layer has a dross roughness ranging from 200 nm to 20 μm, from 1 μm to 10 μm, or from 1 μm to 5 μm.
507. The symmetric solar cell of any one of clauses 464 to 506, wherein the solderable layer of the at least one fine grid line and the at least one busbar, when present, has a thickness of less than 40 μm, less than 30 μm, less than 25 μm, less than 20 μm, or less than 10 μm.
508. The symmetric solar cell of any one of clauses 464 to 507, wherein the silver contact pad of the at least one fine grid line and the at least one busbar, when present, has a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.
509. The symmetric solar cell of any one of clauses 464 to 508, wherein the solderable layer of the at least one fine grid line and the at least one busbar, when present, is a solder layer comprising a solder material.
510. The symmetric solar cell of clause 509, wherein the solder material is a Silver-Aluminum-Copper (SAC) solder material.
511. The symmetric solar cell of any one of clauses 464 to 510, wherein the front and/or rear surface of the doped silicon substrate has a total surface area, wherein the silver contact pads of the at least one fine grid line and the at least one busbar, when present, have a combined surface area, and wherein the combined surface area ranges from 0.5% to 7%, from 0.5% to 6%, from 0.5% to 5%, from 0.5% to 4%, from 0.5% to 3%, from 0.5% to 2%, from 0.5% to 1%, or from 0.5% to 0.75% of the total surface area.
512. An asymmetric solar cell comprising:
a silicon substrate having a front, light-facing surface and a rear surface, wherein the rear surface is opposite of the light-facing surface;
at least one passivation layer on at least a portion of the rear surface of the silicon substrate, wherein the at least one passivation layer comprises an intrinsic amorphous layer on at least a portion of the substrate and a doped layer on at least a portion of the intrinsic amorphous layer, wherein the doped layer comprises at least one doped region and at least one oppositely-doped region;
a transparent conductive oxide layer on at least a portion of the at least one passivation layer
at least one first fine grid line on at least a portion of the transparent conductive oxide layer;
at least one second fine grid line on at least a portion of the transparent conductive oxide layer;
wherein at least one of the at least one first fine grid line or the at least one second fine grid line is a first conductive multilayer line comprising at least two conductive multilayer stacks;
wherein a conductive multilayer stack of the at least two conductive multilayer stacks comprises:
a metal layer comprising copper (Cu) or coated aluminum;
a silver contact pad comprising a silver sublayer and no glass frit; and
a solderable layer between, and contacting, the metal layer and the silver contact pad;
wherein the silver contact pad of the conductive multilayer stack contacts at least a portion of the transparent conductive oxide layer; and
wherein the metal layer of the conductive multilayer stack is a continuous layer that connects the at least two conductive multilayer stacks of the first conductive multilayer line.
513. The asymmetric solar cell of clause 512, wherein either the at least one fine grid line or the at least one second fine grid line is the first conductive multilayer line and the other comprises sintered aluminum.
514. The asymmetric solar cell of clause 512, wherein the at least one first fine grid line is a first conductive multilayer line comprising at least two conductive multilayer stacks, and wherein the at least one second fine grid line is a second conductive multilayer line comprising at least two conductive multilayer stacks.
515. The asymmetric solar cell of any one of clauses 512 to 514, further comprising:
at least one first interconnection pad contacting the at least one first fine grid line; and
at least one second interconnection pad contacting the at least one second fine grid line;
wherein the at least one first interconnection pad is a third conductive multilayer line comprising at least two conductive multilayer stacks; and
wherein the at least one second interconnection pad is a fourth conductive multilayer line comprising at least two conductive multilayer stacks, a conductive multilayer stack of the at least two conductive multilayer stacks in the third and/or fourth conductive multilayer line comprising:
a metal layer comprising copper (Cu) or coated aluminum;
a silver contact pad comprising a silver sublayer and no glass frit; and
a solderable layer between, and contacting, the metal layer and the silver contact pad; and
wherein the silver contact pad of the conductive multilayer stack contacts at least a portion of the transparent conductive oxide layer; and
wherein the metal layer of the conductive multilayer stack is a continuous layer that connects the at least two conductive multilayer stacks of the at least one first and/or second interconnection pad.
516. The asymmetric solar cell of clause 515, wherein the metal layer of the at least two conductive multilayer stacks of the first conductive multilayer line is a continuous layer that is connected to the at least two conductive multilayer stacks of the third conductive multilayer line.
517. The asymmetric solar cell of clause 515 or 516, wherein the metal layer of the at least two conductive multilayer stacks of the second conductive multilayer line is a continuous layer that is connected to the at least two conductive multilayer stacks of the fourth conductive multilayer line.
518. The asymmetric solar cell of any one of clauses 512 to 517, further comprising at least one first solder pad on at least a first portion of the front and/or rear surface of the silicon substrate and at least one second solder pad on at least a second portion of the front and/or rear surface of the silicon substrate, wherein the at least one first fine grid line contacts the at least one first solder pad, and wherein the at least one second fine grid line contacts the at least one second solder pad.
519. The asymmetric solar cell of any one of clauses 512 to 518, wherein the intrinsic amorphous layer of the at least one passivation layer comprises intrinsic amorphous silicon (a-Si: H(i)).
520. The asymmetric solar cell of any one of clauses 512 to 519, wherein the at least one oppositely-doped region comprises an n-type doped hydrogenated amorphous silicon (a-Si: H(n)).
521. The asymmetric solar cell of any one of clauses 512 to 519, wherein the at least one doped region comprises a p-type doped hydrogenated amorphous silicon (a-Si: H(p)).
522. The asymmetric solar cell of any one of clauses 512 to 521, wherein the transparent conductive oxide layer comprises indium tin oxide.
523. The asymmetric solar cell of any one of clauses 512 to 522, wherein the intrinsic amorphous layer of the at least one passivation layer contacts at least a portion of the silicon substrate, the at least one doped region of the at least one passivation layer contacts at least a portion of the intrinsic amorphous layer, and the transparent conductive oxide layer contacts at least a portion of the at least one doped region.
524. The asymmetric solar cell of any one of clauses 512 to 522, wherein the intrinsic amorphous layer of the at least one passivation layer contacts at least a portion of the silicon substrate, the at least one oppositely-doped region of the at least one passivation layer contacts at least a portion of the intrinsic amorphous layer, and the transparent conductive oxide layer contacts at least a portion of the at least one oppositely-doped region.
525. The asymmetric solar cell of any one of clauses 512 to 524, wherein the transparent conductive oxide layer is between and contacts at least a portion of the at least one doped region of the at least one passivation layer and at least a portion of the silver contact pad of the at least one first and/or second fine grid line.
526. The asymmetric solar cell of any one of clauses 512 to 524, wherein the transparent conductive oxide layer is between and contacts at least a portion of the at least one oppositely-doped region of the at least one passivation layer and at least a portion of the silver contact pad of the at least one first and/or second fine grid line.
527. The asymmetric solar cell of any one of clauses 512 to 526, wherein a thickness of the intrinsic amorphous layer of the at least one passivation layer is from 2 nm to 5 nm.
528. The asymmetric solar cell of any one of clauses 512 to 527, wherein a thickness of the doped layer of the at least one passivation layer is from 10 nm to 50 nm.
529. The asymmetric solar cell of any one of clauses 512 to 528, wherein a thickness of the transparent conductive oxide layer is from 50 nm to 100 nm.
530. The asymmetric solar cell of any one of clauses 512 to 529, wherein the silicon substrate is p-type doped.
531. The asymmetric solar cell of any one of clauses 512 to 529, wherein the silicon substrate is n-type doped.
532. The asymmetric solar cell of any one of clauses 512 to 531, wherein a silver contact pad of a first conductive multilayer stack of the at least two conductive multilayer stacks of the first conductive multilayer line is separated from a silver contact pad of a second conductive multilayer stack by a distance from 200 μm to 2 mm, 300 μm to 2 mm, 300 μm to 1 mm, 400 μm to 1 mm, or 400 μm to 900 μm.
533. The asymmetric solar cell of any one of clauses 512 to 532, wherein the metal layer of the at least one first and/or second fine grid line and the at least one first and/or second interconnection pad, when present. has a thickness ranging from 4 μm to 100 μm, from 4 μm to 50 μm, from 4 μm to 25 μm, from 4 μm to 10 μm, or from 4 μm to 6 μm.
534. The asymmetric solar cell of any one of clauses 512 to 533, wherein the metal layer of the at least one first and/or second fine grid line and the at least one first and/or second interconnection pad, when present, has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm.
535. The asymmetric solar cell of any one of clauses 512 to 534, wherein the substrate has a thickness ranging from 120 μm to 180 μm.
536. The asymmetric solar cell of any one of clauses 512 to 535, wherein the metal layer of the at least one first and/or second fine grid line and the at least one first and/or second interconnection pad, when present, comprises, consists of, or consists essentially of Cu.
537. The asymmetric solar cell of any one of clauses 512 to 535, wherein the metal layer of the at least one first and/or second fine grid line and the at least one first and/or second interconnection pad, when present, comprises, consists of, or consists essentially of coated aluminum.
538. The asymmetric solar cell of clause 537, wherein the coated aluminum comprises an aluminum layer and, on at least one side of the aluminum layer, and at least one corrosion resistant joining layer contacting the solderable layer.
539. The asymmetric solar cell of clause 538, wherein the coated aluminum does not comprise a native oxide between the aluminum layer and the at least one corrosion resistant joining layer.
540. The asymmetric solar cell of clause 538 or 539, wherein the at least one corrosion resistant joining layer is:
an alloy of aluminum and a metal, wherein the metal is:
selected from copper (Cu), magnesium (Mg), manganese (Mn), silicon (Si), tin (Sn), zinc (Zn), and a combination thereof; or
selected from chromium (Cr), cobalt (Co), molybdenum (Mo), nickel (Ni), tantalum (Ta), titanium (Ti), tungsten (W), an alloy thereof, a nitride thereof, a boride thereof, a composite thereof, and a combination thereof; or
selected from Ti, an alloy thereof, a nitride thereof, a boride thereof, a composite thereof, and a combination thereof.
541. The asymmetric solar cell of any one of clauses 538 to 540, further comprising a second metal layer between, and contacting, the at least one corrosion resistant joining layer and the solderable layer.
542. The asymmetric solar cell of clause 541, wherein the second metal layer comprises copper.
543. The asymmetric solar cell of any one of clauses 538 to 542, wherein the at least one corrosion resistant joining layer has a thickness, width, or both, ranging from 50 nm to 200 nm, or from 20 nm to 100 nm.
544. The asymmetric solar cell of any one of clauses 512 to 543, wherein the metal layer of the at least one first and/or second fine grid line and the at least one first and/or second interconnection pad, when present, has a surface roughness Ra ranging from 100 nm to 500 nm; from 200 nm to 500 nm; or from 300 nm to 500 nm.
545. The asymmetric solar cell of any one of clauses 512 to 544, wherein the metal layer of the at least one first and/or second fine grid line and the at least one first and/or second interconnection pad, when present, is laser cut.
546. The asymmetric solar cell of clause 545, wherein the metal layer has a burr roughness ranging from 200 nm to 20 μm, from 1 μm from 10 μm, or from 1 μm to 5 μm.
547. The asymmetric solar cell of clause 545 or 546, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.
548. The asymmetric solar cell of any one of clauses 545 to 547, wherein the metal layer has a burr mean height ranging from 200 nm to 20 μm, from 1 μm to 10 μm, or from 1 μm to 5 μm.
549. The asymmetric solar cell of any one of clauses 545 to 548, wherein the metal layer has a dross mean height ranging from 200 nm to 20 μm, from 1 μm to 10 μm, or from 1 μm to 5 μm.
550. The asymmetric solar cell of any one of clauses 545 to 549, wherein the metal layer has a dross roughness ranging from 200 nm to 20 μm, from 1 μm to 10 μm, or from 1 μm to 5 μm
551. The asymmetric solar cell of any one of clauses 512 to 550, wherein the solderable layer of the at least one first and/or second fine grid line and the at least one first and/or second interconnection pad, when present, has a thickness of less than 40 μm, less than 30 μm, less than 25 μm, less than 20 μm, or less than 10 μm.
552. The asymmetric solar cell of any one of clauses 512 to 551, wherein the silver contact pad of the at least one first and/or second fine grid line and the at least one first and/or second interconnection pad, when present, has a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.
553. The asymmetric solar cell of any one of clauses 512 to 552, wherein the solderable layer of the at least one first and/or second fine grid line and the at least one first and/or second interconnection pad, when present, is a solder layer comprising a solder material.
554. The asymmetric solar cell of clause 553, wherein the solder material is a Silver-Aluminum-Copper (SAC) solder material.
555. The asymmetric solar cell of any one of clauses 512 to 554, wherein the rear surface of the silicon substrate has a total surface area, wherein the silver contact pads of the at least one first and/or second fine grid line and the at least one first and/or second interconnection pad, when present, have a combined surface area, and wherein the combined surface area ranges from 0.5% to 7%, from 0.5% to 6%, from 0.5% to 5%, from 0.5% to 4%, from 0.5% to 3%, from 0.5% to 2%, from 0.5% to 1%, or from 0.5% to 0.75% of the total surface area.
556. A solar cell module comprising:
a first solar cell and a second solar cell;
an interconnect that connects the first solar cell and the second solar cell;
wherein the first solar cell and the second solar cell comprise:
a doped silicon substrate having a front surface and a rear surface, wherein the front surface is a light-facing surface, and the rear surface is opposite of the light-facing surface;
at least one passivation layer directly on at least a portion of the front and/or rear surface of the silicon substrate, wherein the at least one passivation layer comprises an intrinsic amorphous layer on at least a portion of the doped silicon substrate and a doped layer on at least a portion of the intrinsic amorphous layer;
a transparent conductive oxide layer on at least a portion of the at least one passivation layer;
and
at least one fine grid line on at least a portion of the front and/or rear surface of the doped silicon substrate;
wherein the at least one fine grid line is a conductive multilayer line comprising at least two conductive multilayer stacks, a conductive multilayer stack of the at least two conductive
a metal layer comprising copper (Cu) or coated aluminum;
a silver contact pad comprising a silver sublayer and no glass frit; and
a solderable layer between, and contacting, the metal layer and the silver contact pad; and
wherein the silver contact pad of the conductive multilayer stack contacts at least a portion of the transparent conductive oxide layer; and
wherein the metal layer of the conductive multilayer stack is a continuous layer that connects the at least two conductive multilayer stacks of the conductive multilayer line.
557. The solar cell module of clause 556, wherein the first solar cell and the second solar cell further comprise:
at least one solder pad on at least a portion of the front and/or rear surface of the doped silicon substrate; and
at least one busbar on at least a portion of the front and/or rear surface of the doped silicon substrate, wherein the at least one busbar contacts the at least one solder pad,
wherein the interconnect comprises a first tabbing wire contacting the at least one solder pad on the first solar cell and the at least one solder pad on the second solar cell, and a bus ribbon that contacts the first tabbing wire.
558. The solar cell module of clause 557, wherein the at least one fine grid line on the first solar cell contacts the at least one busbar on the first solar cell, and the at least one fine grid line on the second solar cell contacts the at least one busbar on the second solar cell.
559. The solar cell module of clause 557 or 558, wherein the respective at least one busbar on the first solar cell and the second solar cell is a conductive multilayer line comprising at least two conductive multilayer stacks, a conductive multilayer stack of the at least two conductive multilayer stacks comprising:
a metal layer comprising copper (Cu) or coated aluminum;
a silver contact pad comprising a silver sublayer and no glass frit;
a solderable layer between, and contacting, the metal layer and the silver contact pad;
wherein the silver contact pad of the conductive multilayer stack contacts at least a portion of the transparent conductive oxide layer; and
wherein the metal layer of the conductive multilayer stack is a continuous layer that connects the at least two conductive multilayer stacks of the at least one busbar.
560. The solar cell module of clause 556, wherein the interconnect comprises a first interconnection pad on the first solar cell and a second interconnection pad on the second solar cell, wherein the first interconnection pad contacts the second interconnection pad to form a contact.
561. The solar cell module of clause 560, wherein the first solar cell and the second solar cell further comprise at least one busbar on at least a portion of the front and/or rear surface of the doped silicon substrate, wherein the respective at least one fine grid line contacts the respective at least one busbar.
562. The solar cell module of clause 561, wherein the respective at least one busbar on the first solar cell and the second solar cell is a conductive multilayer line comprising at least two conductive multilayer stacks, a conductive multilayer stack of the at least two conductive multilayer stacks comprising:
a metal layer comprising copper (Cu) or coated aluminum;
a silver contact pad comprising a silver sublayer and no glass frit;
a solderable layer between, and contacting, the metal layer and the silver contact pad;
wherein the silver contact pad of the conductive multilayer stack contacts at least a portion of the transparent conductive oxide layer; and
wherein the metal layer of the conductive multilayer stack is a continuous layer that connects the at least two conductive multilayer stacks of the respective at least one busbar.
563. The solar cell module of any one of clauses 560 to 562, wherein the first interconnection pad and/or the second interconnection pad is a conductive multilayer line comprising at least two conductive multilayer stacks, a conductive multilayer stack of the at least two conductive multilayer stacks comprising:
a metal layer comprising copper (Cu) or coated aluminum;
a silver contact pad comprising a silver sublayer and no glass frit;
a solderable layer between, and contacting, the metal layer and the silver contact pad;
wherein the silver contact pad of the conductive multilayer stack contacts at least a portion of the transparent conductive oxide layer; and
wherein the metal layer of the conductive multilayer stack is a continuous layer that connects the at least two conductive multilayer stacks of the conductive multilayer line.
564. The solar cell module of any one of clauses 560 to 563, wherein the first interconnection pad contacts the at least two conductive multilayer stacks of the at least one fine grid line and the at least two conductive multilayer stacks of the at least one busbar of the respective first solar cell and second fine grid line on the first solar cell, and wherein the second interconnection pad contacts the at least two conductive multilayer stacks of the at least one fine grid line and the at least two conductive multilayer stacks of the at least one busbar on the second solar cell.
565. The solar cell module of any one of clauses 560 to 564, wherein the first interconnection pad, the second interconnection pad, or both, are a metal comprising copper (Cu) or coated aluminum.
566. The solar cell module of any one of clauses 560 to 565, wherein the contact of the first interconnection pad and the second interconnection pad is a weld.
567. The solar cell module of any one of clauses 560 to 566, wherein the first interconnection pad contacts the metal layer of the at least two conductive multilayer stacks of the at least one fine grid line and/or the metal layer of the at least two conductive multilayer stacks of the at least one busbar on the first solar cell
568. The solar cell module of any one of clauses 560 to 567, wherein the second interconnection pad contacts the metal layer of the at least two conductive multilayer stacks of the at least one fine grid line and/or the metal layer of the at least two conductive multilayer stacks of the at least one busbar on the second solar cell.
569. The solar cell module of any one of clauses 561 to 568, wherein the first interconnection pad contacts the at least one busbar on the first solar cell.
570. The solar cell module of any one of clauses 561 to 569, wherein the second interconnection pad contacts the at least one busbar on the second solar cell.
571. The solar cell module of clause 556, wherein the interconnect comprises at least one first tabbing wire that contacts the at least one fine grid line on the first solar cell or the second solar cell, wherein the at least one first tabbing wire comprises a metal core and a solder coating, and wherein the interconnect further comprises a bus ribbon contacting the at least one first tabbing wire.
572. The solar cell module of clause 571, wherein the at least one first tabbing wire contacts the at least one fine grid line on the first solar cell and the at least one fine grid line on the second solar cell.
573. The solar cell module of clause 571 or 572, wherein the at least one first tabbing wire is soldered to the respective metal layer of the respective at least one fine grid line on the first solar cell and the second solar cell.
574. The solar cell module of any one of clauses 571 to 573, wherein the metal layer of the at least two conductive multilayer stacks of the at least one fine grid line on the first solar cell and the at least one fine grid line on the second solar cell comprises copper (Cu).
575. The solar cell module of any one of clauses 571 to 574, wherein the metal core comprises copper, aluminum, carbon, tin, iron, or an alloy thereof, a composite thereof, or a combination thereof.
576. The solar cell module of any one of clauses 571 to 575, wherein the metal core comprises copper.
577. The solar cell module of any one of clauses 571 to 576, wherein the at least one first tabbing wire has a diameter from 80 μm to 1000 μm, from 100 μm to 300 μm, or from 120 μm to 200 μm.
578. The solar cell module of any one of clauses 571 to 577, wherein the solder coating has a thickness from 0.5 μm to 100 μm or from 10 μm to 50 μm.
579. The solar cell module of any one of clauses 571 to 578, wherein the solder coating comprises tin, lead, silver, bismuth, copper, zinc, antimony, manganese, indium, or an alloy thereof, a composite thereof, or a combination thereof.
580. The solar cell module of any one of clauses 571 to 579, wherein the first solar cell and the second solar cell further comprise at least one solder pad on the respective front surface and/or rear surface of the first solar cell and the second solar cell.
581. The solar cell module of clause 580, wherein the first solar cell and the second solar cell further comprise at least one second tabbing wire contacting the respective at least one solder pad on the front surface and/or rear surface of the first solar cell and the second solar cell.
582. The solar cell module of any one of clauses 571 to 581, wherein the at least one first tabbing wire contacts the respective at least one fine grid line on the rear surface of the first solar cell and the second solar cell.
583. The solar cell module of any one of clauses 571 to 582, further comprising at least one second fine grid line on at least a portion of the front surface and/or rear surface of the first solar cell and second solar cell, wherein the at least one second fine grid line is a conductive multilayer line comprising at least two conductive multilayer stacks, a conductive multilayer stack of the at least two conductive multilayer stacks comprising:
a metal layer comprising copper (Cu) or coated aluminum;
a silver contact pad comprising a silver sublayer and no glass frit; and
a solderable layer between, and contacting, the metal layer and the silver contact pad;
wherein the silver contact pad of the conductive multilayer stack contacts the transparent conductive oxide layer; and
wherein the metal layer of the conductive multilayer stack is a continuous layer that connects the at least two conductive multilayer stacks.
584. The solar cell module of any one of clauses 556 to 583, wherein the doped layer of the at least one passivation layer contains a different dopant, different dopant type, and/or different dopant concentration from the doped silicon substrate.
585. The solar cell module of any one of clauses 556 to 584, wherein the intrinsic amorphous silicon layer of the at least one passivation layer comprises intrinsic amorphous silicon (a-Si: H(i)).
586. The solar cell module of any one of clauses 556 to 585, wherein the doped layer of the at least one passivation layer comprises a p-type doped hydrogenated amorphous silicon (a-Si: H(p)).
587. The solar cell module of any one of clauses 556 to 586, wherein the doped layer of the at least one passivation layer comprises an n-type doped hydrogenated amorphous silicon (a-Si: H(n)).
588. The solar cell module of any one of clauses 556 to 587, wherein the transparent conductive oxide layer comprises indium tin oxide.
589. The solar cell module of any one of clauses 556 to 588, wherein the intrinsic amorphous layer of the at least one passivation layer contacts at least a portion of the doped silicon substrate, the doped layer of the at least one passivation layer contacts at least a portion of the intrinsic amorphous layer, and/or the transparent conductive oxide layer contacts at least a portion of the doped layer.
590. The solar cell module of any one of clauses 556 to 589, wherein the at least one passivation layer is on the front surface of the doped silicon substrate.
591. The solar cell module of any one of clauses 556 to 590, wherein the at least one passivation layer is on the rear surface of the doped silicon substrate.
592. The solar cell module of any one of clauses 556 to 591, wherein a thickness of the intrinsic amorphous silicon layer of the at least one passivation layer is from 2 nm to 5 nm.
593. The solar cell module of any one of clauses 556 to 592, wherein a thickness of the doped layer of the at least one passivation layer is from 10 nm to 50 nm.
594. The solar cell module of any one of clauses 556 to 593, wherein a thickness of the transparent conductive oxide layer is from 50 nm to 100 nm.
595. The solar cell module of any one of clauses 556 to 594, wherein the silicon substrate is p-type doped.
596. The solar cell module of any one of clauses 556 to 594, wherein the silicon substrate is n-type doped.
597. The solar cell module of any one of clauses 556 to 596, wherein a silver contact pad of a first conductive multilayer stack of the at least two conductive multilayer stacks of the at least one fine grid line is separated from a silver contact pad of a second conductive multilayer stack by a distance from 200 μm to 2 mm, 300 μm to 2 mm, 300 μm to 1 mm, 400 μm to 1 mm, or 400 μm to 900 μm.
598. The solar cell module of any one of clauses 556 to 597, wherein the metal layer of the at least one fine grid line, the at least one busbar, when present, and the first and/or second interconnection pad, when present, has a thickness ranging from 4 μm to 100 μm, from 4 μm to 50 μm, from 4 μm to 25 μm, from 4 μm to 10 μm, or from 4 μm to 6 μm.
599. The solar cell module of any one of clauses 556 to 598, wherein the metal layer of the at least one fine grid line, the at least one busbar, when present, and the first and/or second interconnection pad, when present, has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm.
600. The solar cell module of any one of clauses 556 to 599, wherein the substrate has a thickness ranging from 120 μm to 180 μm.
601. The solar cell module of any one of clauses 556 to 600, wherein the metal layer of the at least one fine grid line, the at least one busbar, when present, and the first and/or second interconnection pad, when present, comprises, consists of, or consists essentially of Cu.
602. The solar cell module of any one of clauses 556 to 600, wherein the metal layer of the at least one fine grid line, the at least one busbar, when present, and the first and/or second interconnection pad, when present, comprises, consists of, or consists essentially of coated aluminum.
603. The solar cell module of clause 602, wherein the coated aluminum comprises an aluminum layer and, on at least one side of the aluminum layer, and at least one corrosion resistant joining layer contacting the solderable layer.
604. The solar cell module of clause 603, wherein the coated aluminum does not comprise a native oxide between the aluminum layer and the at least one corrosion resistant joining layer.
605. The solar cell module of clause 603 or 604, wherein the at least one corrosion resistant joining layer is:
an alloy of aluminum and a metal, wherein the metal is
selected from copper (Cu), magnesium (Mg), manganese (Mn), silicon (Si), tin (Sn), zinc (Zn), and a combination thereof; or
selected from chromium (Cr), cobalt (Co), molybdenum (Mo), nickel (Ni), tantalum (Ta), titanium (Ti), tungsten (W), an alloy thereof, a nitride thereof, a boride thereof, a composite thereof, and a combination thereof; or
selected from Ti, an alloy thereof, a nitride thereof, a boride thereof, a composite thereof, and a combination thereof.
606. The solar cell module of any one of clauses 603 to 605, further comprising a second metal layer between, and contacting, the at least one corrosion resistant joining layer and the solderable layer.
607. The solar cell module of clause 606, wherein the second metal layer comprises copper.
608. The solar cell module of any one of clauses 603 to 607, wherein the at least one corrosion resistant joining layer has a thickness, width, or both, ranging from 50 nm to 200 nm, or from 20 nm to 100 nm.
609. The solar cell module of any one of clauses 556 to 608, wherein the metal layer of the at least one fine grid line, the at least one busbar, when present, and the first and/or second interconnection pad, when present, has a surface roughness Ra ranging from 100 nm to 500 nm, from 200 nm to 500 nm, or from 300 nm to 500 nm.
610. The solar cell module of any one of clauses 556 to 609, wherein the metal layer of the at least one fine grid line, the at least one busbar, when present, and the first and/or second interconnection pad, when present, is laser cut.
611. The solar cell module of clause 610, wherein the metal layer has a burr roughness ranging from 200 nm to 20 μm, from 1 μm from 10 μm, or from 1 μm to 5 μm.
612. The solar cell module of clause 610 or 611, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.
613. The solar cell module of clause any one of clauses 610 to 612, wherein the metal layer has a burr mean height ranging from 200 nm to 20 μm, from 1 μm to 10 μm, or from 1 μm to 5 μm.
614. The solar cell module of any one of clauses 610 to 613, wherein the metal layer has a dross mean height ranging from 200 nm to 20 μm, from 1 μm to 10 μm, or from 1 μm to 5 μm.
615. The solar cell module of any one of clauses 610 to 614, wherein the metal layer has a dross roughness ranging from 200 nm to 20 μm, from 1 μm to 10 μm, or from 1 μm to 5 μm
616. The solar cell module of any one of clauses 556 to 615, wherein the solderable layer of the at least one fine grid line, the at least one busbar, when present, and the first and/or second interconnection pad, when present, has a thickness of less than 40 μm, less than 30 μm, less than 25 μm, less than 20 μm, or less than 10 μm.
617. The solar cell module of any one of clauses 556 to 616, wherein the silver contact pad of the at least one fine grid line, the at least one busbar, when present, and the first and/or second interconnection pad, when present, has a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.
618. The solar cell module of any one of clauses 556 to 617, wherein the solderable layer of the at least one fine grid line, the at least one busbar, when present, and the first and/or second interconnection pad, when present, is a solder layer comprising a solder material.
619. The solar cell module of clause 618, wherein the solder material is a Silver-Aluminum-Copper (SAC) solder material.
620. A solar cell module comprising:
a first solar cell and a second solar cell;
an interconnect that connects the first solar cell and the second solar cell;
wherein the first solar cell and the second solar cell comprise:
a silicon substrate having a front, light-facing surface and a rear surface, wherein the rear surface is opposite of the light-facing surface;
at least one passivation layer directly on at least a portion of the rear surface of the silicon substrate, wherein the at least one passivation layer comprises an intrinsic amorphous layer on at least a portion of the substrate and a doped layer on at least a portion of the intrinsic amorphous layer, wherein the doped layer comprises at least one doped region and at least one oppositely doped region;
a transparent conductive oxide layer on at least a portion of the at least one passivation layer;
at least one first fine grid line on at least a portion of the transparent conductive oxide layer; and
at least one second fine grid line on at least a portion of the transparent conductive oxide layer;
wherein at least one of the at least one first fine grid line or the at least one second fine grid line is a first conductive multilayer line comprising at least two conductive multilayer stacks, wherein a conductive multilayer stack of the at least two conductive multilayer stacks comprises:
a metal layer comprising copper (Cu) or coated aluminum;
a silver contact pad comprising a silver sublayer and no glass frit; and
a solderable layer between, and contacting, the metal layer and the silver contact pad;
wherein the silver contact pad of the conductive multilayer stack contacts at least a portion of the transparent conductive oxide layer; and
wherein the metal layer of the conductive multilayer stack is a continuous layer that connects the at least two conductive multilayer stacks.
621. The solar cell module of clause 620, wherein either the at least one fine grid line or the at least one second fine grid line is the first conductive multilayer line and the other comprises sintered aluminum.
622. The solar cell module of clause 620, wherein the at least one first fine grid line is a first conductive multilayer line comprising at least two conductive multilayer stacks, and wherein the at least one second fine grid line is a second conductive multilayer line comprising at least two conductive multilayer stacks.
623. The solar cell module of any one of clauses 620 to 622, wherein the interconnect comprises:
at least one first interconnection pad on the first solar cell contacting the at least one first fine grid line;
at least one second interconnection pad on the second solar cell contacting the at least one second fine grid line;
wherein the at least one first interconnection pad is connected to the at least one second interconnection pad.
624. The solar cell module of clause 623, wherein the at least one first interconnection pad is a third conductive multilayer line comprising at least two conductive multilayer stacks, and wherein the at least one second interconnection pad is a fourth conductive multilayer line comprising at least two conductive multilayer stacks, a conductive multilayer stack of the at least two conductive multilayer stacks in the third and/or fourth conductive multilayer line comprising:
a metal layer comprising copper (Cu) or coated aluminum;
a silver contact pad comprising a silver sublayer and no glass frit; and
a solderable layer between, and contacting, the metal layer and the silver contact pad; and
wherein the silver contact pad of the conductive multilayer stack contacts at least a portion of the transparent conductive oxide layer; and
wherein the metal layer of the conductive multilayer stack is a continuous layer that connects the at least two conductive multilayer stacks of the at least one first and/or second interconnection pad.
625. The solar cell module of clause 624, wherein the metal layer of the at least two conductive multilayer stacks of the first conductive multilayer line is a continuous layer that is connected to the least two conductive multilayer stacks of the third conductive multilayer line.
626. The solar cell module of clause 624 or 625, wherein the metal layer of the at least two conductive multilayer stacks of the second conductive multilayer is a continuous layer that is connected to the at least two conductive multilayer stacks of the fourth conductive multilayer line.
627. The solar cell module of any one of clauses 624 to 626, wherein the metal layer of the at least one first interconnection pad on the first solar cell is connected to the metal layer of the at least one second interconnection pad on the second solar cell.
628. The solar cell module of clause 627, wherein the metal layer of the at least one first interconnection pad on the first solar cell is welded to the metal layer of the at least one second interconnection pad on the second solar cell.
629. The solar cell module of any one of clauses 620 to 622, further comprising at least one first solder pad on at least a portion of the front and/or rear surface of the silicon substrate on the first solar cell and at least one second solder pad on at least a portion of the front and/or rear surface of the silicon substrate on the second solar cell, wherein the at least one first fine grid line on the first solar cell contacts the at least one first solder pad, wherein the at least one second fine grid line on the second solar cell contacts the at least one second solder pad, and wherein the interconnect comprises a tabbing wire that contacts the at least one first solder pad on the first solar cell and the at least one second solder pad on the second solar cell, and wherein a bus ribbon contacts the tabbing wire.
630. The solar cell module of any one of clauses 620 to 629, wherein the at least one doped region comprises a p-type dopant and the at least one oppositely-doped region comprises an n-type dopant.
631. The solar cell module of any one of clauses 620 to 630, wherein the intrinsic amorphous layer of the at least one passivation layer comprises intrinsic amorphous silicon (a-Si: H(i)).
632. The solar cell module of any one of clauses 620 to 631, wherein the at least one doped region comprises a p-type doped hydrogenated amorphous silicon (a-Si: H(p)).
633. The solar cell module of any one of clauses 620 to 632, wherein the at least one oppositely-doped region comprises an n-type doped hydrogenated amorphous silicon (a-Si: H(n)).
634. The solar cell module of any one of clauses 620 to 633, wherein the transparent conductive oxide layer comprises indium tin oxide.
635. The solar cell module of any one of clauses 620 to 634, wherein the intrinsic amorphous layer of the at least one passivation layer contacts at least a portion of the doped silicon substrate, the at least one doped region contacts at least a portion of the intrinsic amorphous layer, and/or the transparent conductive oxide layer contacts at least a portion of the at least one doped region.
636. The solar cell module of any one of clauses 620 to 634, wherein the intrinsic amorphous layer of the at least one passivation layer contacts at least a portion of the doped silicon substrate, the at least one oppositely-doped region contacts at least a portion of the intrinsic amorphous layer, and/or the transparent conductive oxide layer contacts at least a portion of the at least one oppositely-doped region.
637. The solar cell module of any one of clauses 620 to 636, wherein the transparent conductive oxide layer is between and contacts at least a portion of the at least one doped region and at least a portion of the silver contact pad.
638. The solar cell module of any one of clauses 620 to 636, wherein the transparent conductive oxide layer is between and contacts at least a portion of the at least one oppositely-doped region and at least a portion of the silver contact pad.
639. The solar cell module of any one of clauses 620 to 638, wherein a thickness of the intrinsic amorphous layer of the at least one passivation layer is from 2 nm to 5 nm.
640. The solar cell module of any one of clauses 620 to 639, wherein a thickness of the doped layer of the at least one passivation layer is from 10 nm to 50 nm.
641. The solar cell module of any one of clauses 620 to 640, wherein a thickness of the transparent conductive oxide layer is from 50 nm to 100 nm.
642. The solar cell module of any one of clauses 620 to 641, wherein the doped silicon substrate is p-type doped.
643. The solar cell module of any one of clauses 620 to 641, wherein the doped silicon substrate is n-type doped.
644. The solar cell module of any one of clauses 620 to 643, wherein a silver contact pad of a first conductive multilayer stack of the at least two conductive multilayer stacks of the first conductive multilayer line is separated from a silver contact pad of a second conductive multilayer stack by a distance from 200 μm to 2 mm, 300 μm to 2 mm, 300 μm to 1 mm, 400 μm to 1 mm, or 400 μm to 900 μm.
645. The solar cell module of any one of clauses 620 to 644, wherein the metal layer of the at least one first and/or second fine grid line and the at least one first and/or second interconnection pad, when present, has a thickness ranging from 4 μm to 100 μm, from 4 μm to 50 μm, from 4 μm to 25 μm, from 4 μm to 10 μm, or from 4 μm to 6 μm.
646. The solar cell module of any one of clauses 620 to 645, wherein the metal layer of the at least one first and/or second fine grid line and the at least one first and/or second interconnection pad, when present, has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm.
647. The solar cell module of any one of clauses 620 to 646, wherein the substrate has a thickness ranging from 120 μm to 180 μm.
648. The solar cell module of any one of clauses 620 to 647, wherein the metal layer of the at least one first and/or second fine grid line and the at least one first and/or second interconnection pad, when present, comprises, consists of, or consists essentially of Cu.
649. The solar cell module of any one of clauses 620 to 647, wherein the metal layer of the at least one first and/or second fine grid line and the at least one first and/or second interconnection pad, when present, comprises, consists of, or consists essentially of coated aluminum.
650. The solar cell module of clause 649, wherein the coated aluminum comprises an aluminum layer and, on at least one side of the aluminum layer, and at least one corrosion resistant joining layer contacting the solderable layer.
651. The solar cell module of clause 650, wherein the coated aluminum does not comprise a native oxide between the aluminum layer and the at least one corrosion resistant joining layer.
652. The solar cell module of clause 650 or 651, wherein the at least one corrosion resistant joining layer is:
an alloy of aluminum and a metal, wherein the metal is:
selected from copper (Cu), magnesium (Mg), manganese (Mn), silicon (Si), tin (Sn), zinc (Zn), and a combination thereof; or
selected from chromium (Cr), cobalt (Co), molybdenum (Mo), nickel (Ni), tantalum (Ta), titanium (Ti), tungsten (W), an alloy thereof, a nitride thereof, a boride thereof, a composite thereof, and a combination thereof; or
selected from Ti, an alloy thereof, a nitride thereof, a boride thereof, a composite thereof, and a combination thereof.
653. The solar cell module of any one of clauses 650 to 652, further comprising a second metal layer between, and contacting, the at least one corrosion resistant joining layer and the solderable layer.
654. The solar cell module of clause 653, wherein the second metal layer comprises copper.
655. The solar cell module of any one of clauses 650 to 654, wherein the at least one corrosion resistant joining layer has a thickness, width, or both, ranging from 50 nm to 200 nm, or from 20 nm to 100 nm.
656. The solar cell module of any one of clauses 620 to 655, wherein the metal layer of the at least one first and/or second fine grid line and the at least one first and/or second interconnection pad, when present, has a surface roughness Ra ranging from 100 nm to 500 nm; from 200 nm to 500 nm; or from 300 nm to 500 nm.
657. The solar cell module of any one of clauses 620 to 656, wherein the metal layer of the at least one first and/or second fine grid line and the at least one first and/or second interconnection pad, when present, is laser cut.
658. The solar cell module of clause 657, wherein the metal layer has a burr roughness ranging from 200 nm to 20 μm, from 1 μm from 10 μm, or from 1 μm to 5 μm.
659. The solar cell module of clause 657 or 658, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.
660. The solar cell module of any one of clauses 657 to 659, wherein the metal layer has a burr mean height ranging from 200 nm to 20 μm, from 1 μm to 10 μm, or from 1 μm to 5 μm.
661. The solar cell module of any one of clauses 657 to 660, wherein the metal layer has a dross mean height ranging from 200 nm to 20 μm, from 1 μm to 10 μm, or from 1 μm to 5 μm.
662. The solar cell module of any one of clauses 657 to 661, wherein the metal layer has a dross roughness ranging from 200 nm to 20 μm, from 1 μm to 10 μm, or from 1 μm to 5 μm.
663. The solar cell module of any one of clauses 620 to 662, wherein the solderable layer of the at least one first and/or second fine grid line and the at least one first and/or second interconnection pad, when present, has a thickness of less than 40 μm, less than 30 μm, less than 25 μm, less than 20 μm, or less than 10 μm.
664. The solar cell module of any one of clauses 620 to 663, wherein the silver pad of the at least one first and/or second fine grid line and the at least one first and/or second interconnection pad, when present, has a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.
665. The solar cell module of any one of clauses 620 to 664, wherein the solderable layer of the at least one first and/or second fine grid line and the at least one first and/or second interconnection pad, when present, is a solder layer comprising a solder material.
666. The solar cell module of clause 665, wherein the solder material is a Silver-Aluminum-Copper (SAC) solder material.
667. A method for forming a conductive multilayer stack comprising:
providing a silicon substrate having at least one passivation layer, and a transparent conductive oxide layer thereon, on a front and/or a rear surface of the silicon substrate;
forming a silver contact pad, wherein the silver contact pad does not comprise a glass frit;
forming a solderable layer by applying a solderable paste on the silver contact pad;
applying a metal layer comprising copper (Cu) or coated aluminum on the solderable layer; and
heating the metal layer to mechanically join the metal layer to the solderable layer and the solderable layer to the silver contact pad;
wherein the silver contact pad is on at least one portion of the transparent conductive oxide layer.
668. The method of clause 667, wherein forming the silver contact pad comprises:
applying a silver metallization paste on at least one portion of the silicon substrate or on at least one portion of the transparent conductive oxide layer, the silver metallization paste comprising silver particles and no glass frits, and
annealing the silver metallization paste.
669. A method for forming a conductive multilayer line comprising:
providing a silicon substrate having at least one passivation layer and a transparent conductive oxide layer on the at least one passivation layer;
forming a discontinuous line of silver contact pads, wherein a silver contact pad of the discontinuous line of silver contact pad does not comprise a glass frit;
forming a discontinuous line of solderable pads by applying a discontinuous line of solderable paste on and aligned with the discontinuous line of silver contact pads;
applying a metal layer comprising copper (Cu) or coated aluminum on the discontinuous line of solderable pads; and
heating the metal layer to mechanically join the metal layer to the discontinuous line of solderable pads and the discontinuous line of solderable pads to the discontinuous line of silver contact pads;
wherein the silver contact pad is on least one portion of the transparent conductive oxide layer.
670. The method of clause 669, wherein forming the discontinuous line of silver contact pads comprises:
applying a discontinuous line of silver metallization paste on a surface of the transparent conductive oxide layer, the silver metallization paste comprising silver particles and no glass frits;
and annealing the discontinuous line of silver metallization paste.
671. The method of clause 669 or 670, wherein the discontinuous line of silver contact pads comprises a first silver contact pad and a second silver contact pad and wherein the first silver contact pad is separated from the second silver contact pad by a distance from 200 μm to 2 mm, from 300 μm to 1 mm, from 300 μm to 1 mm, from 400 μm to 1 mm, or from 400 μm to 900 μm.
672. The method of any one of clauses 667 to 671, wherein the silver contact pads have a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.
673. The method of any one of clauses 667 to 672, wherein the front and/or rear surface has a total surface are, wherein the silver contact pads have a combined surface area, and wherein the combined surface area ranges from 0.5% to 7%, from 0.5% to 6%, from 0.5% to 5%, from 0.5% to 4%, from 0.5% to 3%, from 0.5% to 2%, from 0.5% to 1%, or from 0.5% to 0.75% of a total surface area.
674. The method of any one of clauses 667 to 673, wherein the metal layer has a thickness ranging from 4 μm to 100 μm, from 4 μm to 50 μm, from 4 μm to 25 μm, from 4 μm to 10 μm, or from 4 μm to 6 μm.
675. The method of any one of clauses 667 to 674, wherein the metal layer has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm.
676. The method of any one of clauses 667 to 675, wherein the silicon substrate has a thickness ranging from 120 μm to 180 μm.
677. The method according to any one of clauses 667 to 676, further comprising laser cutting the metal layer into a pattern prior to applying the metal layer.
678. The method according to clause 677, wherein the metal layer has a burr roughness ranging from 200 nm to 20 μm, from 1 μm to 10 μm, or from 1 μm to 5 μm.
679. The method according to clause 677 or 678, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.
680. The method according to any one of clauses 677 to 679, wherein the metal layer has a burr mean height ranging from 200 nm to 20 μm, from 1 μm to 10 μm, or from 1 μm to 5 μm.
681. The method according to any one of clauses 677 to 680, wherein the metal layer has a dross mean height ranging from 200 nm to 20 μm, from 1 μm to 10 μm, or from 1 μm to 5 μm.
682. The method according to any one of clauses 677 to 681, wherein the metal layer has a dross roughness ranging from 200 nm to 20 μm, from 1 μm to 10 μm, or from 1 μm to 5 μm.
683. The method according to any one of clauses 669 to 682, wherein the conductive multilayer line is a fine grid line or a bus bar.
684. The method of any one of clauses 667 to 683, further comprising:
mechanically joining a tabbing wire to the metal layer of the conductive multilayer stack or the conductive multilayer liner, wherein the tabbing wire comprises a metal core and a solder coating, wherein the metal layer comprises Cu, and wherein the tabbing wire comprises a metal core and a solder coating.
685. The method of clause 684, wherein the tabbing wire is soldered to the metal layer.
686. The method of clause 684 or 685, wherein the metal core comprises:
copper, aluminum, carbon, tin, or iron; or an alloy thereof, a composite thereof, or a combination thereof.
687. The method of any one of clauses 684 to 686, wherein the metal core comprises copper.
688. The method of any one of clauses 684 to 687, wherein the tabbing wire has a diameter from 80 μm to 1000 μm, from 100 μm to 300 μm, or from 120 μm to 200 μm.
689. The method of any one of clauses 684 to 688, wherein the solder coating has a thickness from 0.5 μm to 100 μm or from 10 μm to 50 μm.
690. The method of any one of clauses 684 to 689, wherein the solder coating comprises:
tin, lead, silver, bismuth, copper, zinc, antimony, manganese, or indium; or an alloy thereof, a composite thereof, or a combination thereof.

The embodiments and examples described above are intended to be merely illustrative and non-limiting. Those skilled in the art will recognize or will be able to ascertain using no more than routine experimentation, numerous equivalents of specific compounds, materials and procedures. All such equivalents are considered to be within the scope and are encompassed by the appended claims.

1.-20. (canceled)

21. A conductive multilayer stack comprising:
a metal layer comprising copper (Cu);
a silver contact layer comprising a silver sublayer and a glass frit sublayer, wherein the silver sublayer is on the glass frit sublayer; and
a solderable layer between, and contacting, the metal layer and the silver contact layer; and
wherein the glass frit sublayer of the conductive multilayer stack contacts at least a portion of a silicon substrate, contacts at least a portion of an at least one passivation layer on the silicon substrate, or contacts a combination thereof.

22. The conductive multilayer stack of claim 21, wherein the metal layer has a thickness ranging from 4 μm to 100 μm, from 4 μm to 50 μm, from 4 μm to 25 μm, from 4 μm to 10 μm, or from 4 μm to 6 μm.

23. The conductive multilayer stack of claim 21, wherein the metal layer has a width from 30 μm to 500 μm, from 30 μm to 450 μm, from 30 μm to 400 μm, from 30 μm to 350 μm, from 30 μm to 300 μm, from 30 μm to 250 μm, from 30 μm to 200 μm, from 30 μm to 150 μm, from 40 μm to 125 μm, from 40 μm to 100 μm, from 50 μm to 100 μm, or from 50 μm to 75 μm.

24. The conductive multilayer stack of claim 21, wherein the substrate has a thickness ranging from 120 μm to 180 μm.

25. The conductive multilayer stack of claim 21, wherein the metal layer consists of, or consists essentially of Cu.

26. The conductive multilayer stack of claim 21, wherein the glass frit sublayer penetrates through the at least one passivation layer.

27. The conductive multilayer stack of claim 21, wherein the metal layer has a surface roughness Ra ranging from 100 nm to 500 nm, from 200 nm to 500 nm, or from 300 nm to 500 nm.

28. The conductive multilayer stack of claim 21, wherein the metal layer is laser cut.

29. The conductive multilayer stack of claim 28, wherein the metal layer has a burr roughness ranging from 200 nm to 20 μm, from 1 μm to 10 μm, or from 1 μm to 5 μm.

30. The conductive multilayer stack of claim 28, wherein the metal layer has an in-plane edge roughness ranging from 0.5 μm to 50 μm, from 0.5 μm to 20 μm, from 0.5 μm to 10 μm, from 0.5 μm to 5 μm, from 0.5 μm to 2.5 μm, or from 0.1 μm to 1.5 μm.

31. The conductive multilayer stack of claim 28, wherein the metal layer has a burr mean height ranging from 200 nm to 20 μm, from 1 μm to 10 μm, or from 1 μm to 5 μm.

32. The conductive multilayer stack of claim 28, wherein the metal layer has a dross mean height ranging from 200 nm to 20 μm, from 1 μm to 10 μm, or from 1 μm to 5 μm.

33. The conductive multilayer stack of claim 28, wherein the metal layer has a dross roughness ranging from 200 nm to 20 μm, from 1 μm to 10 μm, or from 1 μm to 5 μm.

34. The conductive multilayer stack of claim 21, wherein the solderable layer has a thickness of less than 40 μm, less than 30 μm, less than 25 μm, less than 20 μm, or less than 10 μm.

35. The conductive multilayer stack of claim 21, wherein the silver sublayer has a thickness from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.

36. The conductive multilayer stack of claim 21, wherein the glass frit sublayer has a thickness from 1 nm to 3 μm, from 1 nm to 1 μm, or from 1 nm to 200 nm.

37. The conductive multilayer stack of claim 21, wherein the solderable layer is a solder layer comprising a solder material.

38. The conductive multilayer stack of claim 37, wherein the solder material is a Silver-Aluminum-Copper (SAC) solder material.

39. The conductive multilayer stack of claim 21, wherein the silver contact layer comprises silver contact pads.

40. The conductive multilayer stack of claim 39, wherein the silver contact layer comprises a discontinuous line of silver contact pads.

41. The conductive multilayer stack of claim 39, where the silver contact pads have a length ranging from 30 μm to 250 μm, from 30 μm to 225 μm, from 30 μm to 200 μm, from 30 μm to 175 μm, from 30 μm to 150 μm, from 30 μm to 125 μm, from 30 μm to 100 μm, from 30 μm to 75 μm, from 30 μm to 60 μm, from 30 μm to 50 μm, or from 30 μm to 40 μm.

42. The conductive multilayer stack of claim 39, wherein the silver contact pads has a thickness ranging from 3 μm to 30 μm, from 4 μm to 25 μm, from 4 μm to 20 μm, from 4 μm to 15 μm, from 4 μm to 12 μm, from 4 μm to 10 μm, from 4 μm to 8 μm, or from 4 μm to 5 μm.

43. The conductive multilayer stack of claim 40, wherein the silver contact pads are consecutive silver contact pads in the discontinuous line, and a first silver contact pad of the silver contact pads is separated from a second silver contact pad of the silver contact pads by a distance from 200 μm to 2 mm, from 300 μm to 1 mm, from 300 μm to 1 mm, from 400 μm to 1 mm, or from 400 μm to 900 μm.

44. The conductive multilayer stack of claim 21, wherein the silicon substrate and at least one passivation layer are the silicon substrate and the at least one passivation layer of a solar cell.

45. A solar cell comprising at least two grid lines having two or more conductive multilayer stacks of claim 21.

46. The solar cell of claim 45, wherein the at least two grid lines are a fine grid line, a busbar, or a combination thereof.

47. The solar cell of claim 45, wherein a silver contact pad of a first conductive multilayer stack of the two or more conductive multilayer stacks is separated from a silver contact pad of a second conductive multilayer stack of the two or more conductive multilayer stacks by a distance from 200 μm to 2 mm, from 300 μm to 1 mm, from 300 μm to 1 mm, from 400 μm to 1 mm, or from 400 μm to 900 μm.
